(19) United States
(12) Patent Application Publication
(10) Pub. No.: US 2025/0149441 A1
(43) Pub. Date: May 8, 2025

(54) SEMICONDUCTOR DEVICE

(71) Applicant: ROHM CO., LTD., Kyoto-shi (JP)

(72) Inventor: Kazuma MORIYAMA, Kyoto-shi (JP)

(73) Assignee: ROHM CO., LTD., Kyoto-shi (JP)

(21) Appl. No.: 19/015,702

(22) Filed: Jan. 10, 2025

Related U.S. Application Data
(63) Continuation of application No. PCT/JP2023/024812, filed on Jul. 4, 2023.

(30) Foreign Application Priority Data
Jul. 11, 2022 (JP) 2022-111395

(51) Int. Cl. H01L 23/522; H01L 23/528; H10D 12/00

(52) U.S. Cl. CPC H01L 23/5228; H01L 23/5283; H10D 12/481

(57) ABSTRACT

A semiconductor device includes a chip that has a main surface, a trench resistive structure that is formed in the main surface, a resistive film that is electrically connected to the trench resistive structure on the main surface, a gate terminal electrode that has a lower resistance than that of the resistive film and that is electrically connected to the trench resistive structure via the resistive film on the main surface, and a gate wiring electrode that has a lower resistance than that of the resistive film and that is electrically connected to the gate terminal electrode via the resistive film and the trench resistive structure on the main surface.

### CROSS-REFERENCE TO RELATED APPLICATIONS

The present application is a bypass continuation of International Patent Application No. PCT/JP2023/024812 filed on Jul. 4, 2023, which claims priority to Japanese Patent Application No. 2022-111395 filed on Jul. 11, 2022, the entire disclosures of those applications are incorporated herein by reference.

### BACKGROUND

### 1. Field of the disclosure

The present disclosure relates to a semiconductor device.

### 2. Description of the Related Art

US2017/0040423A1 discloses a semiconductor device that includes a semiconductor substrate, a plurality of trench structures, and a gate pad portion. The plurality of trench structures are formed in a front surface of the semiconductor substrate. The gate pad portion is arranged on the semiconductor substrate to cover the plurality of trench structures.

### BRIEF DESCRIPTION OF THE DRAWINGS

FIG. 1 is a plan view illustrating a semiconductor device according to a first embodiment.

FIG. 2 is a plan view illustrating a layout of a first main surface.

FIG. 3 is an enlarged plan view illustrating an active region and an outer peripheral region.

FIG. 4 is a cross-sectional view taken along line IV-IV illustrated in FIG. 3.

FIG. 5 is a cross-sectional view taken along line V-V illustrated in FIG. 3.

FIG. 6 is a cross-sectional view taken along line VI-VI illustrated in FIG. 3.

FIG. 7 is an enlarged plan view illustrating an active region and a boundary region.

FIG. 8 is a cross-sectional view taken along line VIII-VIII illustrated in FIG. 7.

FIG. 9 is a cross-sectional view taken along line IX-IX illustrated in FIG. 7.

FIG. 10 is a cross-sectional view illustrating a structure of an outer peripheral region.

FIG. 11 is an enlarged plan view illustrating a pad region.

FIG. 12 is an enlarged plan view illustrating a gate resistive structure illustrated in FIG. 11.

FIG. 13 is an enlarged plan view illustrating an inner portion of a gate resistive structure illustrated in FIG. 12.

FIG. 14 is an enlarged plan view illustrating one end portion of the gate resistive structure illustrated in FIG. 12.

FIG. 15 is an enlarged plan view illustrating the other end portion of the gate resistive structure illustrated in FIG. 12.

FIG. 16 is a cross-sectional view taken along line XVI-XVI illustrated in FIG. 13.

FIG. 17 is a cross-sectional view taken along line XVII-XVII illustrated in FIG. 13.

FIG. 18 is a cross-sectional view taken along line XVIII-XVIII illustrated in FIG. 13.

FIG. 19 is a cross-sectional view taken along line XIX-XIX illustrated in FIG. 13.

FIG. 20 is a cross-sectional view taken along line XX-XX illustrated in FIG. 14.

FIG. 21 is a cross-sectional view taken along line XXI-XXI illustrated in FIG. 15.

FIG. 22 is a cross-sectional view taken along line XXII-XXII illustrated in FIG. 12.

FIG. 23 is a plan view illustrating a layout of a resistive film, a gate electrode film, and a gate wiring film.

FIG. 24 is an electric circuit diagram illustrating a gate resistive structure, a gate terminal electrode, and a gate wiring electrode.

FIG. 25 is an enlarged plan view illustrating a layout of a first main surface of a semiconductor device according to a second embodiment.

FIG. 26 is a cross-sectional view taken along line XXVI-XXVI illustrated in FIG. 25.

FIG. 27 is a plan view illustrating a layout of a first main surface of a semiconductor device according to a third embodiment.

FIG. 28 is a cross-sectional view illustrating a structure on a boundary region side of the semiconductor device illustrated in FIG. 27.

FIG. 29 is a cross-sectional view illustrating a structure on the outer peripheral region side of the semiconductor device illustrated in FIG. 27.

FIG. 30 is an enlarged plan view illustrating a first resistance connection electrode according to a modification.

FIG. 31 is a cross-sectional view illustrating a second resistance connection electrode according to a first modification.

FIG. 32 is an enlarged plan view illustrating a second resistance connection electrode according to a second modification.

FIG. 33 is an enlarged plan view illustrating a second resistance connection electrode according to a third modification.

FIG. 34 is a cross-sectional view illustrating a third resistance connection electrode according to the first modification.

FIG. 35 is an enlarged plan view illustrating a third resistance connection electrode according to the second modification.

FIG. 36 is an enlarged plan view illustrating a third resistance connection electrode according to the third modification.

FIG. 37 is an enlarged plan view illustrating a gate resistive structure according to the first modification.

FIG. 38 is an enlarged plan view illustrating an inner portion of the gate resistive structure illustrated in FIG. 37.

FIG. 39 is an enlarged plan view illustrating a gate resistive structure according to the second modification.

FIG. 40 is an enlarged plan view illustrating a gate resistive structure according to the third modification.

FIG. 41 is an electric circuit diagram illustrating a gate resistive structure, a gate terminal electrode, and a gate wiring electrode.

FIG. 42 is a plan view illustrating a gate wiring electrode according to the modification and an emitter terminal electrode according to the modification.

FIG. 43 is an enlarged plan view illustrating a gate connection electrode according to the modification.

FIG. 44 is a cross-sectional view taken along line XLIV-XLIV illustrated in FIG. 43.

### DETAILED DESCRIPTION OF THE PREFERRED EMBODIMENTS

Hereinafter, specific embodiments are described in detail with reference to the accompanying drawings. The attached drawings are schematic views and are not strictly illustrated, and scales and the like thereof do not always match. Also, identical reference signs are given to corresponding structures among the accompanying drawings and duplicate descriptions thereof shall be omitted or simplified. For the structures whose description has been omitted or simplified, the description given before the omission or simplification shall apply.

When the wording “substantially equal” is used in a description in which a comparison target is present, the wording includes a numerical value (shape) equal to a numerical value (shape) of the comparison target and also includes a numerical error (shape error) in a range of ±10% with respect to the numerical value (shape) of the comparison target. Although the wordings “first,” “second,” “third,” and the like are used in the embodiments, these are symbols attached to names of respective structures in order to clarify the order of description and are not attached with an intention of restricting the names of the respective structures.

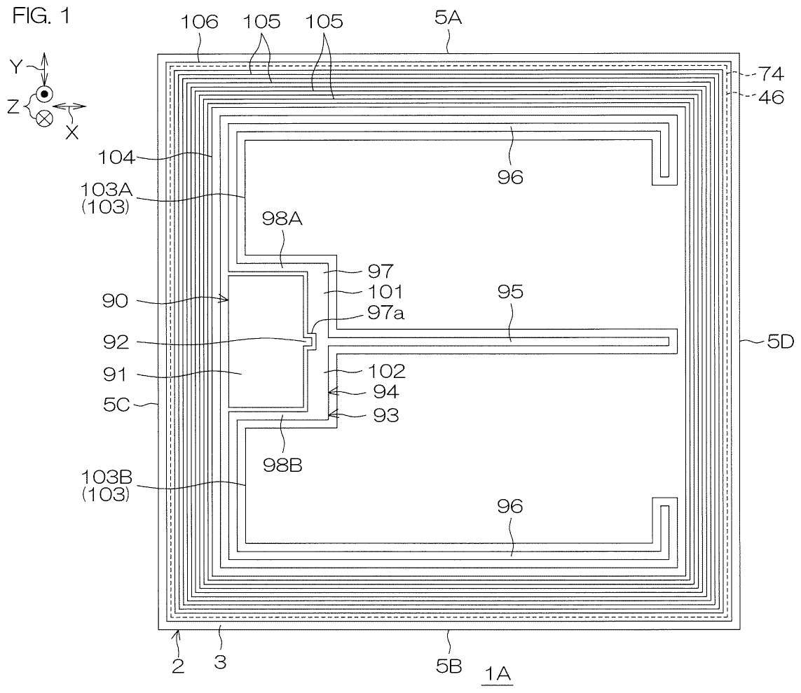

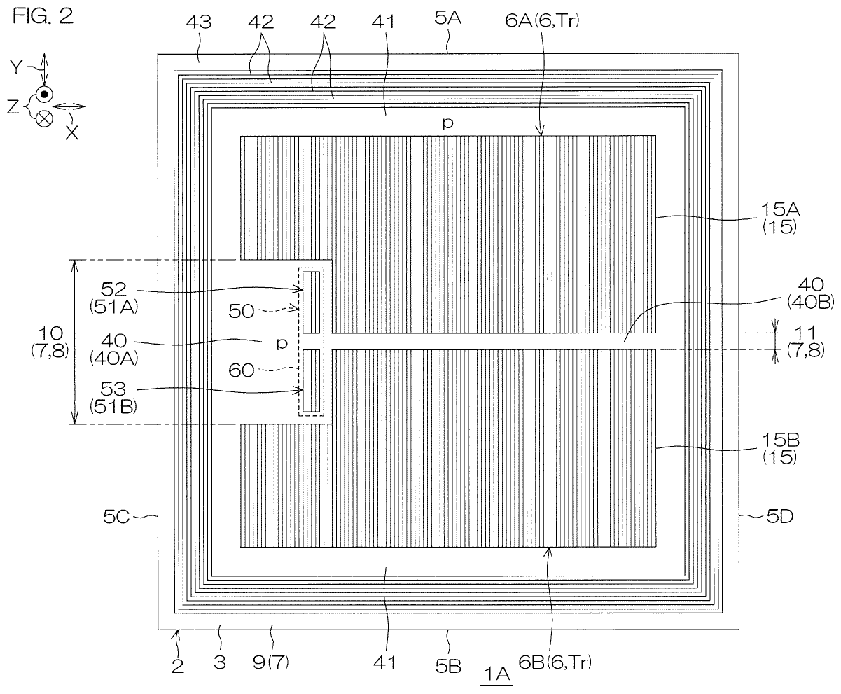

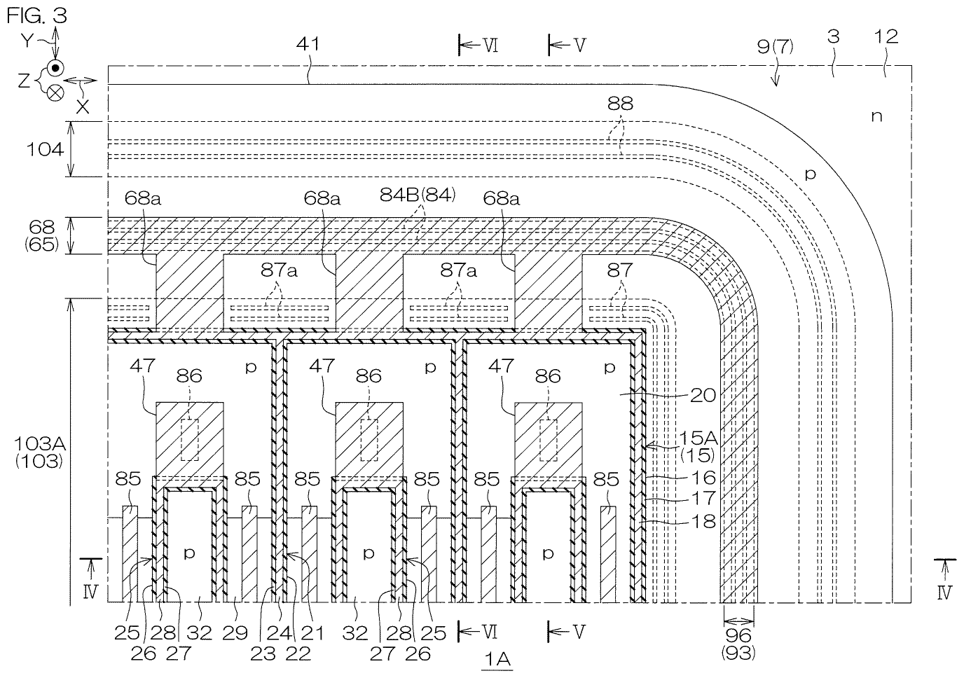

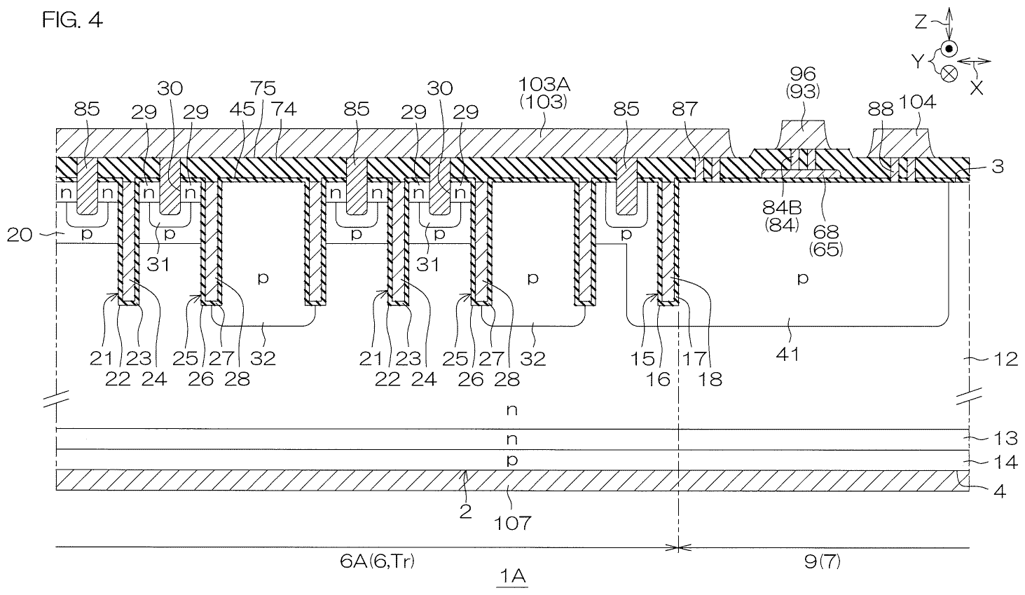

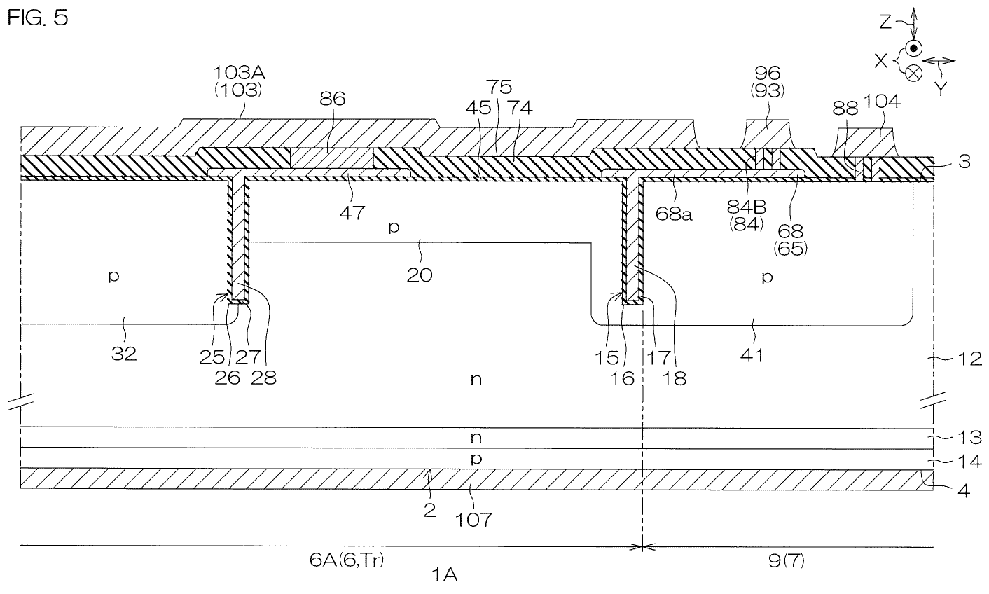

FIG. 1 is a plan view illustrating a semiconductor device 1A according to a first embodiment. FIG. 2 is a plan view illustrating a layout of a first main surface 3. FIG. 3 is an enlarged plan view illustrating an active region 6 and an outer peripheral region 9. FIG. 4 is a cross-sectional view taken along line IV-IV illustrated in FIG. 3. FIG. 5 is a cross-sectional view taken along line V-V illustrated in FIG. 3.

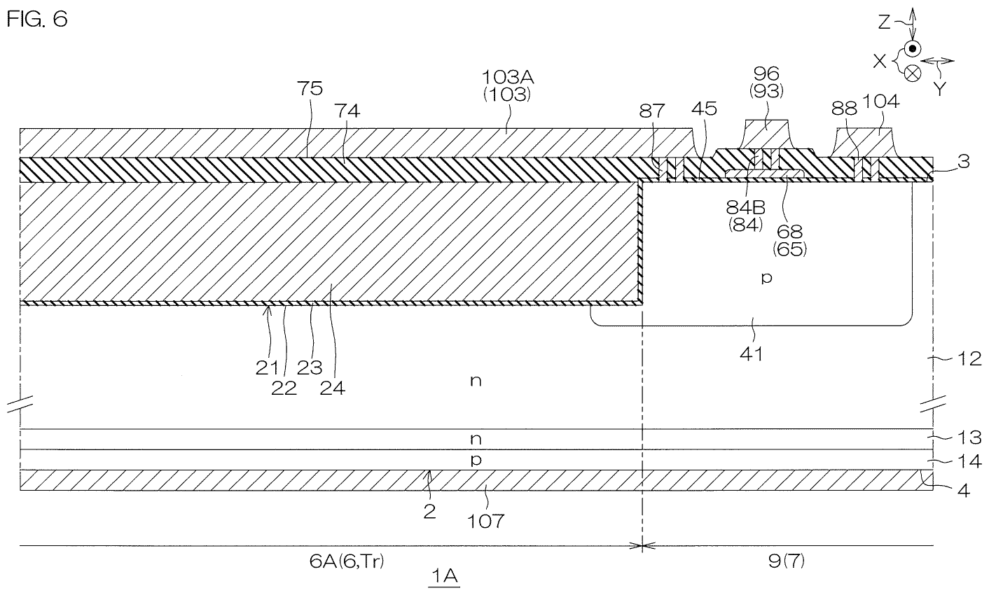

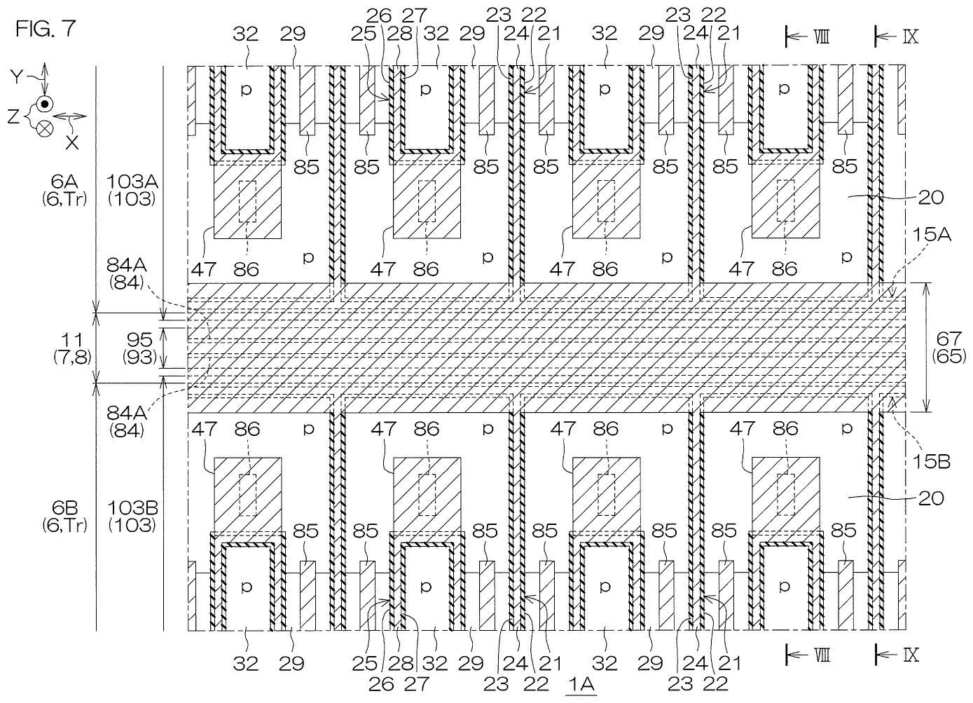

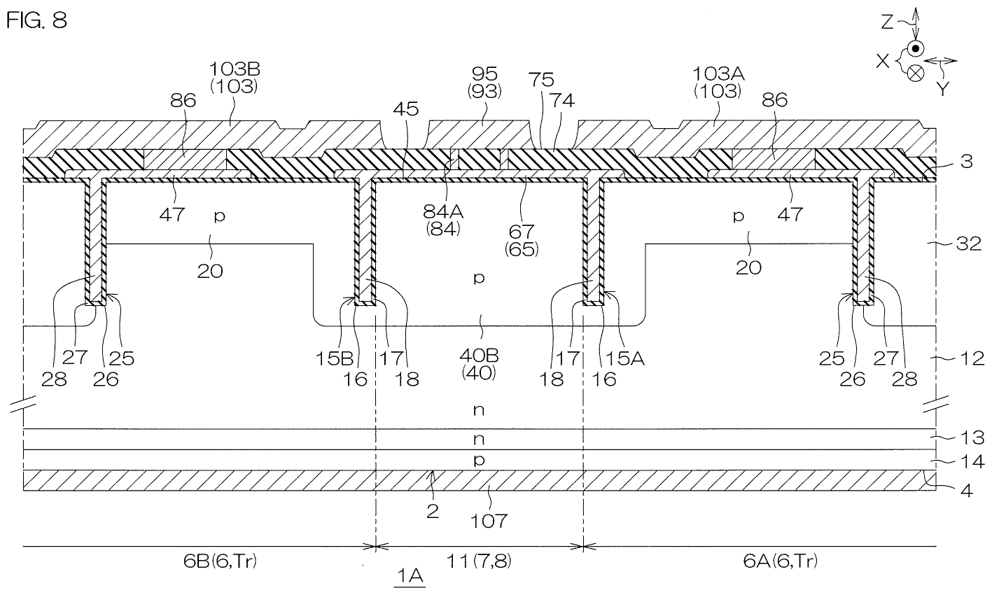

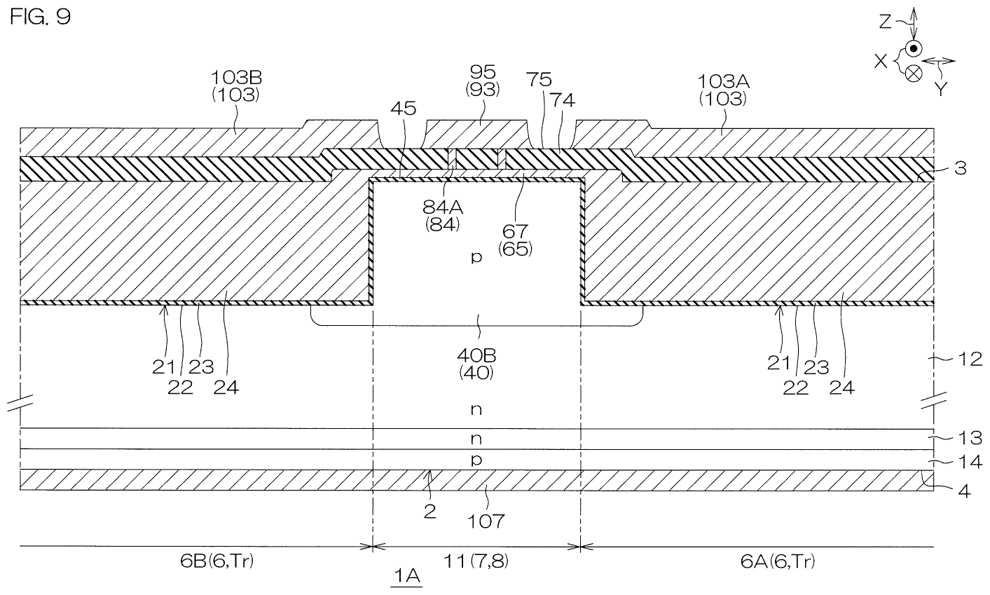

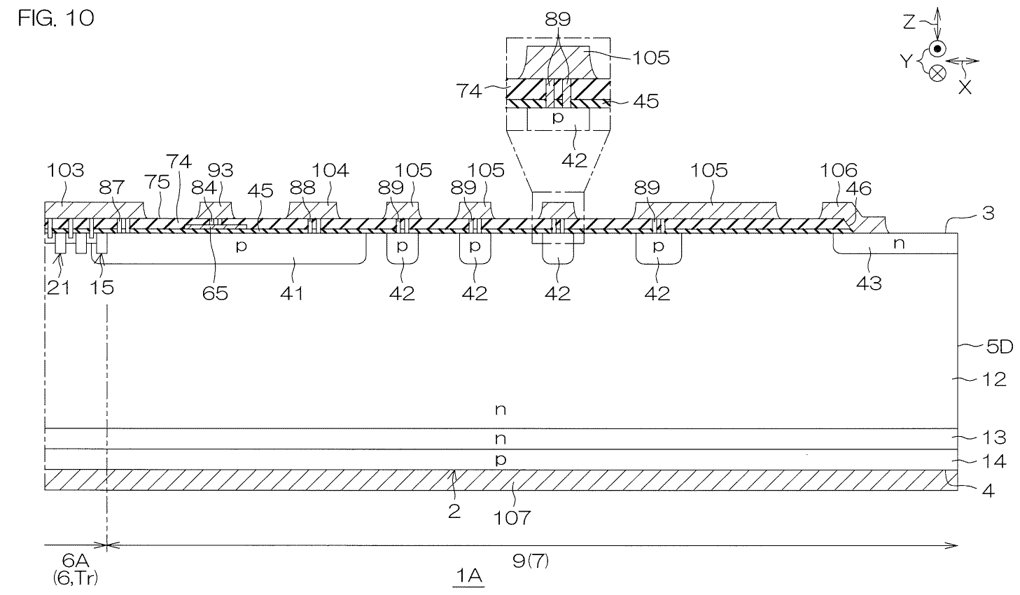

FIG. 6 is a cross-sectional view taken along line VI-VI illustrated in FIG. 3. FIG. 7 is an enlarged plan view illustrating the active region 6 and a boundary region 8. FIG. 8 is a cross-sectional view taken along line VIII-VIII illustrated in FIG. 7. FIG. 9 is a cross-sectional view taken along line IX-IX illustrated in FIG. 7. FIG. 10 is a cross-sectional view illustrating a structure of the outer peripheral region 9.

The semiconductor device 1A is an IGBT semiconductor device having an IGBT (insulated gate bipolar transistor). With reference to FIGS. 1 to 10, the semiconductor device 1A includes a chip 2 having a hexahedron shape (specifically, a rectangular parallelepiped shape). The chip 2 may be referred to as a “semiconductor chip.” In this embodiment, the chip 2 has a single layer structure constituted of a silicon single crystal substrate (semiconductor substrate).

The chip 2 has the first main surface 3 on one side, a second main surface 4 on the other side, and first to fourth side surfaces 5A to 5D connecting the first main surface 3 and the second main surface 4. The first main surface 3 and the second main surface 4 are each formed in a quadrangle shape in plan view as viewed in a normal direction Z thereto (hereinafter, simply referred to as “plan view”). The normal direction Z is also a thickness direction of the chip 2.

The first side surface 5A and the second side surface 5B extend in a first direction X along the first main surface 3 and face each other in a second direction Y intersecting the first direction X along the first main surface 3. Specifically, the second direction Y is orthogonal to the first direction X. The third side surface 5C and the fourth side surface 5D extend in the second direction Y and face each other in the first direction X.

The semiconductor device 1A includes the plurality of active regions 6 provided at an interval in the first main surface 3. The plurality of active regions 6 include a first active region 6A on one side and a second active region 6B on the other side. The first active region 6A is provided in a region on the first side surface 5A side with respect to a straight line crossing the center of the first main surface 3 in the first direction X.

The second active region 6B is provided in a region on the second side surface 5B side with respect to a straight line crossing the center of the first main surface 3 in the first direction X. In this embodiment, each of the active regions 6 is formed in a polygonal shape having four sides parallel to the peripheral edge of the chip 2 in plan view. A planar shape of each of the active regions 6 is arbitrary.

The semiconductor device 1A includes a non-active region 7 provided in a region outside the plurality of active regions 6 on the first main surface 3. The non-active region 7 includes the boundary region 8 and the outer peripheral region 9. The boundary region 8 is provided in a band shape extending in the first direction X in a region between the first active region 6A and the second active region 6B. In this embodiment, the boundary region 8 is positioned on a straight line crossing the center of the first main surface 3 in the first direction X.

The boundary region 8 includes a pad region 10 having a comparatively large width in the second direction Y and a street region 11 having a width smaller than the width of the pad region 10 in the second direction Y. The pad region 10 may be referred to as a “first boundary region” or a “wide region.” The street region 11 may be referred to as a “second boundary region,” a “line region,” or a “narrow region.”

The pad region 10 is provided in a region on one side (the third side surface 5C side) in the first direction X. In this embodiment, the pad region 10 is positioned on a straight line crossing the center of the first main surface 3 in the first direction X in plan view and is provided in a quadrangular shape in the vicinity of the central portion of the third side surface 5C.

The street region 11 is provided in a region on the other side (the fourth side surface 5D side) in the first direction X with respect to the pad region 10. In this embodiment, the street region 11 is led out in a band shape from the pad region 10 toward the fourth side surface 5D side and is positioned on a straight line crossing the center of the first main surface 3 in the first direction X.

The outer peripheral region 9 is provided in the peripheral edge portion of the chip 2 such as to collectively surround the plurality of active regions 6. The outer peripheral region 9 is provided in an annular shape (the quadrangular annular shape in this embodiment) extending along the peripheral edge (first to fourth side surfaces 5A to 5D) of the chip 2. The outer peripheral region 9 is connected to the pad region 10 on one side (the third side surface 5C side) of the first main surface 3 and is connected to the street region 11 on the other side (the fourth side surface 5D side) of the first main surface 3.

The semiconductor device 1A includes an n-type (first conductivity type) drift region 12 formed inside the chip 2. The drift region 12 is formed in the entire region inside the chip 2. In this embodiment, the chip 2 is constituted of an n-type semiconductor substrate (n-type semiconductor chip), and the drift region 12 is formed using the n-type chip 2.

The semiconductor device 1A includes an n-type buffer region 13 formed in a surface layer portion of the second main surface 4. In this embodiment, the buffer region 13 is formed in a layer shape extending along the second main surface 4 in the entire region of the second main surface 4. The buffer region 13 has a higher n-type impurity concentration than that of the drift region 12. The presence or absence of the buffer region 13 is arbitrary, and an embodiment without the buffer region 13 may be adopted.

The semiconductor device 1A includes a p-type (second conductivity type) collector region 14 formed in a surface layer portion of the second main surface 4. The collector region 14 is formed in a surface layer portion of the buffer region 13 on the second main surface 4 side. In this embodiment, the collector region 14 is formed in a layer shape extending along the second main surface 4 in the entire region of the second main surface 4. The collector region 14 is exposed from the second main surface 4 and a part of the first to fourth side surfaces 5A to 5D.

The semiconductor device 1A includes a plurality of trench separation structures 15 formed in the first main surface 3 such as to demarcate the plurality of active regions 6. A gate potential is applied to the plurality of trench separation structures 15. The trench separation structure 15 may be referred to as a “trench gate separating structure” or a “trench gate connection structure.” The plurality of trench separation structures 15 include a first trench separation structure 15A on the first active region 6A side and a second trench separation structure 15B on the second active region 6B side.

The first trench separation structure 15A surrounds the first active region 6A and demarcates the first active region 6A from the boundary region 8 and the outer peripheral region 9. In this embodiment, the first trench separation structure 15A is formed in a polygonal annular shape having four sides parallel to the peripheral edge of the chip 2 in plan view. The first trench separation structure 15A has a portion bent such as to demarcate the pad region 10 and the street region 11 of the boundary region 8 in plan view.

The second trench separation structure 15B surrounds the second active region 6B and demarcates the second active region 6B from the boundary region 8 and the outer peripheral region 9. In this embodiment, the second trench separation structure 15B is formed in a polygonal annular shape having four sides parallel to the peripheral edge of the chip 2 in plan view. The second trench separation structure 15B has a portion bent such as to demarcate the pad region 10 and the street region 11 of the boundary region 8 in plan view.

The trench separation structure 15 preferably has a width less than the width of the street region 11. The width of the trench separation structure 15 is a width in a direction orthogonal to a direction in which the trench separation structure 15 extends.

The width of the trench separation structure 15 may be 0.1 μm or more and 2.5 μm or less. The width of the trench separation structure 15 is preferably 0.3 μm or more and 1 μm or less. The width of the trench separation structure 15 is particularly preferably 0.4 μm or more and 0.7 μm or less. The trench separation structure 15 may have a depth of 1 μm or more and 20 μm or less. The depth of the trench separation structure 15 is preferably 4 μm or more and 10 μm or less.

Hereinafter, the configuration of one trench separation structure 15 is described. The trench separation structure 15 includes a separation trench 16, a separation insulation film 17, and a separation embedded electrode 18. The separation trench 16 is formed in the first main surface 3 and demarcates the wall surface of the trench separation structure 15. The separation insulation film 17 covers a wall surface of the separation trench 16 in a film shape. The separation insulation film 17 may include at least one of a silicon oxide film, a silicon nitride film, and an aluminum oxide film.

The separation insulation film 17 preferably has a single layer structure constituted of a single insulating film. The separation insulation film 17 particularly preferably includes a silicon oxide film that is constituted of the oxide of the chip 2. The separation embedded electrode 18 is embedded in the separation trench 16 with the separation insulation film 17 interposed therebetween. The separation embedded electrode 18 may contain conductive polysilicon. A gate potential is applied to the separation embedded electrode 18.

The semiconductor device 1A includes an IGBT structure Tr (transistor structure) formed in each active region 6. The IGBT structure Tr is not formed in the non-active region 7. Since the configuration on the second active region 6B side (the configuration of the IGBT structure Tr) is substantially the same as the configuration on the first active region 6A side (the configuration of the IGBT structure Tr), the configuration on the first active region 6A side is described below. In this embodiment, the configuration on the second active region 6B side is line-symmetric with the configuration on the first active region 6A side with the boundary region 8 interposed therebetween. The description of the structure on the first active region 6A side is applied to the description of the structure on the second active region 6B side, and the description of the structure on the second active region 6B side is omitted.

The semiconductor device 1A includes a p-type base region 20 formed in a surface layer portion of the first main surface 3 in the first active region 6A. The base region 20 may be referred to as a “body region” or a “channel region.” The base region 20 extends in a layer shape along the first main surface 3 and is connected to the inner peripheral wall of the trench separation structure 15. The base region 20 is formed shallower than the trench separation structure 15 and has a bottom portion positioned on the first main surface 3 side than the bottom wall of the trench separation structure 15. The bottom portion of the base region 20 is preferably positioned closer to the first main surface 3 than the intermediate portion of the trench separation structure 15 in a depth range.

The semiconductor device 1A includes a plurality of first trench structures 21 formed in the first main surface 3 in the first active region 6A. A gate potential is applied to the plurality of first trench structures 21. The first trench structure 21 may be referred to as a “trench gate structure.”

The plurality of first trench structures 21 penetrates through the base region 20 such as to reach the drift region 12. The plurality of first trench structures 21 are arranged at intervals in the first direction X in plan view and are each formed in a band shape extending in the second direction Y. That is, the plurality of first trench structures 21 is arranged in a stripe shape extending in the second direction Y.

Each of the first trench structures 21 has one end portion on the boundary region 8 side and the other end portion on the outer peripheral region 9 side in the long direction (the second direction Y). One end portions and the other end portions of the plurality of first trench structures 21 are mechanically and electrically connected to the trench separation structure 15. That is, the plurality of first trench structures 21 configure one ladder-shaped trench structure together with the trench separation structure 15. The connection portions of the first trench structure 21 and the trench separation structure 15 may be considered a part of the trench separation structure 15 and/or a part of the first trench structure 21.

The interval between the plurality of first trench structures 21 is preferably less than the width of the street region 11. The width of the first trench structure 21 is preferably less than the width of the street region 11. The width of the first trench structure 21 is a width in a direction orthogonal to a direction in which the first trench structure 21 extends.

The width of the first trench structure 21 may be 0.1 μm or more and 2.5 μm or less. The width of the first trench structure 21 is preferably 0.3 μm or more and 1 μm or less. The width of the first trench structure 21 is particularly preferably 0.4 μm or more and 0.7 μm or less. A width of the first trench structure 21 is preferably substantially equal to a width of the trench separation structure 15.

The first trench structure 21 may have a depth of 1 μm or more and 20 μm or less. The depth of the first trench structure 21 is preferably 4 μm or more and 10 μm or less. The depth of the first trench structure 21 is preferably substantially equal to the depth of the trench separation structure 15.

Hereinafter, the configuration of one first trench structure 21 is described. The first trench structure 21 includes a first trench 22, a first insulating film 23, and a first embedded electrode 24. The first trench 22 is formed in the first main surface 3 and demarcates a wall surface of the first trench structure 21. In this embodiment, the first trench 22 communicates with the separation trench 16 in both end portions in the second direction Y. Specifically, the side wall of the first trench 22 communicates with the side wall of the separation trench 16, and the bottom wall of the first trench 22 communicates with the bottom wall of the separation trench 16.

The first insulating film 23 covers a wall surface of the first trench 22 in a film shape. The first insulating film 23 may include at least one of a silicon oxide film, a silicon nitride film, and an aluminum oxide film. The first insulating film 23 preferably has a single layer structure constituted of a single insulating film.

The first insulating film 23 particularly preferably includes a silicon oxide film that is constituted of the oxide of the chip 2. In this embodiment, the first insulating film 23 is constituted of the same insulating film as the separation insulation film 17. The first insulating film 23 is connected to the separation insulation film 17 in communication portions of the separation trench 16 and the first trench 22.

The first embedded electrode 24 is embedded in the first trench 22 with the first insulating film 23 interposed therebetween. The first embedded electrode 24 may contain conductive polysilicon. A gate potential is applied to the first embedded electrode 24. The first embedded electrode 24 is mechanically and electrically connected to the separation embedded electrode 18 in communication portions of the separation trench 16 and the first trench 22.

The semiconductor device 1A includes a plurality of second trench structures 25 each formed in a region between the plurality of first trench structures 21 on the first main surface 3 of the first active region 6A. The second trench structure 25 may be referred to as an “emitter trench structure.” Each second trench structure 25 is formed at an interval in the first direction X from the plurality of first trench structures 21 in plan view and is formed in a quadrangular annular shape extending in the second direction Y.

The width of the second trench structure 25 is preferably less than the width of the street region 11. The width of the second trench structure 25 is a width in a direction orthogonal to a direction in which the second trench structure 25 extends.

The width of the second trench structure 25 may be 0.1 μm or more and 2.5 μm or less. The width of the second trench structure 25 is preferably 0.3 μm or more and 1 μm or less. The width of the second trench structure 25 is particularly preferably 0.4 μm or more and 0.7 μm or less. The width of the second trench structure 25 is preferably substantially equal to a width of the first trench structure 21.

The second trench structure 25 may have a depth of 1 μm or more and 20 μm or less. The depth of the second trench structure 25 is preferably 4 μm or more and 10 μm or less. The depth of the second trench structure 25 is preferably substantially equal to the depth of the first trench structure 21.

Hereinafter, the configuration of one second trench structure 25 is described. The second trench structure 25 includes a second trench 26, a second insulating film 27, and a second embedded electrode 28. The second trench 26 is formed in the first main surface 3 and demarcates a wall surface of the second trench structure 25.

The second insulating film 27 covers a wall surface of the second trench 26 in a film shape. The second insulating film 27 may include at least one of a silicon oxide film, a silicon nitride film, and an aluminum oxide film. The second insulating film 27 preferably has a single layer structure constituted of a single insulating film. The second insulating film 27 particularly preferably includes a silicon oxide film that is constituted of the oxide of the chip 2. In this embodiment, the second insulating film 27 is constituted of the same insulating film as the first insulating film 23.

The second embedded electrode 28 is embedded in the second trench 26 with the second insulating film 27 interposed therebetween. The second embedded electrode 28 may contain conductive polysilicon. An emitter potential is applied to the second embedded electrode 28.

The semiconductor device 1A includes a plurality of n-type emitter regions 29 formed in a surface layer portion of the base region 20 in the first active region 6A. Each of the plurality of emitter regions 29 has a higher n-type impurity concentration than that of the drift region 12. The plurality of emitter regions 29 are formed on both sides of the plurality of first trench structures 21, respectively.

The plurality of emitter regions 29 may respectively be each formed in a band shape extending along the plurality of first trench structures 21 in plan view. As a matter of course, the plurality of emitter regions 29 may be formed at intervals along the plurality of first trench structures 21 in plan view.

In this embodiment, the plurality of emitter regions 29 are formed in the region between the first trench structure 21 and the second trench structure 25 such as to be connected to the first trench structure 21 and the second trench structure 25. The emitter region 29 is preferably not formed in a region between the trench separation structure 15 and the outermost first trench structure 21.

The semiconductor device 1A includes a plurality of contact holes 30 formed in the first main surface 3 such as to expose the emitter region 29 in the first active region 6A. The plurality of contact holes 30 are formed on both sides of the plurality of first trench structures 21 at intervals from the plurality of first trench structures 21, respectively. Each of the plurality of contact holes 30 may be formed in a tapered shape in which the opening width narrows from the opening toward the bottom wall.

The plurality of contact holes 30 may be separated from the bottom portion of the emitter region 29 toward the first main surface 3 side such as not to reach the base region 20. As a matter of course, the plurality of contact holes 30 may penetrate through the emitter region 29 such as to reach the base region 20.

The plurality of contact holes 30 are each formed in a band shape extending along the plurality of first trench structures 21 in plan view. The plurality of contact holes 30 are preferably shorter than the plurality of first trench structures 21 in the long direction (the second direction Y). The plurality of contact holes 30 are particularly preferably shorter than the plurality of second trench structures 25.

The semiconductor device 1A includes a plurality of p-type contact regions 31 formed in a region different from the plurality of emitter regions 29 in the surface layer portion of the base region 20 of the first active region 6A. The plurality of contact regions 31 has a higher p-type impurity concentration than that of the base region 20. Each of the plurality of contact regions 31 is formed in a band shape extending along the corresponding contact hole 30 in plan view. Bottom portions of the plurality of contact regions 31 are respectively formed in a region between the bottom wall of the corresponding contact hole 30 and the bottom portion of the base region 20.

The semiconductor device 1A includes a plurality of p-type floating regions 32 each formed in a region surrounded by the plurality of second trench structures 25 in the surface layer portion of the first main surface 3 of the first active region 6A. The plurality of floating regions 32 are formed in an electrically floating state. As a matter of course, an emitter potential may be applied to the plurality of floating regions 32. The plurality of floating regions 32 preferably have a higher p-type impurity concentration than that of the base region 20.

Each floating region 32 extends in a layer shape along the first main surface 3 and is connected to the inner peripheral wall of each second trench structure 25. Each floating region 32 is preferably formed to be deeper than the intermediate portion of the second trench structure 25 in the depth range. In this embodiment, each floating region 32 is formed to be deeper than the second trench structure 25 and has a portion that covers the bottom wall of the second trench structure 25.

As described above, the first active region 6A includes, as the IGBT structure Tr, the base region 20, the plurality of first trench structures 21, the plurality of second trench structures 25, the plurality of emitter regions 29, the plurality of contact holes 30, the plurality of contact regions 31, and the plurality of floating regions 32.

Also, similarly to the first active region 6A, the second active region 6B includes, as the IGBT structure Tr, the base region 20, the plurality of first trench structures 21, the plurality of second trench structures 25, the plurality of emitter regions 29, the plurality of contact holes 30, the plurality of contact regions 31, and the plurality of floating regions 32.

The semiconductor device 1A includes a p-type boundary well region 40 formed in a surface layer portion of the first main surface 3 in the boundary region 8. In this embodiment, the boundary well region 40 has a higher p-type impurity concentration than that of the base region 20. As a matter of course, the boundary well region 40 may have a lower p-type impurity concentration than that of the base region 20.

The boundary well region 40 is formed in a band shape extending along the boundary region 8 in the first direction X in plan view. That is, the boundary well region 40 is formed in a layer shape extending along the first main surface 3 in a region interposed between the first trench separation structure 15A and the second trench separation structure 15B and is exposed from the first main surface 3. The boundary well region 40 is formed in a region interposed between the plurality of first trench structures 21 on the first active region 6A side and the plurality of first trench structures 21 on the second active region 6B side.

The boundary well region 40 includes a first boundary well region 40A formed in the pad region 10 and a second boundary well region 40B formed in the street region 11. The first boundary well region 40A has a comparatively large region width in the second direction Y. The first boundary well region 40A is formed in a polygonal shape (the quadrangular shape in this embodiment) in plan view. The first boundary well region 40A is preferably formed in the entire pad region 10.

The second boundary well region 40B has a region width smaller than the region width of the first boundary well region 40A in the second direction Y and is led out in a band shape from the first boundary well region 40A toward the street region 11. In this embodiment, the second boundary well region 40B is positioned on a straight line crossing the center of the first main surface 3 in the first direction X. The second boundary well region 40B extends in a band shape such as to be positioned in a region on one side (the third side surface 5C side) and a region on the other side (the fourth side surface 5D side) in the first direction X with respect to a straight line crossing the center of the first main surface 3 in the second direction Y.

The boundary well region 40 is preferably formed to be deeper than the base region 20. The boundary well region 40 is particularly preferably formed to be deeper than the plurality of trench separation structures 15 (the plurality of first trench structures 21). In this embodiment, the boundary well region 40 has a width larger than the width of the boundary region 8 in the second direction Y and is led out from the boundary region 8 into the plurality of active regions 6.

The boundary well region 40 is connected to the plurality of trench separation structures 15 adjacent in the second direction Y. The boundary well region 40 has a portion that covers the bottom walls of the plurality of trench separation structures 15. The boundary well region 40 has a portion that covers the bottom walls of the plurality of first trench structures 21 across the plurality of trench separation structures 15.

The boundary well region 40 covers the side wall of the trench separation structure 15 and the side walls of the plurality of trench structures in the plurality of active regions 6 and is connected to each base region 20 in the surface layer portion of the first main surface 3. The depth of the boundary well region 40 may be 1 μm or more and 20 μm or less. The depth of the boundary well region 40 is preferably 5 μm or more and 10 μm or less.

The semiconductor device 1A includes a p-type outer peripheral well region 41 formed in a surface layer portion of the first main surface 3 in the outer peripheral region 9. In this embodiment, the outer peripheral well region 41 has a higher p-type impurity concentration than that of the base region 20. As a matter of course, the outer peripheral well region 41 may have a lower p-type impurity concentration than that of the base region 20. The p-type impurity concentration of the outer peripheral well region 41 is preferably substantially equal to the p-type impurity concentration of the boundary well region 40.

The outer peripheral well region 41 is formed in a layer extending along the first main surface 3 and is exposed from the first main surface 3. The outer peripheral well region 41 is formed at an interval inward from the peripheral edges (first to fourth side surfaces 5A to 5D) of the first main surface 3. The outer peripheral well region 41 is formed in a band shape extending along the plurality of active regions 6 in plan view. In this embodiment, the outer peripheral well region 41 is formed in an annular shape (quadrangular annular shape in this embodiment) collectively surrounding the plurality of active regions 6 in plan view.

The outer peripheral well region 41 is preferably formed to be deeper than the base region 20. The outer peripheral well region 41 is particularly preferably formed to be deeper than the plurality of trench separation structures 15 (the plurality of first trench structures 21). The outer peripheral well region 41 preferably has a depth substantially equal to that of the boundary well region 40.

The outer peripheral well region 41 is connected to the plurality of trench separation structures 15. The outer peripheral well region 41 has a portion that covers the bottom walls of the plurality of trench separation structures 15. The outer peripheral well region 41 is led out from the outer peripheral region 9 into the plurality of active regions 6. The outer peripheral well region 41 has a portion that covers the bottom walls of the plurality of first trench structures 21 across the plurality of trench separation structures 15.

The outer peripheral well region 41 covers the side wall of the trench separation structure 15 and the side walls of the plurality of first trench structures 21 in each active region 6 and is connected to the plurality of base regions 20 in the surface layer portion of the first main surface 3. The outer peripheral well region 41 is connected to the boundary well region 40 in a connection portion between the boundary region 8 and the outer peripheral region 9. That is, the outer peripheral well region 41 demarcates the plurality of active regions 6 together with the boundary well region 40.

With reference to FIG. 10, the semiconductor device 1A includes at least one p-type field region 42 (in this embodiment, a plurality of p-type field regions 42) formed in the surface layer portion of the first main surface 3 in the outer peripheral region 9. The number of the field regions 42 is arbitrary and may be 1 or more and 20 or less (typically 3 or more and 10 or less).

The plurality of field regions 42 may have a higher p-type impurity concentration than that of the base region 20. The plurality of field regions 42 may have a higher p-type impurity concentration than that of the outer peripheral well region 41. The plurality of field regions 42 may have a lower p-type impurity concentration than that of the outer peripheral well region 41. The plurality of field regions 42 may have a p-type impurity concentration equal to that of the outer peripheral well region 41. The plurality of field regions 42 are formed in an electrically floating state.

The plurality of field regions 42 are formed in a region between the peripheral edge of the chip 2 and the outer peripheral well region 41 at intervals from the peripheral edge of chip 2 and the outer peripheral well region 41. The plurality of field regions 42 is formed in a band shape extending along the outer peripheral well region 41 in plan view. In this embodiment, the plurality of field regions 42 are formed in annular shapes (quadrangular annular shapes) surrounding the outer peripheral well region 41 in plan view.

The plurality of field regions 42 is preferably formed to be deeper than the base region 20. The plurality of field regions 42 may be formed in the depth substantially equal to that of the outer peripheral well region 41. The plurality of field regions 42 may be formed to be shallower than the outer peripheral well region 41. The plurality of field regions 42 may be formed at a constant depth.

The interval between the plurality of field regions 42 may gradually increase toward the peripheral edge side of the chip 2. Each of the plurality of field regions 42 has a width smaller than the width of the outer peripheral well region 41. The outermost field region 42 among the plurality of field regions 42 may be formed to be wider than the other field regions 42.

The semiconductor device 1A includes an n-type channel stop region 43 formed in the surface layer portion of the first main surface 3 at an interval from the plurality of field regions 42 toward the peripheral edge side of the chip 2 in the outer peripheral region 9. The channel stop region 43 has a higher n-type impurity concentration than that of the drift region 12.

The channel stop region 43 is formed in a band shape extending along the peripheral edge of the chip 2 in plan view. In this embodiment, the channel stop region 43 is formed in annular shapes (quadrangular annular shapes) surrounding the plurality of field regions 42 in plan view. The channel stop region 43 may be exposed from the first to fourth side surfaces 5A to 5D. The channel stop region 43 is formed in an electrically floating state.

The semiconductor device 1A includes a main surface insulating film 45 selectively covering the first main surface 3. The main surface insulating film 45 selectively covers the first main surface 3 in the active region 6, the boundary region 8, and the outer peripheral region 9. The main surface insulating film 45 may include at least one of a silicon oxide film, a silicon nitride film, and an aluminum oxide film.

The main surface insulating film 45 preferably has a single layer structure constituted of a single insulating film. The main surface insulating film 45 particularly preferably includes a silicon oxide film that is constituted of the oxide of the chip 2. In this embodiment, the main surface insulating film 45 is constituted of the same insulating film as the first insulating film 23 (separation insulation film 17). The main surface insulating film 45 covers the first main surface 3 such as to expose the trench separation structure 15, the first trench structure 21, and the second trench structure 25.

Specifically, the main surface insulating film 45 is connected to the separation insulation film 17, the first insulating film 23, and the second insulating film 27 and exposes the separation embedded electrode 18, the first embedded electrode 24, and the second embedded electrode 28. The main surface insulating film 45 selectively covers the boundary well region 40, the outer peripheral well region 41, the field region 42, and the channel stop region 43 in the boundary region 8 and the outer peripheral region 9.

The main surface insulating film 45 is formed at an interval inward from the peripheral edge of the first main surface 3 and demarcates a removed portion 46 that exposes the peripheral edge portion of the first main surface 3. The removed portion 46 exposes the channel stop region 43 in the peripheral edge portion of the first main surface 3. The removed portion 46 is formed in a band shape extending along the peripheral edges (first to fourth side surfaces 5A to 5D) of the first main surface 3. In this embodiment, the removed portion 46 is formed in an annular shape extending along the peripheral edge of the first main surface 3.

With reference to FIGS. 3 and 6, the semiconductor device 1A includes a plurality of emitter electrode films 47 arranged on the first main surface 3 such as to cover the plurality of second trench structures 25 in the active region 6. Specifically, the plurality of emitter electrode films 47 are arranged on the main surface insulating film 45. The plurality of emitter electrode films 47 may contain conductive polysilicon.

The plurality of emitter electrode films 47 cover both end portions of the plurality of second trench structures 25 in the second direction Y, respectively. In this embodiment, the plurality of emitter electrode films 47 are formed in a band shape extending in the second direction Y in a region between the corresponding second trench structure 25 and the trench separation structure 15. The plurality of emitter electrode films 47 are formed at intervals from the trench separation structure 15 toward the second trench structure 25 side. The plurality of emitter electrode films 47 face the base region 20 with the main surface insulating film 45 interposed therebetween.

The plurality of emitter electrode films 47 are formed integrally with the second embedded electrode 28 of the plurality of second trench structures 25, respectively. That is, each of the plurality of emitter electrode films 47 includes a portion where a part of the second embedded electrode 28 is led out in a film shape onto the first main surface 3 (the main surface insulating film 45). As a matter of course, the plurality of emitter electrode films 47 may be formed separately from the second embedded electrode 28.

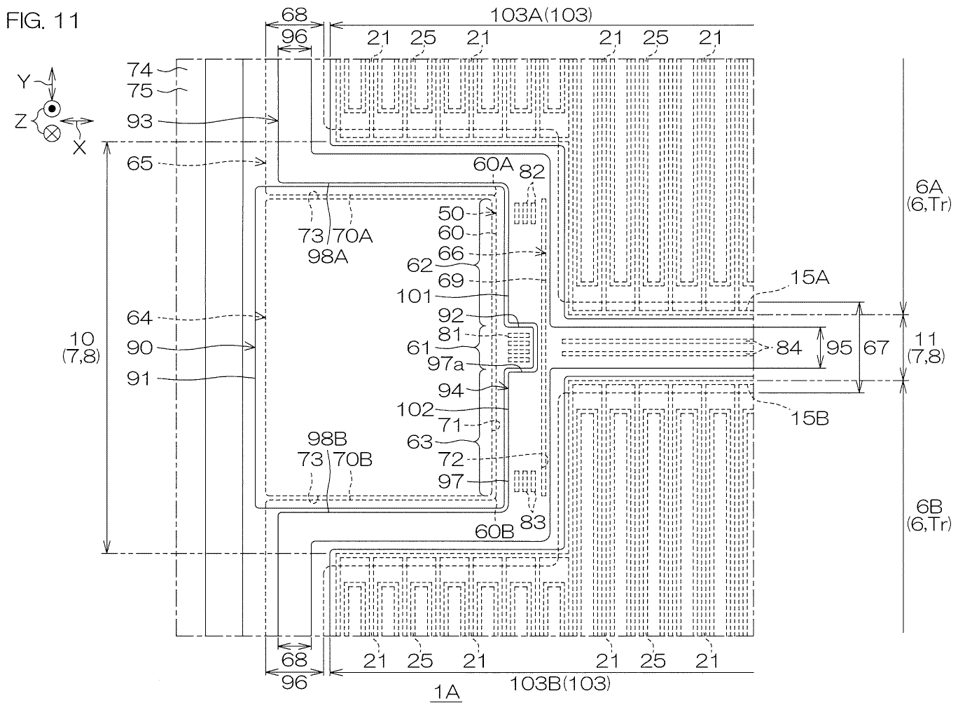

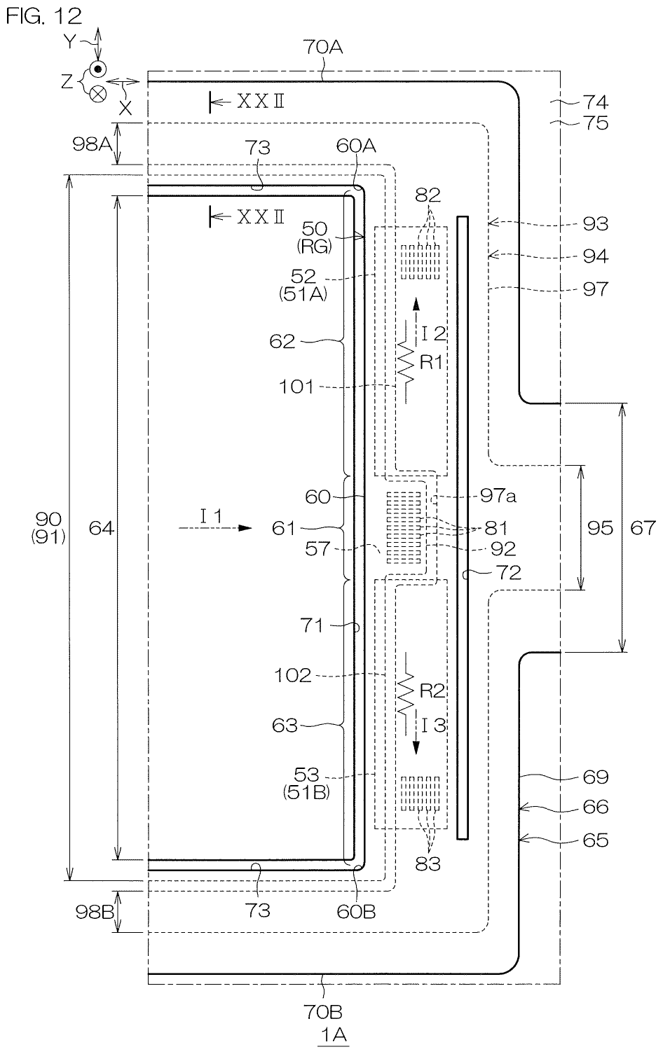

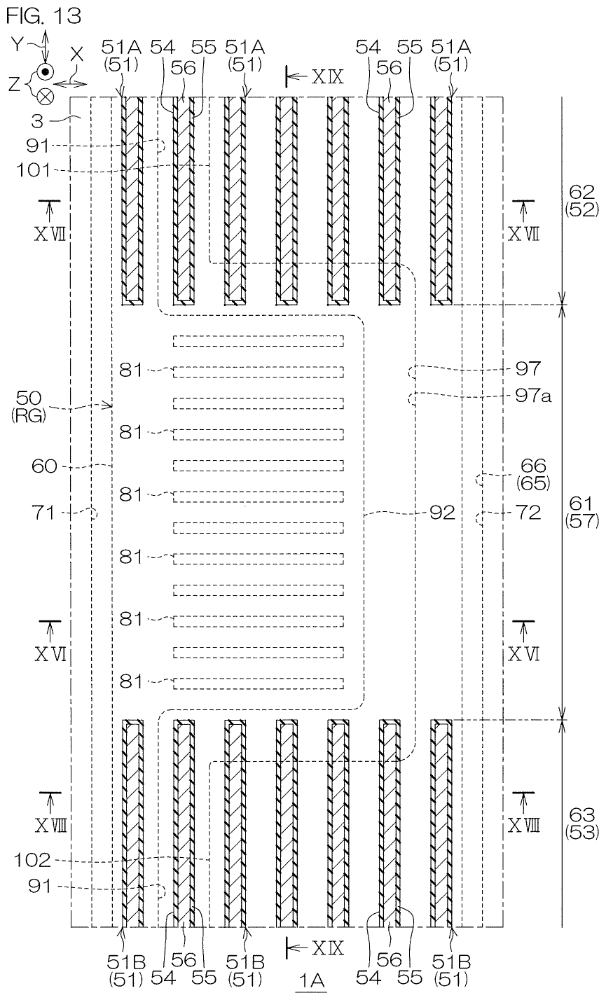

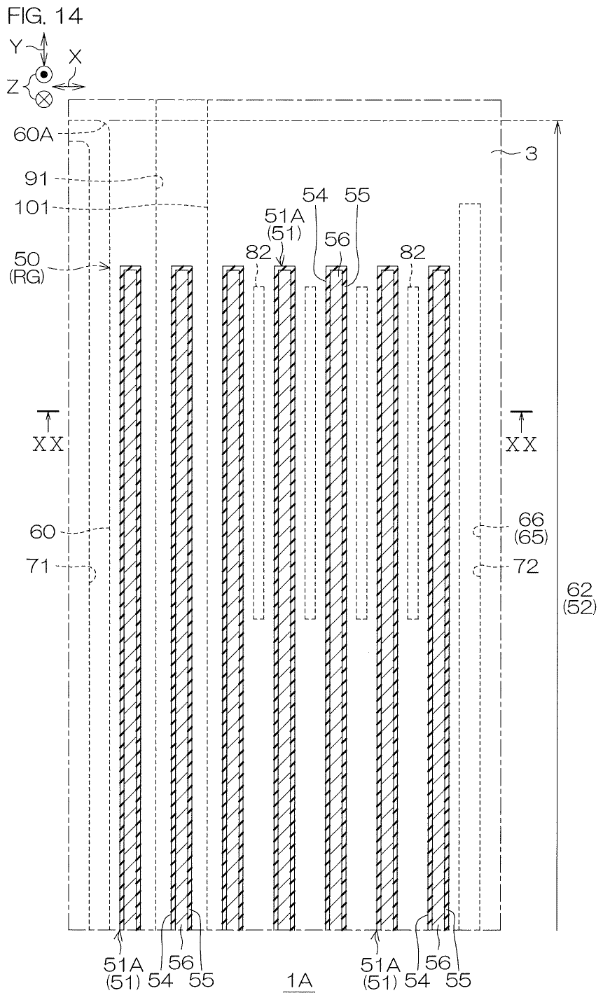

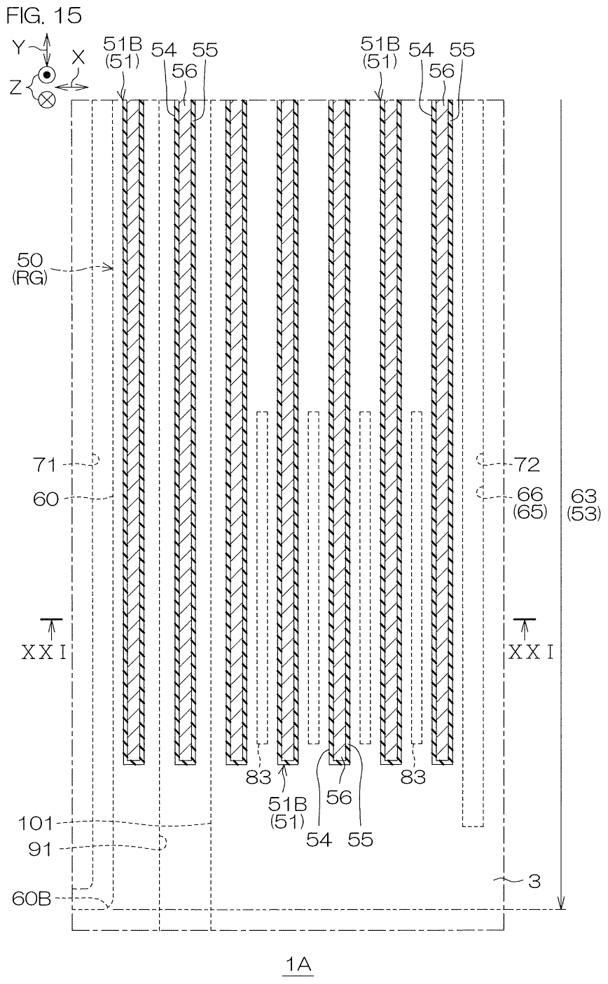

FIG. 11 is an enlarged plan view illustrating the pad region 10. FIG. 12 is an enlarged plan view illustrating a gate resistive structure 50 illustrated in FIG. 11. FIG. 13 is an enlarged plan view illustrating an inner portion of the gate resistive structure 50 illustrated in FIG. 12. FIG. 14 is an enlarged plan view illustrating one end portion of the gate resistive structure 50 illustrated in FIG. 12. FIG. 15 is an enlarged plan view illustrating the other end portion of the gate resistive structure 50 illustrated in FIG. 12.

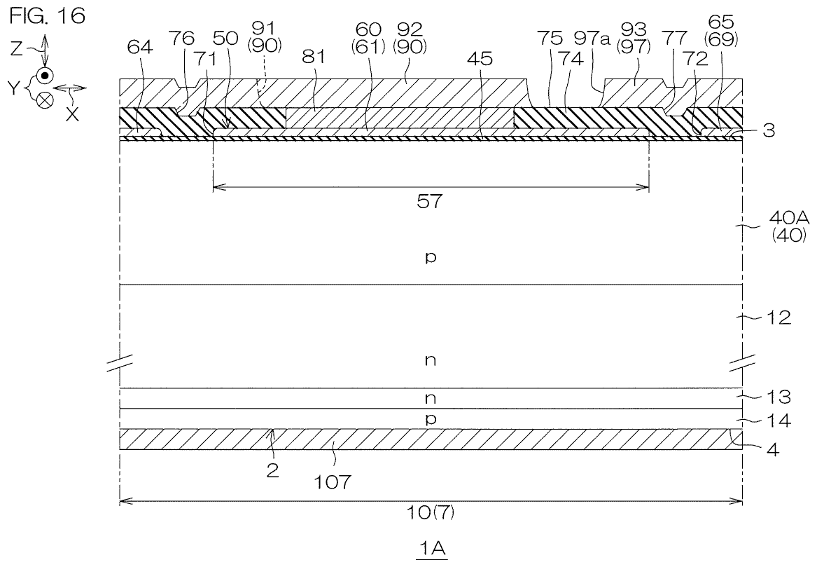

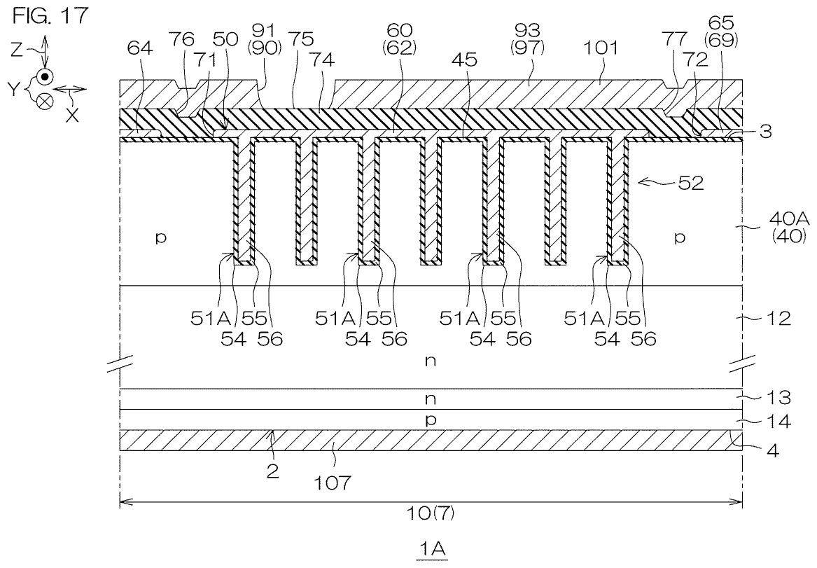

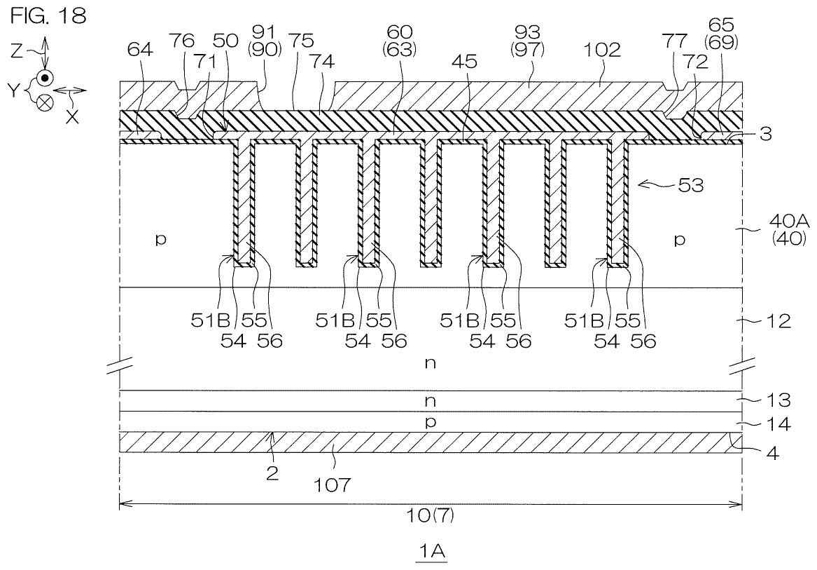

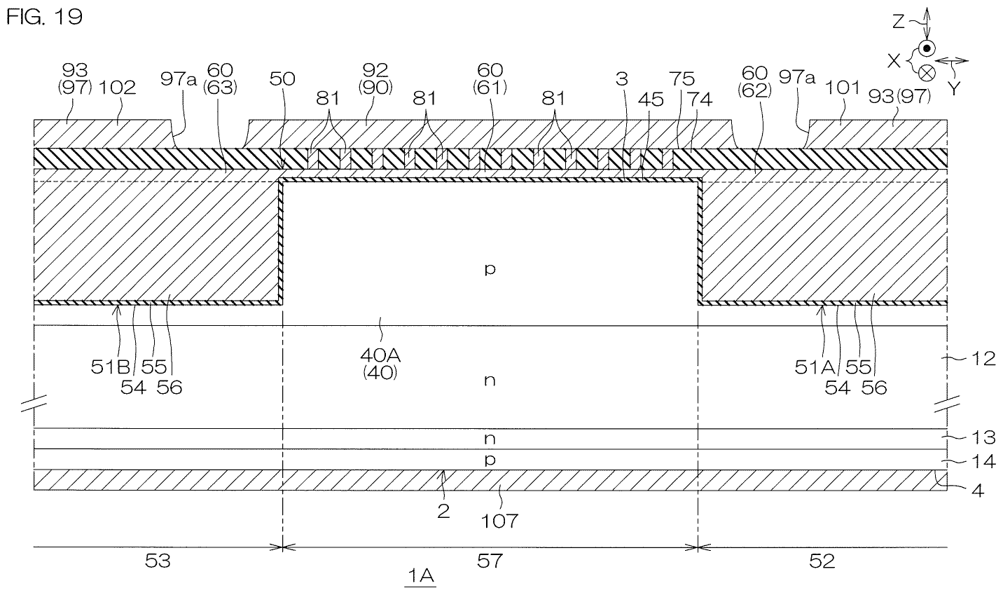

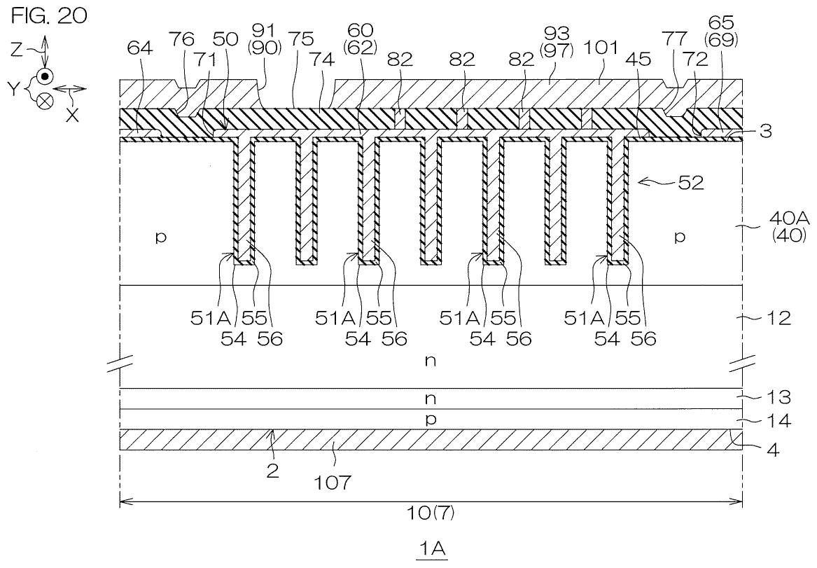

FIG. 16 is a cross-sectional view taken along line XVI-XVI illustrated in FIG. 13. FIG. 17 is a cross-sectional view taken along line XVII-XVII illustrated in FIG. 13. FIG. 18 is a cross-sectional view taken along line XVIII-XVIII illustrated in FIG. 13. FIG. 19 is a cross-sectional view taken along line XIX-XIX illustrated in FIG. 13. FIG. 20 is a cross-sectional view taken along line XX-XX illustrated in FIG. 14.

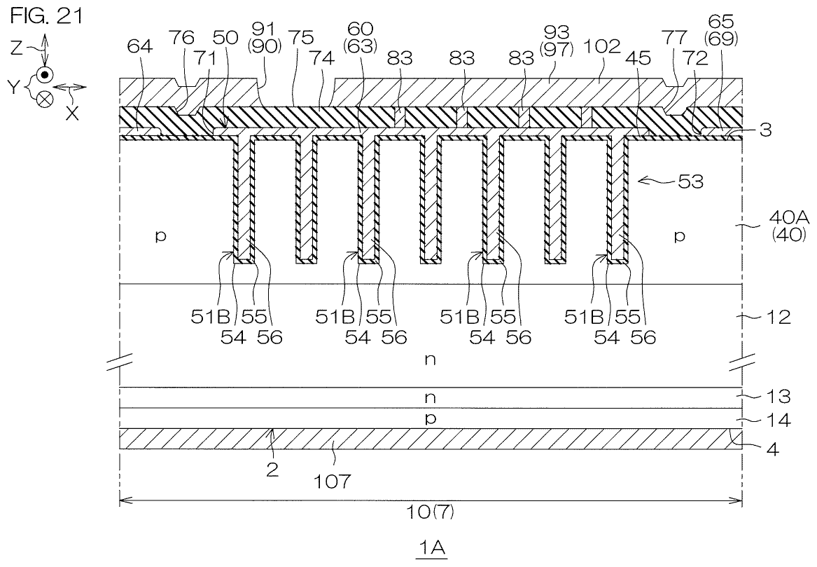

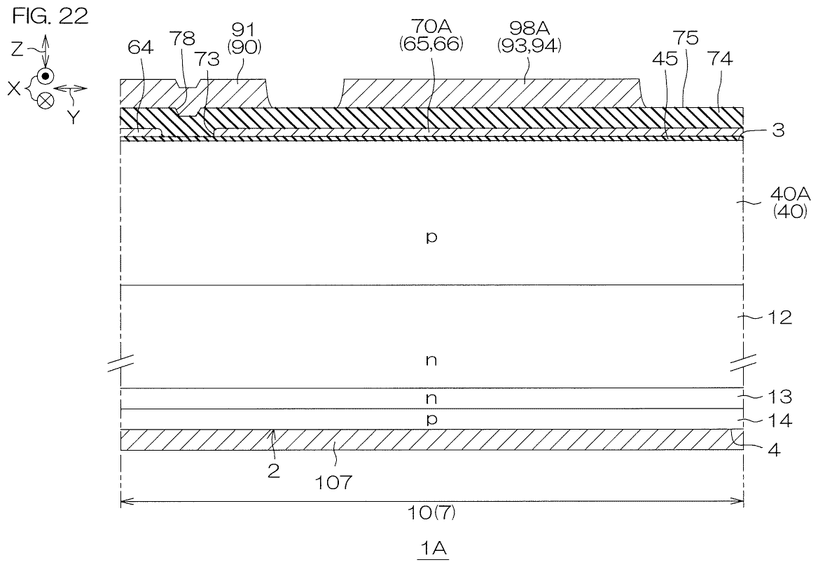

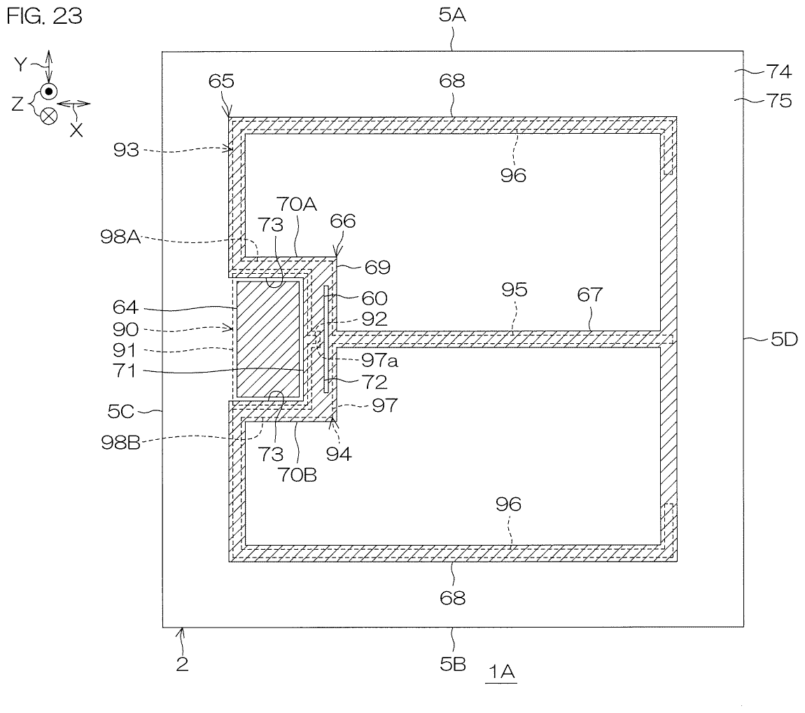

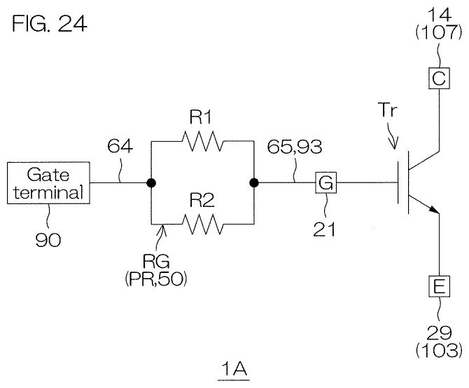

FIG. 21 is a cross-sectional view taken along line XXI-XXI illustrated in FIG. 15. FIG. 22 is a cross-sectional view taken along line XXII-XXII illustrated in FIG. 12. FIG. 23 is a plan view illustrating a layout of a resistive film 60, a gate electrode film 64, and a gate wiring film 65. FIG. 24 is an electric circuit diagram illustrating the gate resistive structure 50, a gate terminal electrode 90, and a gate wiring electrode 93.

With reference to FIGS. 11 to 24, the semiconductor device 1A includes the gate resistive structure 50 formed in the pad region 10. The gate resistive structure 50 configures a gate resistance RG for the gate of the IGBT (the first trench structure 21 of the IGBT structure Tr). For example, the gate resistance RG (gate resistive structure 50) is effective in suppressing oscillation (noise) caused by parasitic inductance at turn-off.

The gate resistive structure 50 includes a plurality of trench resistive structures 51 formed in the first main surface 3 in the pad region 10. A gate potential is applied to the plurality of trench resistive structures 51, however, the plurality of trench resistive structures 51 do not contribute to control of the channel.

In this embodiment, the plurality of gate resistive structures 50 configure a first trench group 52 and a second trench group 53. The first trench group 52 includes a plurality of first trench resistive structures 51A that configure a part of the plurality of trench resistive structures 51 and is provided on one side (the first side surface 5A side) in the second direction Y. The number of the first trench resistive structures 51A is arbitrary and is adjusted based on a resistance to be achieved.

For example, the first trench group 52 may include 2 or more and 100 or less first trench resistive structures 51A. The number of the first trench resistive structures 51A is preferably 50 or less. The number of the first trench resistive structures 51A may be 25 or less. The number of the first trench resistive structures 51A is preferably 5 or more. As a matter of course, the gate resistive structure 50 may include the single first trench resistive structure 51A instead of the first trench group 52.

In this embodiment, the first trench group 52 is provided in a region on one side (the first side surface 5A side) in the second direction Y with respect to a straight line crossing the center of the first main surface 3 in the first direction X. The first trench group 52 is preferably arranged such as to be locally concentrated on the active region 6 side (the street region 11 side) with respect to the outer peripheral region 9 in the pad region 10.

In this embodiment, the first trench group 52 is arranged at an interval from the central portion of the pad region 10 toward the active region 6 side (the street region 11 side). These configurations are effective in suppressing electric field concentration on the plurality of first trench resistive structures 51A.

The plurality of first trench resistive structures 51A are formed in the first main surface 3 at intervals from the plurality of trench separation structures 15 (the plurality of first trench structures 21). The plurality of first trench resistive structures 51A are arranged at intervals in the first direction X in plan view and are each formed in a band shape extending in the second direction Y.

That is, the plurality of first trench resistive structures 51A are arranged in a stripe shape extending in the second direction Y. The plurality of first trench resistive structures 51A have one end portion on one side (the first side surface 5A side) in the second direction Y and the other end portion on the other side (the second side surface 5B side) in the second direction Y.

The plurality of first trench resistive structures 51A are formed at intervals from the bottom portion of the boundary well region 40 (first boundary well region 40A) toward the first main surface 3 side such as to be positioned in the boundary well region 40 (first boundary well region 40A) and face the drift region 12 with a part of the boundary well region 40 interposed therebetween. That is, the plurality of first trench resistive structures 51A do not penetrate through the boundary well region 40 (first boundary well region 40A).

The interval between the plurality of first trench resistive structures 51A is preferably less than the width of the street region 11. The interval between the plurality of first trench resistive structures 51A is preferably substantially equal to the interval between the first trench structure 21 and the second trench structure 25. The interval between the plurality of first trench resistive structures 51A may be smaller than the interval between the first trench structure 21 and the second trench structure 25. The interval between the plurality of first trench resistive structures 51A may be larger than the interval between the first trench structure 21 and the second trench structure 25.

The width of the first trench resistive structure 51A is preferably less than the width of the street region 11. The width of the first trench resistive structure 51A is a width in a direction orthogonal to a direction in which the first trench resistive structure 51A extends.

The width of the first trench resistive structure 51A may be 0.1 μm or more and 2.5 μm or less. The width of the first trench resistive structure 51A is preferably 0.3 μm or more and 1 μm or less. The width of the first trench resistive structure 51A is particularly preferably 0.4 μm or more and 0.7 μm or less. The width of the first trench resistive structure 51A is preferably substantially equal to a width of the first trench structure 21.

The first trench resistive structure 51A may have a depth of 1 μm or more and 20 μm or less. The depth of the first trench resistive structure 51A is preferably 4 μm or more and 10 μm or less. The depth of the first trench resistive structure 51A is preferably substantially equal to the depth of the first trench structure 21.

The second trench group 53 includes a plurality of second trench resistive structures 51B that configure a part of the plurality of trench resistive structures 51 and is provided at an interval from the first trench group 52 on the other side (the second side surface 5B side) in the second direction Y. The number of the second trench resistive structures 51B is arbitrary and is adjusted based on a resistance to be achieved. For example, when a resistance substantially equal to the resistance on the first trench group 52 side is realized, the second trench group 53 may include the second trench resistive structures 51B of the same number as the number of the first trench resistive structure 51A.

For example, when a resistance different from the resistance on the first trench group 52 side is realized, the second trench group 53 may include second trench resistive structures 51B of a different number from the number of first trench resistive structures 51A.

For example, when the resistance on the second trench group 53 side is larger than the resistance on the first trench group 52 side, the number of the second trench resistive structures 51B may be smaller than the number of the first trench resistive structures 51A. For example, when the resistance on the second trench group 53 side is less than the resistance on the first trench group 52 side, the number of the second trench resistive structures 51B may be larger than the number of the first trench resistive structures 51A.

For example, the second trench group 53 may include 2 or more and 100 or less second trench resistive structures 51B. The number of the second trench resistive structures 51B is preferably 50 or less. The number of the second trench resistive structures 51B may be 25 or less. The number of the second trench resistive structures 51B is preferably 5 or more. As a matter of course, the semiconductor device 1A may include the single second trench resistive structure 51B instead of the second trench group 53.

In this embodiment, the second trench group 53 is provided in a region on the other side (the second side surface 5B side) in the second direction Y with respect to a straight line crossing the center of the first main surface 3 in the first direction X. The second trench group 53 faces the first trench group 52 in the second direction Y.

The second trench group 53 is preferably arranged such as to be locally concentrated on the active region 6 side (the street region 11 side) with respect to the outer peripheral region 9 in the pad region 10. In this embodiment, the second trench group 53 is arranged at an interval from the central portion of the pad region 10 toward the active region 6 side (the street region 11 side). These configurations are effective in suppressing electric field concentration on the plurality of second trench resistive structures 51B.

The plurality of second trench resistive structures 51B are formed in the first main surface 3 at intervals from the plurality of trench separation structures 15 (the plurality of first trench structures 21). The plurality of second trench resistive structures 51B are arranged at intervals in the first direction X in plan view and are each formed in a band shape extending in the second direction Y.

That is, the plurality of second trench resistive structures 51B are arranged in a stripe shape extending in the second direction Y. The plurality of second trench resistive structures 51B face the plurality of first trench resistive structures 51A in a one-to-one correspondence relationship in the second direction Y, respectively. That is, the plurality of second trench resistive structures 51B are arranged in the same straight line as the plurality of first trench resistive structures 51A, respectively. The plurality of second trench resistive structures 51B have one end portion on one side (the first side surface 5A side) in the second direction Y and the other end portion on the other side (the second side surface 5B side) in the second direction Y.

The plurality of second trench resistive structures 51B are formed at intervals from the bottom portion of the boundary well region 40 (first boundary well region 40A) toward the first main surface 3 side such as to be positioned in the boundary well region 40 (first boundary well region 40A) and face the drift region 12 with a part of the boundary well region 40 interposed therebetween. That is, the plurality of second trench resistive structures 51B do not penetrate through the boundary well region 40 (first boundary well region 40A).

The interval between the plurality of second trench resistive structures 51B is preferably less than the width of the street region 11. The interval between the plurality of second trench resistive structures 51B is preferably substantially equal to the interval between the adjacent first trench structure 21 and the adjacent second trench structure 25. The interval between the plurality of second trench resistive structures 51B may be smaller than the interval between the first trench structure 21 and the second trench structure 25. The interval between the plurality of second trench resistive structures 51B may be larger than the interval between the first trench structure 21 and the second trench structure 25.

The interval between the plurality of second trench resistive structures 51B may be smaller than the interval between the plurality of first trench resistive structures 51A. The interval between the plurality of second trench resistive structures 51B may be larger than the interval between the plurality of first trench resistive structures 51A. The interval between the plurality of second trench resistive structures 51B is preferably substantially equal to the interval between the plurality of first trench resistive structures 51A.

The width of the second trench resistive structure 51B is preferably less than the width of the street region 11. The width of the second trench resistive structure 51B is a width in a direction orthogonal to a direction in which the second trench resistive structure 51B extends.

The width of the second trench resistive structure 51B may be 0.1 μm or more and 2.5 μm or less. The width of the second trench resistive structure 51B is preferably 0.3 μm or more and 1 μm or less. The width of the second trench resistive structure 51B is particularly preferably 0.4 μm or more and 0.7 μm or less. The width of the second trench resistive structure 51B is preferably substantially equal to a width of the first trench resistive structure 51A.

In this embodiment, the second trench resistive structure 51B has a length substantially equal to the length of the first trench resistive structure 51A in the second direction Y. As a matter of course, the second trench resistive structure 51B may be longer than the first trench resistive structure 51A in the second direction Y. Also, the second trench resistive structure 51B may be shorter than the first trench resistive structure 51A in the second direction Y. The length of the first trench resistive structure 51A and the length of the second trench resistive structure 51B are adjusted according to the resistance to be achieved.

The second trench resistive structure 51B may have a depth of 1 μm or more and 20 μm or less. The depth of the second trench resistive structure 51B is preferably 4 μm or more and 10 μm or less. The depth of the second trench resistive structure 51B is preferably substantially equal to the depth of the first trench resistive structure 51A (first trench structure 21).

Hereinafter, the configuration of one trench resistive structure 51 (the first trench resistive structure 51A or the second trench resistive structure 51B) is described. The trench resistive structure 51 includes a resistance trench 54, a resistance insulation film 55, and a resistance embedded electrode 56. The resistance trench 54 is formed in the first main surface 3 and demarcates the wall surface of the trench resistive structure 51.

The resistance insulation film 55 covers a wall surface of the resistance trench 54 in a film shape. The resistance insulation film 55 is connected to the main surface insulating film 45 on the first main surface 3. The resistance insulation film 55 may include at least one of a silicon oxide film, a silicon nitride film, and an aluminum oxide film. The resistance insulation film 55 preferably has a single layer structure constituted of a single insulating film. The resistance insulation film 55 particularly preferably includes a silicon oxide film that is constituted of the oxide of the chip 2.

The resistance embedded electrode 56 is embedded in the resistance trench 54 with the resistance insulation film 55 interposed therebetween. The resistance embedded electrode 56 may contain conductive polysilicon. A gate potential is applied to the resistance embedded electrode 56.

In this embodiment, the gate resistive structure 50 includes a space region 57 demarcated in the pad region 10 to a region between the first trench group 52 and the second trench group 53. The space region 57 is formed by a flat portion of the first main surface 3 in a region between the other end portions of the plurality of first trench resistive structures 51A and one end portions of the plurality of second trench resistive structures 51B.

In this embodiment, the space region 57 is demarcated into a quadrangular shape in plan view. The space region 57 exposes the boundary well region 40 from the first main surface 3. In this embodiment, the space region 57 is formed in a straight line crossing the center of the first main surface 3 in the first direction X in plan view and faces the street region 11 in the first direction X.

The space region 57 has a space width along the second direction Y. The space width is larger than the width of the first trench resistive structure 51A (the second trench resistive structure 51B) in the first direction X. The space width is larger than the interval between two first trench resistive structures 51A (second trench resistive structures 51B) adjacent to each other in the first direction X. The space width is preferably larger than the width of the first trench group 52 (second trench group 53) in the first direction X. The space width may be smaller than the width of the first trench group 52 (second trench group 53) in the first direction X.

The space width is preferably smaller than the length of the first trench group 52 (second trench group 53) in the second direction Y. The space width may be substantially equal to the width of the street region 11 in the second direction Y. The space width may be larger than the width of the street region 11 in the second direction Y. The space width may be smaller than the width of the street region 11 in the second direction Y.

The gate resistive structure 50 includes the resistive film 60 arranged on the first main surface 3 such as to cover the plurality of trench resistive structures 51 in the pad region 10. Specifically, the resistive film 60 is arranged on the main surface insulating film 45. The resistive film 60 includes at least one of a conductive polysilicon film and an alloy film.

The alloy film may include an alloy crystal constituted of a metal element and a non-metal element. The alloy film may include at least one of a CrSi film, a CrSiN film, a CrSiO film, a TaN film, and a TiN film. In this embodiment, the resistive film 60 contains a conductive polysilicon.

The thickness of the resistive film 60 is adjusted as appropriate in accordance with the resistance to be attained. The thickness of the resistive film 60 is preferably equal to or less than the depth of the first trench resistive structure 51A (second trench resistive structure 51B). The thickness of the resistive film 60 is particularly preferably less than the depth of the first trench resistive structure 51A (second trench resistive structure 51B).

The thickness of the resistive film 60 is preferably 0.5 times or more the width of the first trench resistive structure 51A (second trench resistive structure 51B). The thickness of the resistive film 60 may be 0.05 μm or more and 2.5 μm or less. The thickness of the resistive film 60 is preferably 0.5 μm or more and 1.5 μm or less. When the resistive film 60 is constituted of an alloy film, the thickness of the resistive film 60 may be 0.1 nm or more and 100 nm or less.

The resistive film 60 is formed in a band shape extending in the second direction Y and has a first end portion 60A on one side (the first side surface 5A side) in the second direction Y and a second end portion 60B on the other side (the second side surface 5B side) in the second direction Y. The resistive film 60 has a width larger than the width of the first trench group 52 (second trench group 53) in the first direction X with respect to the first direction X. The width of the resistive film 60 may be less than the space width. As a matter of course, the width of the resistive film 60 may be equal to or larger than the space width. The resistive film 60 preferably has a uniform width in the first direction X.

The resistive film 60 has a portion positioned on one side (the first side surface 5A side) in the second direction Y and a portion positioned on the other side (the second side surface 5B side) with respect to a straight line crossing the center of the first main surface 3 in the first direction X. The resistive film 60 faces the first active region 6A, the second active region 6B, and the street region 11 in the first direction X. That is, the resistive film 60 faces the plurality of trench separation structures 15, the plurality of first trench structures 21, and the plurality of second trench structures 25 in the first direction X.

The resistive film 60 includes a first covering portion 61 that covers the space region 57, a second covering portion 62 that covers the first trench group 52, and a third covering portion 63 that covers the second trench group 53. The first covering portion 61 is a portion that covers the first main surface 3 in a region outside the first trench group 52 (the plurality of first trench resistive structures 51A) and the second trench group 53 (the plurality of second trench resistive structures 51B). The first covering portion 61 is positioned at an intermediate portion between the first end portion 60A and the second end portion 60B and faces the boundary well region 40 with the main surface insulating film 45 interposed therebetween in the thickness direction.

The second covering portion 62 forms the first end portion 60A of the resistive film 60 and covers all of the first trench resistive structures 51A. The second covering portion 62 forms the first end portion 60A further outward than the one end portions of the plurality of first trench resistive structures 51A (the peripheral edge side of the pad region 10). That is, the first end portion 60A faces the first covering portion 61 with the first trench group 52 interposed therebetween in plan view. The second covering portion 62 is connected to the resistance embedded electrodes 56 of the plurality of first trench resistive structures 51A and faces the boundary well region 40 with the main surface insulating film 45 interposed therebetween in the thickness direction.

The third covering portion 63 forms the second end portion 60B of the resistive film 60 and covers all of the second trench resistive structures 51B. The third covering portion 63 forms the second end portion 60B further outward than the other end portions of the plurality of second trench resistive structures 51B (the peripheral edge side of the pad region 10). That is, the second end portion 60B faces the first covering portion 61 with the second trench group 53 interposed therebetween in plan view. The third covering portion 63 is connected to the resistance embedded electrode 56 of the plurality of second trench resistive structures 51B and faces the boundary well region 40 with the main surface insulating film 45 interposed therebetween in the thickness direction.

The resistive film 60 is integrally formed with the resistance embedded electrode 56 of the plurality of first trench resistive structures 51A in the second covering portion 62 and is integrally formed with the resistance embedded electrode 56 of the plurality of second trench resistive structures 51B in the third covering portion 63. That is, the resistive film 60 includes a portion where a part of the resistance embedded electrode 56 is led out in a film shape onto the first main surface 3 (the main surface insulating film 45). As a matter of course, the resistive film 60 may be formed separately from the resistance embedded electrode 56.

The semiconductor device 1A includes a gate electrode film 64 arranged on the first main surface 3 such as to be adjacent to the resistive film 60. Specifically, the gate electrode film 64 is arranged on the main surface insulating film 45. The gate electrode film 64 includes at least one of a conductive polysilicon film and an alloy film. The alloy film may include an alloy crystal constituted of a metal element and a non-metal element.

The alloy film may include at least one of a CrSi film, a CrSiN film, a CrSiO film, a TaN film, and a TiN film. The gate electrode film 64 is preferably formed of the same resistance material as the resistive film 60. In this embodiment, the gate electrode film 64 contains conductive polysilicon. The gate electrode film 64 preferably has a thickness substantially equal to the thickness of the resistive film 60.

The gate electrode film 64 is arranged on the main surface insulating film 45 at an interval from the resistive film 60 toward the inner portion side (the third side surface 5C side) of the pad region 10 and is physically separated from the resistive film 60. The gate electrode film 64 is formed at an interval from the plurality of trench separation structures 15 toward the inner portion side of the pad region 10 in plan view.

The gate electrode film 64 faces the boundary well region 40 (first boundary well region 40A) with the main surface insulating film 45 interposed therebetween. The gate electrode film 64 is formed in a polygonal shape (a quadrangular shape in this embodiment) in plan view. In this embodiment, the gate electrode film 64 is formed in a rectangular shape extending in the second direction Y along the resistive film 60.

With reference to FIGS. 11, 12, and 24, the semiconductor device 1A includes a gate wiring film 65 arranged on the first main surface 3 adjacent to the resistive film 60 to face the gate electrode film 64 with the resistive film 60 interposed therebetween. Specifically, the gate wiring film 65 is arranged on the main surface insulating film 45. The gate wiring film 65 includes at least one of a conductive polysilicon film and an alloy film. The alloy film may include an alloy crystal constituted of a metal element and a non-metal element.

The alloy film may include at least one of a CrSi film, a CrSiN film, a CrSiO film, a TaN film, and a TiN film. The gate wiring film 65 is preferably formed of the same resistance material as the resistive film 60. In this embodiment, the gate wiring film 65 contains conductive polysilicon. The gate wiring film 65 preferably has a thickness substantially equal to the thickness of the resistive film 60.

The gate wiring film 65 is arranged on the main surface insulating film 45 at an interval from the gate electrode film 64 and is physically separated from the gate electrode film 64. The gate wiring film 65 includes a first connection portion connected to the first end portion 60A of the resistive film 60 and a second connection portion connected to the second end portion 60B of the resistive film 60.

That is, the gate wiring film 65 is electrically connected to the plurality of trench resistive structures 51 via the resistive film 60. Specifically, the gate wiring film 65 is electrically connected to the plurality of first trench resistive structures 51A between the first covering portion 61 and the second covering portion 62 of the resistive film 60 and is electrically connected to the plurality of second trench resistive structures 51B between the first covering portion 61 and the third covering portion 63 of the resistive film 60.

In this embodiment, the gate wiring film 65 includes a first lower wiring portion 66, a second lower wiring portion 67, and a third lower wiring portion 68. The first lower wiring portion 66 is routed to the pad region 10. Specifically, the first lower wiring portion 66 surrounds the resistive film 60 and the gate electrode film 64 in a plurality of directions (three directions in this form) in pad region 10.

The first lower wiring portion 66 includes a first lower line portion 69 and a plurality of second lower line portions 70A and 70B. The first lower line portion 69 is arranged on the street region 11 side with respect to the resistive film 60 in the pad region 10. The first lower line portion 69 is arranged on the first main surface 3 adjacent to the resistive film 60 to face the gate electrode film 64 with the resistive film 60 interposed therebetween in plan view. The first lower line portion 69 faces the boundary well region 40 (first boundary well region 40A) with the main surface insulating film 45 interposed therebetween in the thickness direction.

The first lower line portion 69 is formed in a band shape extending in the second direction Y along the resistive film 60. The first lower line portion 69 has a length larger than the length of the resistive film 60 and the length of the gate electrode film 64 in the second direction Y. The first lower line portion 69 has one end portion on one side (the first side surface 5A side) in the second direction Y and the other end portion on the other side (the second side surface 5B side) in the second direction Y.

The plurality of second lower line portions 70A and 70B include the second lower line portion 70A on one side and the second lower line portion 70B on the other side. The second lower line portion 70A is arranged in a region on one side (the first side surface 5A side) in the second direction Y with respect to the resistive film 60 and the gate electrode film 64 in the pad region 10. The second lower line portion 70B is arranged in a region on the other side (the second side surface 5B side) in the second direction Y with respect to the resistive film 60 and the gate electrode film 64 in the pad region 10.

The second lower line portion 70A is formed in a band shape extending in the first direction X and has one end portion connected to one end portion of the first lower line portion 69 and the other end portion positioned on the peripheral edge side (the third side surface 5C side) of the chip 2. The second lower line portion 70A is further connected to the first end portion 60A of the resistive film 60 and formed at an interval from the gate electrode film 64. That is, the second lower line portion 70A configures a first connection portion with respect to the first end portion 60A. The second lower line portion 70A faces the boundary well region 40 (first boundary well region 40A) with the main surface insulating film 45 interposed therebetween in the thickness direction.

The second lower line portion 70B is formed in a band shape extending in the first direction X and has one end portion connected to the other end portion of the first lower line portion 69 and the other end portion positioned on the peripheral edge side (the third side surface 5C side) of the chip 2. The second lower line portion 70B on the other side is further connected to the second end portion 60B of the resistive film 60 and formed at an interval from the gate electrode film 64.

That is, the second lower line portion 70B configures a second connection portion with respect to the first end portion 60A. The second lower line portion 70B on the other side faces the second lower line portion 70A on one side with the gate electrode film 64 interposed therebetween. The second lower line portion 70B on the other side faces the boundary well region 40 (first boundary well region 40A) with the main surface insulating film 45 interposed therebetween in the thickness direction.

The second lower wiring portion 67 is routed to the street region 11. Specifically, the second lower wiring portion 67 is led out from the first lower wiring portion 66 to the street region 11. More specifically, the second lower wiring portion 67 is led out from the inner portion (the central portion in this embodiment) of the first lower line portion 69 to the street region 11 and is formed in a band shape extending in the first direction X.

In this embodiment, the second lower wiring portion 67 crosses the center of the chip 2. The second lower wiring portion 67 extends in a band shape such as to be positioned in a region on one side (the third side surface 5C side) and a region on the other side (the fourth side surface 5D side) in the first direction X with respect to a straight line crossing the center of the first main surface 3 in the second direction Y. The second lower wiring portion 67 has one end portion connected to the first lower line portion 69 (first lower wiring portion 66) on one side in the first direction X and the other end portion on the other side in the first direction X.

The second lower wiring portion 67 faces the boundary well region 40 (second boundary well region 40B) with the main surface insulating film 45 interposed therebetween in the thickness direction. The second lower wiring portion 67 has a width larger than the width of the street region 11 in the second direction Y and is led out from the street region 11 to the plurality of active regions 6. The second lower wiring portion 67 covers the plurality of trench separation structures 15 in the plurality of active regions 6.

Also, the second lower wiring portion 67 covers the end portions of the plurality of first trench structures 21 in the plurality of active regions 6. As a result, the second lower wiring portion 67 is electrically connected to the plurality of separation embedded electrodes 18 and the plurality of first embedded electrodes 24 and transmits the gate potential to the plurality of separation embedded electrodes 18 and the plurality of first embedded electrodes 24.

In this embodiment, the second lower wiring portion 67 is integrally formed with the plurality of separation embedded electrodes 18 and the plurality of first embedded electrodes 24. That is, the second lower wiring portion 67 is constituted of a portion where a part of the plurality of separation embedded electrodes 18 and a part of the plurality of first embedded electrodes 24 are led out in a film shape onto the first main surface 3 (the main surface insulating film 45). As a matter of course, the second lower wiring portion 67 is separately formed with the plurality of separation embedded electrodes 18 and the plurality of first embedded electrodes 24.

The third lower wiring portion 68 is routed to the outer peripheral region 9. Specifically, the third lower wiring portion 68 is led out from the first lower wiring portion 66 to the outer peripheral region 9. More specifically, the third lower wiring portion 68 is led out from the other end portions of the plurality of second lower line portions 70A and 70B to one side (the first side surface 5A side) and the other side (the second side surface 5B side) of the outer peripheral region 9 and is formed in a band shape extending along the outer peripheral region 9.

The third lower wiring portion 68 interposes the plurality of active regions 6 together with the second lower wiring portion 67. Specifically, the third lower wiring portion 68 extends along the peripheral edges (first side surfaces 5A to 5D) of the chip 2 such as to surround the plurality of active regions 6 in plan view and is connected to the other end portion of the second lower wiring portion 67. Therefore, the third lower wiring portion 68 surrounds the plurality of active regions 6 together with the second lower wiring portion 67.

The third lower wiring portion 68 faces the inner portion of the outer peripheral well region 41 with the main surface insulating film 45 interposed therebetween. Specifically, the third lower wiring portion 68 faces the inner portion of the outer peripheral well region 41 at an interval inward from the inner edge and the outer edge of the outer peripheral well region 41 in plan view.

With reference to FIG. 3, the third lower wiring portion 68 has at least one lead-out portion 68a (in this embodiment, a plurality of lead-out portions 68a) that approaches from the outer peripheral region 9 and is led out to the active region 6 close thereto in the portion extending along the first side surface 5A. The plurality of lead-out portions 68a covers the first trench separation structure 15A at intervals in the first direction X on the first active region 6A side and covers the second trench separation structure 15B at intervals in the first direction X on the second active region 6B side.

That is, the plurality of lead-out portions 68a cover the end portions of the plurality of first trench structures 21. As a result, in the first active region 6A, the third lower wiring portion 68 is electrically connected to the plurality of separation embedded electrodes 18 and the plurality of first embedded electrodes 24 and transmits the gate potential to the plurality of separation embedded electrodes 18 and the plurality of first embedded electrodes 24.

As a matter of course, the single lead-out portion 68a extending in a band shape along the first trench separation structure 15A may be formed on the first active region 6A side. Also, the single lead-out portion 68a extending in a band shape along the second trench separation structure 15B may be formed on the second active region 6B side.

In this embodiment, the third lower wiring portion 68 is integrally formed with the plurality of separation embedded electrodes 18 and the plurality of first embedded electrodes 24. That is, the third lower wiring portion 68 is constituted of a portion where a part of the plurality of separation embedded electrodes 18 and a part of the plurality of first embedded electrodes 24 are led out in a film shape onto the first main surface 3 (the main surface insulating film 45). As a matter of course, the third lower wiring portion 68 is separately formed with the plurality of separation embedded electrodes 18 and the plurality of first embedded electrodes 24.

With reference to FIGS. 11 to 15, the semiconductor device 1A includes a first slit 71 demarcated in a region between the resistive film 60 and the gate electrode film 64. The first slit 71 is formed in a band shape extending in the second direction Y in plan view and demarcates the first to third covering portions 61 to 63 of the resistive film 60.

The first slit 71 exposes the main surface insulating film 45. The first slit 71 is formed outside the plurality of trench resistive structures 51 in plan view and faces the boundary well region 40 (first boundary well region 40A) in the thickness direction. That is, the first slit 71 does not face the trench resistive structure 51 in the thickness direction.

The first slit 71 has a first length in the second direction Y. The first slit 71 is formed to be narrower than the gate electrode film 64 in the first direction X. The first slit 71 is preferably formed to be narrower than the resistive film 60 in the first direction X. The first slit 71 is preferably formed to be narrower than the first trench group 52 in the first direction X. The first slit 71 is preferably formed to be wider than the trench resistive structure 51 in the first direction X.

The width of the first slit 71 may be 0.1 μm or more and 10 μm or less. The width of the first slit 71 may be 0.1 μm or more and 0.5 μm or less, 0.5 μm or more and 1 μm or less, 1 μm or more and 2.5 μm or less, 2.5 μm or more and 5 μm or less, 5 μm or more and 7.5 μm or less, or 7.5 μm or more and 10 μm or less. The width of the first slit 71 is preferably 3 μm or more and 7 μm or less.

With reference to FIGS. 11 to 15, the semiconductor device 1A includes a second slit 72 demarcated in a region between the resistive film 60 and the gate wiring film 65. Specifically, the second slit 72 is demarcated into a region between the resistive film 60 and the first lower line portion 69. The second slit 72 faces the first slit 71 with the resistive film 60 interposed therebetween.

The second slit 72 is formed in a band shape extending in the second direction Y in plan view and demarcates the first to third covering portions 61 to 63 of the resistive film 60. That is, the second slit 72 extends in parallel to the first slit 71 and demarcates the resistive film 60 together with the first slit 71. The second slit 72 exposes the main surface insulating film 45.

The second slit 72 is formed further outward than the plurality of trench resistive structures 51 in plan view and faces the boundary well region 40 (first boundary well region 40A) in the thickness direction. That is, the second slit 72 does not face the trench resistive structure 51 in the thickness direction. The second slit 72 faces the first slit 71 with the plurality of first trench resistive structures 51A and the plurality of second trench resistive structures 51B interposed therebetween in plan view.

The second slit 72 has a second length in the second direction Y. The second length may be different from the first length of the first slit 71. The second length is preferably equal to or less than the first length from the viewpoint of appropriately connecting the resistive film 60 and the gate wiring film 65. In this embodiment, the second length is less than the first length. As a matter of course, the second length may be substantially equal to the first length. Also, the second length may be larger than the first length.

The second slit 72 is formed to be narrower than the gate electrode film 64 in the first direction X. The second slit 72 is preferably formed to be narrower than the first lower line portion 69 in the first direction X. The second slit 72 is particularly preferably formed to be narrower than the resistive film 60 in the first direction X. The second slit 72 is preferably formed to be narrower than the first trench group 52 in the first direction X. The second slit 72 is preferably formed to be wider than the trench resistive structure 51.

The width of the second slit 72 may be 0.1 μm or more and 10 μm or less. The width of the second slit 72 may be 0.1 μm or more and 0.5 μm or less, 0.5 μm or more and 1 μm or less, 1 μm or more and 2.5 μm or less, 2.5 μm or more and 5 μm or less, 5 μm or more and 7.5 μm or less, or 7.5 μm or more and 10 μm or less.

The width of the second slit 72 is preferably 3 μm or more and 7 μm or less. The width of the second slit 72 may be equal to or larger than the width of the first slit 71. The width of the second slit 72 may be less than the width of the first slit 71. The width of the second slit 72 may be substantially equal to the width of the first slit 71.

With reference to FIGS. 11 to 15, the semiconductor device 1A includes a plurality of third slits 73 demarcated in a region between the gate electrode film 64 and the gate wiring film 65. Specifically, the plurality of third slits 73 are demarcated into regions between the gate electrode film 64 and the plurality of second lower line portions 70A and 70B, respectively.

Each of the plurality of third slits 73 is formed in a band shape extending in the first direction X in plan view and exposes the main surface insulating film 45. The plurality of third slits 73 are connected to the first slits 71 and face each other in the second direction Y with the gate electrode film 64 interposed therebetween. That is, the plurality of third slits 73 demarcates the gate electrode film 64 together with the first slit 71. Also, the plurality of third slits 73 physically and electrically separate the gate electrode film 64 from the gate wiring film 65 together with the first slit 71.

The third slit 73 is formed to be narrower than the gate electrode film 64. The third slit 73 is preferably formed to be narrower than the second lower line portions 70A and 70B. The third slit 73 is particularly preferably formed to be narrower than the resistive film 60. The third slit 73 is preferably formed to be narrower than the first trench group 52 (second trench group 53). The third slit 73 is preferably formed to be wider than the trench resistive structure 51.

The width of the third slit 73 may be 0.1 μm or more and 10 μm or less. The width of the third slit 73 may be 0.1 μm or more and 0.5 μm or less, 0.5 μm or more and 1 μm or less, 1 μm or more and 2.5 μm or less, 2.5 μm or more and 5 μm or less, 5 μm or more and 7.5 μm or less, or 7.5 μm or more and 10 μm or less.

The width of the third slit 73 is preferably 3 μm or more and 7 μm or less. The width of the third slit 73 may be equal to or larger than the width of the first slit 71. The width of the third slit 73 may be less than the width of the first slit 71. The width of the third slit 73 may be substantially equal to the width of the first slit 71.

The semiconductor device 1A includes an interlayer insulating film 74 that covers the main surface insulating film 45. The interlayer insulating film 74 is thicker than the main surface insulating film 45. The interlayer insulating film 74 may have a single layer structure including a single insulating film or a laminated structure including a plurality of insulating films. The interlayer insulating film 74 may include at least one of a silicon oxide film, a silicon nitride film, and an aluminum oxide film.

The interlayer insulating film 74 may have a laminated structure including a plurality of silicon oxide films. In this case, the interlayer insulating film 74 may include at least one of an NSG (non-doped silicate glass) film, a PSG (phosphor silicate glass) film, and a BPSG (boron phosphor silicate glass) film as an example of a silicon oxide film. The order of lamination of the NSG film, the PSG film, and the BPSG film is arbitrary.

The interlayer insulating film 74 covers the main surface insulating film 45 in the active region 6, the boundary region 8, and the outer peripheral region 9. The interlayer insulating film 74 covers the plurality of trench separation structures 15, the plurality of first trench structures 21, and the plurality of second trench structures 25 in the active region 6.

The interlayer insulating film 74 covers the plurality of trench resistive structures 51 (resistance embedded electrodes 56), the resistive film 60, the gate electrode film 64, and the gate wiring film 65 in the pad region 10. The interlayer insulating film 74 covers the boundary well region 40 (first boundary well region 40A) with the main surface insulating film 45 interposed therebetween in the pad region 10. The interlayer insulating film 74 selectively covers the outer peripheral well region 41, the field region 42, and the channel stop region 43 with the main surface insulating film 45 interposed therebetween in the outer peripheral region 9.

The interlayer insulating film 74 enters the first slit 71 from above the resistive film 60 and the gate electrode film 64 and has a portion that covers the main surface insulating film 45 in the first slit 71. That is, the interlayer insulating film 74 faces the boundary well region 40 (first boundary well region 40A) with the main surface insulating film 45 interposed therebetween in the thickness direction in the first slit 71. The interlayer insulating film 74 electrically insulates the resistive film 60 and the gate electrode film 64 in the first slit 71.

The interlayer insulating film 74 enters the second slit 72 from above the resistive film 60 and the gate wiring film 65 (first lower line portion 69) and has a portion that covers the main surface insulating film 45 in the second slit 72. That is, the interlayer insulating film 74 faces the boundary well region 40 (first boundary well region 40A) with the main surface insulating film 45 interposed therebetween in the thickness direction in the second slit 72. The interlayer insulating film 74 electrically insulates the resistive film 60 and the gate wiring film 65 (first lower line portion 69) in the second slit 72.

The interlayer insulating film 74 enters the plurality of third slits 73 from above the gate electrode film 64 and the gate wiring film 65 (second lower line portions 70A and 70B) and has a portion that covers the main surface insulating film 45 in the plurality of third slits 73. That is, the interlayer insulating film 74 faces the boundary well region 40 (first boundary well region 40A) with the main surface insulating film 45 interposed therebetween in the thickness direction in the plurality of third slits 73.

The interlayer insulating film 74 electrically insulates the gate electrode film 64 and the gate wiring film 65 in the plurality of third slits 73. The interlayer insulating film 74 is formed at an interval inward from the peripheral edge of the first main surface 3 and demarcates the removed portion 46 that exposes the peripheral edge portion of the first main surface 3 together with the main surface insulating film 45 at the peripheral edge of the first main surface 3.

The interlayer insulating film 74 has an insulating main surface 75 extending along the first main surface 3 (the main surface insulating film 45). The insulating main surface 75 has a first recess portion 76, a second recess portion 77, and a plurality of third recess portions 78 in the pad region 10 (see FIGS. 16 to 22). The first recess portion 76 is formed in a portion that covers the first slit 71. The first recess portion 76 is recessed toward the first slit 71 and is formed in a band shape extending in the second direction Y along the first slit 71 in plan view.

The second recess portion 77 is formed in a portion that covers the second slit 72. The second recess portion 77 is recessed toward the second slit 72 and is formed in a band shape extending in the second direction Y along the second slit 72 in plan view. The plurality of third recess portions 78 are formed in portions covering the plurality of third slits 73, respectively. Each of the plurality of third recess portions 78 is recessed toward the corresponding third slit 73 and is formed in a band shape extending in the first direction X along the corresponding third slit 73 in plan view.

With reference to FIGS. 11 to 22, the semiconductor device 1A includes at least one first resistance connection electrode 81 (in this embodiment, a plurality of first resistance connection electrodes 81) embedded in the interlayer insulating film 74 such as to be electrically connected to the resistive film 60. The first resistance connection electrode 81 may be referred to as a “first resistance via electrode.” The first resistance connection electrode 81 may include at least one of a Ti film, a TiN film, a W film, an Al film, a Cu film, an Al alloy film, a Cu alloy film, and a conductive polysilicon film. In this embodiment, the first resistance connection electrode 81 has a laminated structure including a Ti film and a W film.

In this embodiment, the plurality of first resistance connection electrodes 81 are connected to the first covering portion 61 of the resistive film 60. That is, the plurality of first resistance connection electrodes 81 are connected to a portion of the resistive film 60 covering a region outside the plurality of trench resistive structures 51. Specifically, the plurality of first resistance connection electrodes 81 are connected to a portion of the resistive film 60 covering the space region 57 between the first trench group 52 (the plurality of first trench resistive structures 51A) and the second trench group 53 (the plurality of second trench resistive structures 51B).

The plurality of first resistance connection electrodes 81 are formed in regions with intervals from the plurality of trench resistive structures 51 in the second direction Y in plan view and do not face the plurality of trench resistive structures 51 in the first direction X. In this embodiment, the plurality of first resistance connection electrodes 81 are each formed in a band shape extending in the first direction X in plan view, and are arranged at intervals in the second direction Y. That is, the plurality of first resistance connection electrodes 81 are arranged in a stripe shape extending in the first direction X in plan view.

The plurality of first resistance connection electrodes 81 extend in a direction intersecting (this embodiment, orthogonal to) the extending direction of the resistive film 60 (the plurality of trench resistive structures 51). That is, the plurality of first resistance connection electrodes 81 intersect (are orthogonal to) the current direction of the resistive film 60. As a result, the current can be appropriately expanded from the plurality of first resistance connection electrodes 81 to the resistive film 60. That is, current constriction caused by the layout of the plurality of first resistance connection electrodes 81 is suppressed, and an undesirable variation (increase) in the resistance caused by the current constriction is suppressed.

The plurality of first resistance connection electrodes 81 face only the flat portion of the first main surface 3 with the resistive film 60 interposed therebetween, and do not face the trench resistive structure 51 with the resistive film 60 interposed therebetween. The plurality of first resistance connection electrodes 81 face the boundary well region 40 (first boundary well region 40A) with the resistive film 60 and the main surface insulating film 45 interposed therebetween. The plurality of first resistance connection electrodes 81 are formed in a region interposed between the first slit 71 and the second slit 72 at intervals from the first slit 71 and the second slit 72 in plan view.

That is, the plurality of first resistance connection electrodes 81 is formed to be narrower than the resistive film 60 in the first direction X. The plurality of first resistance connection electrodes 81 face the one or the plurality of first trench resistive structures 51A on one side (the first side surface 5A side) in the second direction Y in plan view and face the one or the plurality of second trench resistive structures 51B on the other side (the second side surface 5B side) in the second direction Y.

The plurality of first resistance connection electrodes 81 suffice to face at least two of the plurality of first trench resistive structures 51A in the second direction Y and do not have to face all of the first trench resistive structures 51A. In this embodiment, the plurality of first resistance connection electrodes 81 face some of the plurality of first trench resistive structures 51A in the second direction Y. As a matter of course, the plurality of first resistance connection electrodes 81 may face all of the first trench resistive structures 51A in the second direction Y.

Similarly, the plurality of first resistance connection electrodes 81 suffice to face at least two of the plurality of second trench resistive structures 51B in the second direction Y and do not have to face all of the first trench resistive structures 51A. In this embodiment, the plurality of first resistance connection electrodes 81 face some of the plurality of second trench resistive structures 51B in the second direction Y. As a matter of course, the plurality of first resistance connection electrodes 81 may face all of the second trench resistive structures 51B in the second direction Y.

The plurality of first resistance connection electrodes 81 have a first connection area S1 with respect to the resistive film 60. The first connection area S1 is defined by the total plane area of the plurality of first resistance connection electrodes 81. When the single first resistance connection electrode 81 is formed, the first connection area S1 is defined by the plane area of the single first resistance connection electrode 81. The first connection area S1 is adjusted according to a first current I1 flowing through the first resistance connection electrode 81 (see FIG. 12).

With reference to FIGS. 11 to 22, the semiconductor device 1A includes at least one second resistance connection electrode 82 (in this embodiment, a plurality of second resistance connection electrodes 82) embedded in the interlayer insulating film 74 such as to be electrically connected to the resistive film 60 at a location different from the first resistance connection electrode 81. The second resistance connection electrode 82 may be referred to as a “second resistance via electrode.”

The second resistance connection electrode 82 may include at least one of a Ti film, a TiN film, a W film, an Al film, a Cu film, an Al alloy film, a Cu alloy film, and a conductive polysilicon film. In this embodiment, the second resistance connection electrode 82 has a laminated structure including a Ti film and a W film.

In this embodiment, the plurality of second resistance connection electrodes 82 are connected to the second covering portion 62 of the resistive film 60. That is, the plurality of second resistance connection electrodes 82 are connected to a portion of the resistive film 60 covering the first trench group 52 (the plurality of first trench resistive structures 51A).

The plurality of second resistance connection electrodes 82 form a first gate resistor R1 with the plurality of first resistance connection electrodes 81. The first gate resistor R1 is configured by a portion positioned in a region between the plurality of first resistance connection electrodes 81 and the plurality of second resistance connection electrodes 82 in the resistive film 60 and the plurality of first trench resistive structures 51A. The resistance of the first gate resistor R1 is adjusted by the distance between the plurality of first resistance connection electrodes 81 and the plurality of second resistance connection electrodes 82.

The plurality of second resistance connection electrodes 82 are formed in a region facing the plurality of first trench resistive structures 51A in the first direction X in plan view. In this embodiment, the plurality of second resistance connection electrodes 82 extend in a different direction from the first resistance connection electrode 81 in plan view. Specifically, the plurality of second resistance connection electrodes 82 are each formed in a band shape extending in the second direction Y in plan view, and are arranged at intervals in the first direction X. That is, the plurality of second resistance connection electrodes 82 are arranged in a stripe shape extending in the second direction Y in plan view.

The plurality of second resistance connection electrodes 82 are arranged in regions between the plurality of first trench resistive structures 51A adjacent to each other at intervals from the plurality of first trench resistive structures 51A in plan view. That is, the plurality of second resistance connection electrodes 82 are alternately arranged with the plurality of first trench resistive structures 51A in the first direction X.

Also, in this embodiment, the plurality of second resistance connection electrodes 82 face only the flat portion of the first main surface 3 with the resistive film 60 interposed therebetween, and do not face the trench resistive structure 51 with the resistive film 60 interposed therebetween. The plurality of second resistance connection electrodes 82 face the boundary well region 40 (first boundary well region 40A) with the resistive film 60 and the main surface insulating film 45 interposed therebetween.

The plurality of second resistance connection electrodes 82 suffice to be arranged in some of the regions between the plurality of first trench resistive structures 51A and is not necessarily arranged in all of the regions between the plurality of first trench resistive structures 51A. The plurality of second resistance connection electrodes 82 suffice to be arranged in at least one region positioned on the active region 6 side among the regions between the plurality of first trench resistive structures 51A and do not have to be arranged in at least one region positioned on the gate electrode film 64 side.

It is preferable that at least one of the plurality of second resistance connection electrodes 82 faces the plurality of first resistance connection electrodes 81 in the second direction Y in plan view. In this case, at least one of the plurality of second resistance connection electrodes 82 positioned on the gate electrode film 64 side preferably faces the plurality of first resistance connection electrodes 81 in the second direction Y.

At least one of the plurality of second resistance connection electrodes 82 positioned on the active region 6 side may not face the plurality of first resistance connection electrodes 81 in the second direction Y. As a matter of course, all of the second resistance connection electrodes 82 may be arranged to face the plurality of first resistance connection electrodes 81 in the second direction Y.

The plurality of second resistance connection electrodes 82 have the length less than the length of the plurality of first trench resistive structures 51A in the second direction Y. The plurality of second resistance connection electrodes 82 are preferably arranged in the region of the plurality of first trench resistive structures 51A on the other end portion side with respect to the intermediate portion of plurality of first trench resistive structures 51A in the long direction.

The length of the plurality of second resistance connection electrodes 82 is preferably 1/100 or more and ½ or less of the length of the plurality of first trench resistive structures 51A. The length of the plurality of second resistance connection electrodes 82 may be 1/20 or more and ¼ or less of the length of the plurality of first trench resistive structures 51A.

The plurality of second resistance connection electrodes 82 have a second connection area S2 with respect to the resistive film 60. The second connection area S2 is defined by the total plane area of the plurality of second resistance connection electrodes 82. When the single second resistance connection electrode 82 is formed, the second connection area S2 is defined by the plane area of the single second resistance connection electrode 82.

The second connection area S2 may be substantially equal to the first connection area S1. The second connection area S2 may be larger than the first connection area S1. The second connection area S2 may be less than the first connection area S1. The second connection area S2 is adjusted according to a current ratio I2/I1 (shunt ratio) of a second current I2 flowing through the second resistance connection electrode 82 to the first current I1 flowing through the first resistance connection electrode 81 (see FIG. 12).

In this case, a value of an area ratio S2/S1 of the second connection area S2 to the first connection area S1 is preferably set to be equal to or larger than the value of the current ratio I2/I1. For example, when the current ratio I2/I1 is 1, the area ratio S2/S1 is preferably set to 1 or more. For example, when the current ratio I2/I1 is 1/2, the area ratio S2/S1 is preferably set to 1/2 or more.

When the current ratio I2/I1 is 1/4, the area ratio S2/S1 is preferably set to 1/4 or more. In this embodiment, the current ratio I2/I1 is almost 1/2, and the second connection area S2 is 1/2 times or more the first connection area S1. The second connection area S2 is preferably twice or less the first connection area S1.

With reference to FIGS. 11 to 22, the semiconductor device 1A includes at least one third resistance connection electrode 83 (in this embodiment, a plurality of third resistance connection electrodes 83) embedded in the interlayer insulating film 74 such as to be electrically connected to the resistive film 60 at a location different from the first resistance connection electrode 81 and the second resistance connection electrode 82. The third resistance connection electrode 83 may be referred to as a “third resistance via electrode.”

The third resistance connection electrode 83 may include at least one of a Ti film, a TiN film, a W film, an Al film, a Cu film, an Al alloy film, a Cu alloy film, and a conductive polysilicon film. In this embodiment, the third resistance connection electrode 83 has a laminated structure including a Ti film and a W film.

In this embodiment, the plurality of third resistance connection electrodes 83 are connected to the third covering portion 63 of the resistive film 60. That is, the plurality of third resistance connection electrodes 83 are connected to a portion of the resistive film 60 covering the second trench group 53 (the plurality of second trench resistive structures 51B).

The plurality of third resistance connection electrodes 83 form a second gate resistor R2 with the plurality of first resistance connection electrodes 81. The second gate resistor R2 is configured by a portion positioned in a region between the plurality of first resistance connection electrodes 81 and the plurality of third resistance connection electrodes 83 in the resistive film 60 and the plurality of second trench resistive structures 51B.

The resistance of the second gate resistor R2 is adjusted by the distance between the plurality of first resistance connection electrodes 81 and the plurality of third resistance connection electrodes 83. In this form, the resistance of the second gate resistor R2 is substantially equal to the resistance of the first gate resistor R1. Also, the distance between the plurality of first resistance connection electrodes 81 and the plurality of third resistance connection electrodes 83 is substantially equal to the distance between the plurality of first resistance connection electrodes 81 and the plurality of second resistance connection electrodes 82.

As a matter of course, the resistance of the second gate resistor R2 may be different from the resistance of the first gate resistor R1. In this case, the distance between the plurality of first resistance connection electrodes 81 and the plurality of third resistance connection electrodes 83 may be different from the distance between the plurality of first resistance connection electrodes 81 and the plurality of second resistance connection electrodes 82.

For example, the resistance of the second gate resistor R2 may be less than the resistance of the first gate resistor R1. In this case, the distance between the plurality of first resistance connection electrodes 81 and the plurality of third resistance connection electrodes 83 may be set to be less than the distance between the plurality of first resistance connection electrodes 81 and the plurality of second resistance connection electrodes 82.

For example, the resistance of the second gate resistor R2 may be larger than the resistance of the first gate resistor R1. In this case, the distance between the plurality of first resistance connection electrodes 81 and the plurality of third resistance connection electrodes 83 may be set to be larger than the distance between the plurality of first resistance connection electrodes 81 and the plurality of second resistance connection electrodes 82.

The plurality of third resistance connection electrodes 83 are formed in a region facing the plurality of second trench resistive structures 51B in the first direction X in plan view. In this embodiment, the plurality of third resistance connection electrodes 83 extend in a different direction from the first resistance connection electrode 81 in plan view. Specifically, the plurality of third resistance connection electrodes 83 are each formed in a band shape extending in the second direction Y in plan view, and are arranged at intervals in the first direction X. That is, the plurality of third resistance connection electrodes 83 are arranged in a stripe shape extending in the second direction Y in plan view.

The plurality of third resistance connection electrodes 83 are arranged in regions between the plurality of second trench resistive structures 51B adjacent to each other at intervals from the plurality of second trench resistive structures 51B in plan view. That is, the plurality of third resistance connection electrodes 83 are alternately arranged with the plurality of second trench resistive structures 51B in the first direction X.

Also, in this embodiment, the plurality of third resistance connection electrodes 83 face only the flat portion of the first main surface 3 with the resistive film 60 interposed therebetween, and do not face the trench resistive structure 51 with the resistive film 60 interposed therebetween. The plurality of third resistance connection electrodes 83 face the boundary well region 40 (first boundary well region 40A) with the resistive film 60 and the main surface insulating film 45 interposed therebetween.

The plurality of third resistance connection electrodes 83 suffice to be arranged in some of the regions between the plurality of second trench resistive structures 51B and is not necessarily arranged in all of the regions between the plurality of second trench resistive structures 51B. The plurality of third resistance connection electrodes 83 suffice to be arranged in at least one region positioned on the active region 6 side among the regions between the plurality of second trench resistive structures 51B and do not have to be arranged in at least one region positioned on the gate electrode film 64 side.

It is preferable that at least one of the plurality of third resistance connection electrodes 83 faces the plurality of first resistance connection electrodes 81 in the second direction Y in plan view. In this case, at least one of the plurality of third resistance connection electrodes 83 positioned on the gate electrode film 64 side preferably faces the plurality of first resistance connection electrodes 81 in the second direction Y.

At least one of the plurality of third resistance connection electrodes 83 positioned on the active region 6 side may not face the plurality of first resistance connection electrodes 81 in the second direction Y. As a matter of course, all of the third resistance connection electrodes 83 may be arranged to face the plurality of first resistance connection electrodes 81 in the second direction Y.

It is preferable that at least one of the plurality of third resistance connection electrodes 83 faces the plurality of second resistance connection electrodes 82 in the second direction Y in plan view. In this embodiment, the number of the plurality of third resistance connection electrodes 83 is set to be equal to the number of the plurality of second resistance connection electrodes 82, and all of the third resistance connection electrodes 83 face all of the second resistance connection electrodes 82 in the second direction Y in a one-to-one correspondence relationship. As a matter of course, the number of third resistance connection electrodes 83 may be larger than the number of second resistance connection electrodes 82 or may be smaller than the number of second resistance connection electrodes 82.

The plurality of third resistance connection electrodes 83 have the length less than the length of the plurality of second trench resistive structures 51B in the second direction Y. The plurality of third resistance connection electrodes 83 are preferably arranged in the region of the plurality of second trench resistive structures 51B on the other end portion side with respect to the intermediate portion of plurality of second trench resistive structures 51B in the long direction.

The length of the plurality of third resistance connection electrodes 83 is preferably 1/100 or more and ½ or less of the length of the plurality of second trench resistive structures 51B. The length of the plurality of third resistance connection electrodes 83 may be 1/20 or more and ¼ or less of the length of the plurality of second trench resistive structures 51B. The length of the third resistance connection electrode 83 may be substantially equal to the length of the second resistance connection electrode 82. The length of the third resistance connection electrode 83 may be larger than the length of the second resistance connection electrode 82. The length of the third resistance connection electrode 83 may be smaller than the length of the second resistance connection electrode 82.

The plurality of third resistance connection electrodes 83 have a third connection area S3 with respect to the resistive film 60. The third connection area S3 is defined by the total plane area of the plurality of third resistance connection electrodes 83. When the single third resistance connection electrode 83 is formed, the third connection area S3 is defined by the plane area of the single third resistance connection electrode 83. The third connection area S3 is adjusted according to a current ratio I3/I1 (shunt ratio) of a third current I3 flowing through the third resistance connection electrode 83 to the first current I1 flowing through the first resistance connection electrode 81 (see FIG. 12).

In this case, a value of an area ratio S3/S1 of the third connection area S3 to the first connection area S1 is preferably set to be equal to or larger than the value of the current ratio I3/I1. For example, when the current ratio I3/I1 is 1, the area ratio S3/S1 is preferably set to 1 or more. For example, when the current ratio I3/I1 is 1/2, the area ratio S3/S1 is preferably set to 1/2 or more.

When the current ratio I3/I1 is 1/4, the area ratio S3/S1 is preferably set to 1/4or more. In this embodiment, since the third current I3 is substantially equal to the second current I2, and the current ratio I3/I1 is substantially 1/2, the third connection area S3 is set to 1/2 times or more the first connection area S1. The third connection area S3 is preferably twice or less the first connection area S1. As a matter of course, the third current I3 may be larger than the second current I2 or smaller than the second current I2.

With reference to FIGS. 3 to 10, the semiconductor device 1A includes a plurality of gate connection electrodes 84 embedded in the interlayer insulating film 74 such as to be electrically connected to the gate wiring film 65 in the non-active region 7. The gate connection electrode 84 may be referred to as a “gate via electrode.” The plurality of gate connection electrodes 84 may include at least one of a Ti film, a TiN film, a W film, an Al film, a Cu film, an Al alloy film, a Cu alloy film, and a conductive polysilicon film. In this embodiment, the plurality of gate connection electrodes 84 has a laminated structure including a Ti film and a W film.

The plurality of gate connection electrodes 84 include at least one first gate connection electrode 84A (in this embodiment, a plurality of first gate connection electrodes 84A) and at least one second gate connection electrode 84B (in this embodiment, a plurality of second gate connection electrodes 84B). The plurality of first gate connection electrodes 84A are embedded in a portion of the interlayer insulating film 74 covering the second lower wiring portion 67 in the street region 11 and are electrically connected to the second lower wiring portion 67 (see FIGS. 7 to 9). In this embodiment, the plurality of first gate connection electrodes 84A are formed at intervals in the second direction Y and formed in a band shape extending in the first direction X.

The plurality of second gate connection electrodes 84B are embedded in a portion of the interlayer insulating film 74 covering the third lower wiring portion 68 in the outer peripheral region 9 and are electrically connected to the third lower wiring portion 68 (see FIGS. 3 to 6). In this embodiment, the plurality of second gate connection electrodes 84B are formed at intervals from the inner edge side toward the outer edge side of the third lower wiring portion 68 and are formed in a band shape extending along the third lower wiring portion 68.

With reference to FIGS. 3 and 4, the semiconductor device 1A includes a plurality of first emitter connection electrodes 85 that penetrate through the main surface insulating film 45 and are embedded in the interlayer insulating film 74 such as to be electrically connected to the plurality of emitter regions 29 in the active region 6. The first emitter connection electrode 85 may be referred to as a “first emitter via electrode.”

The plurality of first emitter connection electrodes 85 may include at least one of a Ti film, a TiN film, a W film, an Al film, a Cu film, an Al alloy film, a Cu alloy film, and a conductive polysilicon film. In this embodiment, the plurality of first emitter connection electrodes 85 has a laminated structure including a Ti film and a W film.

Each of the plurality of first emitter connection electrodes 85 is embedded in each of the plurality of contact holes 30 and is formed in a band shape extending in the second direction Y along each of the plurality of first trench structures 21 in plan view. That is, in this embodiment, the plurality of first emitter connection electrodes 85 extend in the same direction as the extending direction of the plurality of second resistance connection electrodes 82 and the extending direction of the plurality of third resistance connection electrodes 83. The plurality of first emitter connection electrodes 85 are electrically connected to the emitter region 29 and the contact region 31 in the corresponding contact hole 30.

With reference to FIGS. 3 and 5, the semiconductor device 1A includes a plurality of second emitter connection electrodes 86 that penetrate through the main surface insulating film 45 and are embedded in the interlayer insulating film 74 such as to be electrically connected to the plurality of emitter electrode films 47 in the active region 6. The second emitter connection electrode 86 may be referred to as a “second emitter via electrode.”

The plurality of second emitter connection electrodes 86 may include at least one of a Ti film, a TiN film, a W film, an Al film, a Cu film, an Al alloy film, a Cu alloy film, and a conductive polysilicon film. In this embodiment, the plurality of second emitter connection electrodes 86 have a laminated structure including a Ti film and a W film. The plurality of second emitter connection electrodes 86 are electrically connected to the second embedded electrode 28 via the plurality of emitter electrode films 47.

With reference to FIGS. 3 to 6, the semiconductor device 1A includes at least one first well connection electrode 87 (in this embodiment, a plurality of first well connection electrodes 87) that penetrates through the main surface insulating film 45 and is embedded in the interlayer insulating film 74 such as to be electrically connected to the inner edge of the outer peripheral well region 41. The first well connection electrode 87 may be referred to as a “first well via electrode.”

The plurality of first well connection electrodes 87 may include at least one of a Ti film, a TiN film, a W film, an Al film, a Cu film, an Al alloy film, a Cu alloy film, and a conductive polysilicon film. In this embodiment, the plurality of first well connection electrodes 87 have a laminated structure including a Ti film and a W film.

In this embodiment, the plurality of first well connection electrodes 87 are arranged at intervals from the inner edge side toward the outer edge side of the outer peripheral well region 41. The plurality of first well connection electrodes 87 are arranged on the inner edge side of the outer peripheral well region 41 with respect to the intermediate portion of the outer peripheral well region 41 in the width direction and is electrically connected to the region on the inner edge side of the outer peripheral well region 41.

Specifically, the plurality of first well connection electrodes 87 are arranged in a region between the inner edge of the outer peripheral well region 41 and the third lower wiring portion 68 of the gate wiring film 65. Each of the plurality of first well connection electrodes 87 extends in a band shape along the inner edge of the outer peripheral well region 41.

Each of the plurality of first well connection electrodes 87 has a plurality of segment portions 87a in a portion extending in the first direction X (see FIG. 3). Each of the plurality of segment portions 87a is arranged in a region between the plurality of lead-out portions 68a of the gate wiring film 65 (third lower wiring portion 68) at intervals from the plurality of lead-out portions 68a. When the single lead-out portion 68a extending in a band shape is formed along the trench separation structure 15, the plurality of segment portions 87a is omitted.

With reference to FIGS. 3 to 6, the semiconductor device 1A includes at least one second well connection electrode 88 (in this embodiment, a plurality of second well connection electrodes 88) that penetrates through the main surface insulating film 45 and is embedded in the interlayer insulating film 74 such as to be electrically connected to the outer edge of the outer peripheral well region 41. The second well connection electrode 88 may be referred to as a “second well via electrode.”

The plurality of second well connection electrodes 88 may include at least one of a Ti film, a TiN film, a W film, an Al film, a Cu film, an Al alloy film, a Cu alloy film, and a conductive polysilicon film. In this embodiment, the plurality of second well connection electrodes 88 have a laminated structure including a Ti film and a W film.

In this embodiment, the plurality of second well connection electrodes 88 are arranged at intervals from the inner edge side toward the outer edge side of the outer peripheral well region 41. The plurality of second well connection electrodes 88 are arranged on the outer edge side of the outer peripheral well region 41 with respect to the intermediate portion of the outer peripheral well region 41 in the width direction and is electrically connected to the region on the outer edge side of the outer peripheral well region 41. Specifically, the plurality of second well connection electrodes 88 are arranged in a region between the outer edge of the outer peripheral well region 41 and the third lower wiring portion 68 of the gate wiring film 65. Each of the plurality of second well connection electrodes 88 extends in a band shape along the outer edge of the outer peripheral well region 41.

With reference to FIG. 10, the semiconductor device 1A includes a plurality of field connection electrodes 89 that penetrate through the main surface insulating film 45 and are embedded in the interlayer insulating film 74 such as to be electrically connected to the corresponding field region 42. In this embodiment, the plurality of field connection electrodes 89 is connected to one field region 42. As a matter of course, the single field connection electrode 89 may be connected to one field region 42. The field connection electrode 89 may be referred to as a “field via electrode.”

The plurality of field connection electrodes 89 may include at least one of a Ti film, a TiN film, a W film, an Al film, a Cu film, an Al alloy film, a Cu alloy film, and a conductive polysilicon film. In this embodiment, the plurality of field connection electrodes 89 have a laminated structure including a Ti film and a W film.

Each of the plurality of field connection electrodes 89 is formed in a band shape extending along the corresponding field region 42. In this embodiment, each of the plurality of field connection electrodes 89 is formed in an annular shape (quadrangular annular shape) extending along the corresponding field region 42. In this embodiment, the plurality of field connection electrodes 89 are formed to be in an electrically floating state.

With reference to FIGS. 1 and 11 to 22, the semiconductor device 1A includes a gate terminal electrode 90 arranged on the first main surface 3 such as to be electrically connected to the gate resistive structure 50 in the pad region 10 (non-active region 7). Specifically, the gate terminal electrode 90 is arranged on the interlayer insulating film 74. The gate terminal electrode 90 may be referred to as a “gate pad” or a “gate pad electrode.”

The gate terminal electrode 90 is preferably constituted of a conductive material different from the resistive film 60. The gate terminal electrode 90 is preferably constituted of a conductive material different from the gate electrode film 64. The gate terminal electrode 90 has a lower resistance than that of the trench resistive structure 51 and the resistive film 60 and is electrically connected to the trench resistive structure 51 via the resistive film 60. The gate terminal electrode 90 has a lower resistance than that of the gate electrode film 64.

In this embodiment, the gate terminal electrode 90 is constituted of a metal film. The gate terminal electrode 90 may also be referred to as a “gate metal terminal.” The gate terminal electrode 90 may include at least one of a Ti film, a TiN film, a W film, an Al film, a Cu film, an Al alloy film, a Cu alloy film, and a conductive polysilicon film.

The gate terminal electrode 90 may include at least one of a pure Cu film (Cu film having a purity of 99% or more), a pure Al film (Al film having a purity of 99% or more), an AlCu alloy film, an AlSi alloy film, and an AlSiCu alloy film. In this embodiment, the gate terminal electrode 90 has a laminated structure that includes a Ti film and an Al alloy film (in this embodiment, an AlCu alloy film) laminated in that order from the chip 2 side.

The gate terminal electrode 90 preferably has a thickness larger than the thickness of the resistive film 60 (the thickness of the gate electrode film 64). The thickness of the gate terminal electrode 90 may be 1 μm or more and 10 μm or less.

The gate terminal electrode 90 preferably has a plane area of 1% or more and 30% or less of the plane area of the first main surface 3. The plane area of the gate terminal electrode 90 is particularly preferably 25% or less of the plane area of the first main surface 3. The plane area of the gate terminal electrode 90 may be 10% or less of the plane area of the first main surface 3.

The gate terminal electrode 90 is arranged on the interlayer insulating film 74 such as to cover the resistive film 60 and the gate electrode film 64 in the pad region 10. The gate terminal electrode 90 covers the plurality of first resistance connection electrodes 81 in a portion that covers the resistive film 60 and is electrically connected to the plurality of first resistance connection electrodes 81. That is, the gate terminal electrode 90 is electrically connected to the resistive film 60 (first covering portion 61) via the plurality of first resistance connection electrodes 81.

With reference to FIGS. 11 to 22 (particularly FIGS. 11 to 13), the gate terminal electrode 90 includes a first electrode portion 91 and a second electrode portion 92. The first electrode portion 91 has a comparatively wide electrode width in the second direction Y. The first electrode portion 91 is a portion that forms a terminal main body of the gate terminal electrode 90 and is positioned in a region outside the first resistance connection electrode 81 in plan view. The first electrode portion 91 may be referred to as a “terminal main body portion.”

For example, a bonding wire is connected to the first electrode portion 91. Therefore, the first electrode portion 91 is formed to be wider than the joint portion of the bonding wire. The first electrode portion 91 is formed in a polygonal shape (quadrangular shape in this embodiment) having four sides parallel to the peripheral edge of the chip 2 (the peripheral edge of the pad region 10) in plan view. The first electrode portion 91 is arranged in a region facing the gate electrode film 64 with the interlayer insulating film 74 interposed therebetween.

The first electrode portion 91 preferably covers 50% or more of the region of the gate electrode film 64 in plan view. The first electrode portion 91 particularly preferably covers 90% or more of the region of the gate electrode film 64 in plan view. In this embodiment, the first electrode portion 91 has a wider electrode width than the gate electrode film 64 and covers the entire region of the gate electrode film 64.

Flatness of the first electrode portion 91 is enhanced by the gate electrode film 64. The first electrode portion 91 may be electrically insulated from the gate electrode film 64 by the interlayer insulating film 74. The first electrode portion 91 may be electrically connected to the gate electrode film 64 via one or the plurality of gate connection electrodes 84 embedded in the interlayer insulating film 74.

The first electrode portion 91 covers the first slit 71 with the interlayer insulating film 74 interposed therebetween and backfills the first recess portion 76 of the interlayer insulating film 74 (insulating main surface 75). When the gate terminal electrode 90 (first electrode portion 91) partially exposing the first recess portion 76 is formed, it is concerned that electrode residues generated during a step of forming the gate terminal electrode 90 remain in the first recess portion 76.

When the electrode residue exists, it is concerned that the gate terminal electrode 90 (first electrode portion 91) is electrically connected to another electrode via the electrode residue. Therefore, the gate terminal electrode 90 (first electrode portion 91) preferably covers the entire region of the first slit 71 with the interlayer insulating film 74 interposed therebetween.

That is, the gate terminal electrode 90 (first electrode portion 91) preferably fills the entire region of the first recess portion 76 of the interlayer insulating film 74 (insulating main surface 75). According to this configuration, a layout that avoids the problem of electrode residue in the first recess portion 76 is provided. According to the present disclosure, an embodiment including the gate terminal electrode 90 (first electrode portion 91) partially exposes the first recess portion 76 is not excluded.

The first electrode portion 91 is led out from above the gate electrode film 64 to above the resistive film 60 across the first slit 71 in plan view. In this embodiment, the first electrode portion 91 covers the edge portion of the resistive film 60 with the interlayer insulating film 74 interposed therebetween. Specifically, the first electrode portion 91 covers the edge portion of the resistive film 60 at an interval toward the gate electrode film 64 side with respect to a straight line crossing the center portion of the resistive film 60 in the second direction Y.

The first electrode portion 91 may cover one or the plurality of trench resistive structures 51 with the resistive film 60 interposed therebetween in a portion that covers the resistive film 60. The first electrode portion 91 may cover one or the plurality of first trench resistive structures 51A with the resistive film 60 interposed therebetween. The first electrode portion 91 may cover one or the plurality of second trench resistive structures 51B with the resistive film 60 interposed therebetween. In this embodiment, the first electrode portion 91 covers one first trench resistive structure 51A and one second trench resistive structure 51B with the resistive film 60 interposed therebetween.

The first electrode portion 91 covers the plurality of third slits 73 with the interlayer insulating film 74 interposed therebetween and backfills the plurality of third recess portions 78 of the interlayer insulating film 74 (insulating main surface 75). When the gate terminal electrode 90 (first electrode portion 91) partially exposing the plurality of third recess portions 78 are formed, it is concerned that electrode residues generated during a step of forming the gate terminal electrode 90 remain in the plurality of third recess portions 78.

When the electrode residue exists, it is concerned that the gate terminal electrode 90 (first electrode portion 91) is electrically connected to another electrode via the electrode residue. Therefore, the gate terminal electrode 90 (first electrode portion 91) preferably covers the entire region of the plurality of third recess portions 78 with the interlayer insulating film 74 interposed therebetween.

That is, the gate terminal electrode 90 (first electrode portion 91) preferably fills the entire region of the third recess portion 78 of the interlayer insulating film 74 (insulating main surface 75). According to this configuration, a layout that avoids the problem of electrode residue in the plurality of third recess portions 78 is provided. According to the present disclosure, an embodiment including the gate terminal electrode 90 (first electrode portion 91) partially exposes the plurality of third recess portions 78 is not excluded.

The first electrode portion 91 is led out from above the gate electrode film 64 to above the plurality of second lower line portions 70A and 70B across the plurality of third slits 73 in plan view. In this embodiment, the first electrode portion 91 covers the edge portions of the plurality of second lower line portions 70A and 70B with the interlayer insulating film 74 interposed therebetween.

The second electrode portion 92 has a smaller electrode width than that of the first electrode portion 91 in the second direction Y and includes a lead-out portion led out in the second direction Y such as to protrude from the first electrode portion 91 toward the plurality of first resistance connection electrodes 81. The second electrode portion 92 may be referred to as a “terminal lead-out portion.” For example, a bonding wire is not connected to the second electrode portion 92. Therefore, the second electrode portion 92 is formed to be narrower than the joint portion of the bonding wire.

The protruding direction of the second electrode portion 92 is the same as the extending direction of the plurality of first resistance connection electrodes 81. In this embodiment, the second electrode portion 92 is led out from the central portion of the first electrode portion 91 and covers all of the first resistance connection electrodes 81.

The second electrode portion 92 is formed at an interval from the first slit 71 toward the second slit 72 side in plan view and does not intersect the first slit 71. Furthermore, the second electrode portion 92 is formed at an interval from the second slit 72 toward the first slit 71 side in plan view and does not intersect the second slit 72. That is, the second electrode portion 92 has a width smaller than the width of the resistive film 60 in the first direction X and is arranged only in a region directly above the resistive film 60.

The second electrode portion 92 faces the space region 57 with the main surface insulating film 45, the resistive film 60, and the interlayer insulating film 74 interposed therebetween. That is, the second electrode portion 92 faces the flat portion of the first main surface 3 in the thickness direction. Also, the second electrode portion 92 faces the boundary well region 40 (first boundary well region 40A) in the thickness direction.

The second electrode portion 92 has a width larger than the width of the trench resistive structure 51 in the first direction X with respect to the first direction X. The second electrode portion 92 has a width larger than the length of the trench resistive structure 51 in the second direction Y with respect to the second direction Y. The second electrode portion 92 preferably has a width smaller than the space width of the space region 57 in the second direction Y.

In this embodiment, the second electrode portion 92 is formed at intervals from the other end portion (first trench group 52) of the plurality of first trench resistive structures 51A toward the space region 57 side. Also, in this embodiment, the second electrode portion 92 is formed at intervals from one end portions (second trench group 53) of the plurality of second trench resistive structures 51B toward the space region 57 side. That is, the second electrode portion 92 faces only the space region 57 in the thickness direction and does not face the plurality of trench resistive structures 51 in the thickness direction.

As a matter of course, the second electrode portion 92 may face the other end portions (first trench group 52) of the plurality of first trench resistive structures 51A in the thickness direction. Also, the second electrode portion 92 may face one end portions (second trench group 53) of the plurality of second trench resistive structures 51B in the thickness direction. In view of the flatness of the second electrode portion 92, the second electrode portion 92 is preferably formed in a region outside the plurality of trench resistive structures 51 at intervals from the plurality of trench resistive structures 51 in plan view.

With reference to FIGS. 11 to 23, the semiconductor device 1A includes the gate wiring electrode 93 arranged on the first main surface 3 such as to be electrically connected to the gate resistive structure 50 in the pad region 10 (non-active region 7). Specifically, the gate wiring electrode 93 is arranged on the interlayer insulating film 74. The gate wiring electrode 93 may be referred to as a “gate finger” or a “gate finger electrode.”

The gate wiring electrode 93 is preferably constituted of a conductive material different from the resistive film 60. The gate wiring electrode 93 is preferably constituted of a conductive material different from the gate wiring film 65. The gate wiring electrode 93 has a lower resistance than that of the trench resistive structure 51 and the resistive film 60 and is electrically connected to the gate terminal electrode 90 via the trench resistive structure 51 and the resistive film 60. The gate wiring electrode 93 has a lower resistance than that of the gate wiring film 65.

In this embodiment, the gate wiring electrode 93 is constituted of a metal film. The gate wiring electrode 93 may be referred to as a “gate metal wiring.” The gate wiring electrode 93 may include at least one of a Ti film, a TiN film, a W film, an Al film, a Cu film, an Al alloy film, a Cu alloy film, and a conductive polysilicon film.

The gate wiring electrode 93 may include at least one of a pure Cu film, a pure Al film, an AlCu alloy film, an AlSi alloy film, and an AlSiCu alloy film. In this embodiment, the gate wiring film 65 has a laminated structure that includes a Ti film and an Al alloy film (in this embodiment, an AlCu alloy film) laminated in that order from the chip 2 side. That is, the gate wiring film 65 has the same electrode configuration as the gate terminal electrode 90.

The gate wiring electrode 93 preferably has a thickness larger than the thickness of the resistive film 60 (the thickness of the gate wiring film 65). The thickness of the gate wiring electrode 93 may be 1 μm or more and 10 μm or less. The thickness of the gate wiring electrode 93 is preferably substantially equal to the thickness of the gate terminal electrode 90.

The gate wiring electrode 93 is routed in a region between the active region 6 and the non-active region 7, is electrically connected to the first trench structure 21 (trench separation structure 15) in the active region 6, and is electrically connected to the resistive film 60 in the non-active region 7. Specifically, the gate wiring electrode 93 is electrically connected to the first end portion 60A and the second end portion 60B of the resistive film 60 via the gate wiring film 65.

That is, the gate wiring electrode 93 configures a parallel resistance circuit PR including the first gate resistor R1 and the second gate resistor R2 between the gate wiring electrode 93 and the gate terminal electrode 90 (see also FIG. 24). The parallel resistance circuit PR configures the gate resistance RG interposed between the gate terminal electrode 90 and the gate wiring electrode 93. The parallel resistance circuit PR is also established between the gate electrode film 64 and the gate wiring film 65. The resistance of the gate resistance RG (parallel resistance circuit PR) is calculated by the combined resistance (=(R1+R2)/R1·R2) of the first gate resistor R1 and the second gate resistor R2.

In this embodiment, the gate wiring electrode 93 includes a first upper wiring portion 94, a second upper wiring portion 95, and a third upper wiring portion 96. The first upper wiring portion 94 is arranged in the pad region 10 such as to surround the gate terminal electrode 90 from a plurality of directions (in this embodiment, three directions), and is arranged on the first lower wiring portion 66 of the gate wiring film 65 with the interlayer insulating film 74 interposed therebetween.

The first upper wiring portion 94 includes a first upper line portion 97 and a plurality of second upper line portions 98A and 98B. The first upper line portion 97 is arranged in a region covering the first lower line portion 69 of the gate wiring film 65 with the interlayer insulating film 74 interposed therebetween in the pad region 10 and is formed in a band shape extending in the second direction Y.

The first upper line portion 97 has one end portion on one side (the first side surface 5A side) in the second direction Y and the other end portion on the other side (the second side surface 5B side) in the second direction Y. The first upper line portion 97 covers the second slit 72 with the interlayer insulating film 74 interposed therebetween and backfills the second recess portion 77 of the interlayer insulating film 74 (insulating main surface 75).

When the gate terminal electrode 90 (the first electrode portion 91 and/or the second electrode portion 92) intersecting the second recess portion 77 and the gate wiring electrode 93 (first upper line portion 97) partially exposing the second recess portion 77 are formed, it is concerned that electrode residues generated during a step of forming the gate terminal electrode 90 remain in the plurality of second recess portions 77.

When the electrode residue exists, it is concerned that the gate wiring electrode 93 (first upper line portion 97) is electrically connected to the gate terminal electrode 90 via the electrode residue. In this case, the gate wiring electrode 93 (first upper line portion 97) configures a short circuit without interposing the gate resistive structure 50 together with the gate terminal electrode 90 (first electrode portion 91). Therefore, the gate wiring electrode 93 (first upper line portion 97) preferably covers the entire region of the second slit 72 with the interlayer insulating film 74 interposed therebetween.

That is, the gate wiring electrode 93 (first upper line portion 97) preferably fills the entire region of the second recess portion 77 of the interlayer insulating film 74 (insulating main surface 75). According to this configuration, a layout that avoids the problem of electrode residue in the second recess portion 77 is provided. The present disclosure does not exclude an embodiment including the gate terminal electrode 90 (the first electrode portion 91 and/or the second electrode portion 92) intersecting the second recess portion 77 and the gate wiring electrode 93 (first upper line portion 97) partially exposing the second recess portion 77.

The first upper line portion 97 is led out from above the gate wiring film 65 (first lower line portion 69) to above the resistive film 60 across the second slit 72 in plan view. The first upper line portion 97 covers the edge portion of the resistive film 60 with the interlayer insulating film 74 interposed therebetween. The first upper line portion 97 may further cross a straight line crossing the center portion of the resistive film 60 in the second direction Y to cover a portion of the resistive film 60 positioned in a region on the gate electrode film 64 side with respect to the straight line.

The first upper line portion 97 is formed at an interval from the first electrode portion 91 and the second electrode portion 92 of the gate terminal electrode 90 in the first direction X. In this embodiment, the first upper line portion 97 has a recess portion 97a recessed in the first direction X along the second electrode portion 92 in a portion along the second electrode portion 92 of the gate terminal electrode 90.

The first upper line portion 97 includes a first connection region 101 and a second connection region 102. The first connection region 101 is formed in a region on one side (the first side surface 5A side) in the second direction Y with respect to the recess portion 97a and faces the second electrode portion 92 in the second direction Y. The first connection region 101 covers the second covering portion 62 of the resistive film 60 with the interlayer insulating film 74 interposed therebetween. That is, the first connection region 101 covers the first trench group 52 (the plurality of first trench resistive structures 51A) with the interlayer insulating film 74 and the second covering portion 62 of the resistive film 60 interposed therebetween.

The first connection region 101 further covers the plurality of first resistance connection electrodes 81 and is electrically connected to the plurality of first resistance connection electrodes 81. As a result, the first connection region 101 is electrically connected to the second covering portion 62 of the resistive film 60 and the first trench group 52 (the plurality of first trench resistive structures 51A) via the plurality of first resistance connection electrodes 81.

The first connection region 101 suffices to cover one or the plurality of first trench resistive structures 51A adjacent to the one or the plurality of first resistance connection electrodes 81 and does not have to cover the all of the first trench resistive structures 51A. As a matter of course, the first connection region 101 may cover all of the first trench resistive structures 51A.

The second connection region 102 is formed in a region on the other side (the second side surface 5B side) in the second direction Y with respect to the recess portion 97a and faces the second electrode portion 92 in the second direction Y. The second connection region 102 covers the third covering portion 63 of the resistive film 60 with the interlayer insulating film 74 interposed therebetween. That is, the second connection region 102 covers the second trench group 53 (the plurality of second trench resistive structures 51B) with the interlayer insulating film 74 and the third covering portion 63 of the resistive film 60 interposed therebetween.

The second connection region 102 further covers the plurality of second resistance connection electrodes 82 and is electrically connected to the plurality of second resistance connection electrodes 82. As a result, the second connection region 102 is electrically connected to the third covering portion 63 of the resistive film 60 and the second trench group 53 (the plurality of second trench resistive structures 51B) via the plurality of second resistance connection electrodes 82.

The second connection region 102 suffices to cover one or the plurality of second trench resistive structures 51B adjacent to the one or the plurality of second resistance connection electrodes 82 and does not have to cover the all of the second trench resistive structures 51B. As a matter of course, the second connection region 102 may cover all of the second trench resistive structures 51B.

A facing area of the gate wiring electrode 93 (first upper line portion 97) with respect to the resistive film 60 is preferably larger than a facing area of the gate terminal electrode 90 (the first electrode portion 91 and the second electrode portion 92) with respect to the resistive film 60. As a matter of course, the facing area of the gate wiring electrode 93 may be smaller than the facing area of the gate terminal electrode 90.

When the gate terminal electrode 90 (first electrode portion 91) partially exposing the first recess portion 76 and the first upper line portion 97 intersecting to the first recess portion 76 is formed, it is concerned that an electrode residue generated during the step of forming the gate terminal electrode 90 remains in the plurality of first recess portions 76.

When the electrode residue exists, it is concerned that the gate wiring electrode 93 (first upper line portion 97) is electrically connected to the gate terminal electrode 90 (first electrode portion 91) via the electrode residue. In this case, the gate wiring electrode 93 (first upper line portion 97) configures a short circuit without interposing the gate resistive structure 50 together with the gate terminal electrode 90 (first electrode portion 91).

Therefore, it is preferable that the first upper line portion 97 is formed at an interval from the first recess portion 76 (first slit 71) toward the second recess portion 77 (second slit 72) side in plan view and does not intersect the first recess portion 76 (first slit 71). In this embodiment, the gate terminal electrode 90 (first electrode portion 91) covers the entire region of the first recess portion 76.

That is, the first upper line portion 97 faces the first electrode portion 91 and the second electrode portion 92 of the gate terminal electrode 90 in the first direction X in the region on the resistive film 60. According to this configuration, a layout that avoids the problem of electrode residue in the first recess portion 76 is provided. The present disclosure does not exclude an embodiment including the gate terminal electrode 90 (first electrode portion 91) partially exposing the first recess portion 76 and the first upper line portion 97 intersecting the first recess portion 76.

The first current I1 applied to the gate terminal electrode 90 (second electrode portion 92) is transmitted to the first covering portion 61 of the resistive film 60 via the plurality of first resistance connection electrodes 81. The first current I1 transmitted to the first covering portion 61 is divided into the second current I2 on the second covering portion 62 (first trench group 52) side of the resistive film 60 and the third current I3 on the third covering portion 63 (second trench group 53) side of the resistive film 60.

The second current I2 is transmitted to the first connection region 101 of the first upper line portion 97 via the plurality of second resistance connection electrodes 82, and the third current I3 is transmitted to the second connection region 102 of the first upper line portion 97 via the plurality of third resistance connection electrodes 83. Thus, the gate wiring electrode 93 (first upper line portion 97) configures the parallel resistance circuit PR including the first gate resistor R1 and the second gate resistor R2 between the gate wiring electrode 93 (first upper line portion 97) and the gate terminal electrode 90 (second electrode portion 92) (see also FIG. 24).

The plurality of second upper line portions 98A and 98B include the second upper line portion 98A on one side and a second upper line portion 98B on the other side. The second upper line portion 98A is arranged in a region on one side (the first side surface 5A side) in the second direction Y with respect to the gate terminal electrode 90 in the pad region 10. The second upper line portion 98B is arranged in a region on the other side (the second side surface 5B side) in the second direction Y with respect to the gate terminal electrode 90 in the pad region 10.

The second upper line portion 98A is formed in a band shape extending in the first direction X and has one end portion connected to one end portion of the first upper line portion 97 and the other end portion positioned on the peripheral edge side (the third side surface 5C side) of the chip 2. The second upper line portion 98A covers the second lower line portion 70A of the gate wiring film 65 with the interlayer insulating film 74 interposed therebetween. The second upper line portion 98A is formed at an interval from the first electrode portion 91 of the gate terminal electrode 90 toward one side in the second direction Y.

The second upper line portion 98B is formed in a band shape extending in the first direction X and has the other end portion connected to one end portion of the first upper line portion 97 and the other end portion positioned on the peripheral edge side (the third side surface 5C side) of the chip 2. The second upper line portion 98B covers the second lower line portion 70B of the gate wiring film 65 with the interlayer insulating film 74 interposed therebetween. The second upper line portion 98B is formed at an interval from the first electrode portion 91 of the gate terminal electrode 90 toward the other side in the second direction Y and faces the second upper line portion 98A with the first electrode portion 91 interposed therebetween.

When the gate terminal electrode 90 (first electrode portion 91) partially exposing the first recess portion 76 and the second upper line portions 98A and 98B intersecting to the first recess portion 76 are formed, it is concerned that an electrode residue generated during the step of forming the gate terminal electrode 90 remains in the first recess portion 76. When the electrode residue exists, it is concerned that the gate wiring electrode 93 (second upper line portions 98A and 98B) is electrically connected to the gate terminal electrode 90 (first electrode portion 91) via the electrode residue.

In this case, the gate wiring electrode 93 (second upper line portions 98A and 98B) configures a short circuit without interposing the gate resistive structure 50 together with the gate terminal electrode 90 (first electrode portion 91). Therefore, it is preferable that the second upper line portions 98A and 98B are arranged at intervals from the first recess portion 76 and do not have a portion that covers the first recess portion 76 (a portion intersecting the first recess portion 76).

According to this configuration, a layout that avoids the problem of electrode residue in the first recess portion 76 is provided. The present disclosure does not exclude an embodiment including the gate terminal electrode 90 (first electrode portion 91) partially exposing the first recess portion 76 and the second upper line portions 98A and 98B intersecting the first recess portion 76.

Also, when the gate terminal electrode 90 (first electrode portion 91) that partially exposes the plurality of third recess portions 78 and second upper line portions 98A and 98B that intersect the plurality of third recess portions 78 are formed, it is concerned that the electrode residue generated during the step of forming the gate terminal electrode 90 remains in the plurality of third recess portions 78. In these cases, the gate wiring electrode 93 (second upper line portions 98A and 98B) configures a short circuit without interposing the gate resistive structure 50 together with the gate terminal electrode 90 (first electrode portion 91).

Therefore, it is preferable that the second upper line portions 98A and 98B are arranged at intervals from the plurality of third recess portions 78 and do not have a portion that covers the plurality of third recess portions 78 (a portion intersecting the plurality of third recess portions 78). According to this configuration, a layout that avoids the problem of electrode residue in the plurality of third recess portions 78 is provided. In this embodiment, the gate terminal electrode 90 (first electrode portion 91) covers the entire region of the plurality of third recess portions 78.

That is, the second upper line portions 98A and 98B face the first electrode portion 91 of the gate terminal electrode 90 in the second direction Y in the region on the second lower line portions 70A and 70B. The present disclosure does not exclude an embodiment including the gate terminal electrode 90 (first electrode portion 91) partially exposing the plurality of third recess portions 78 and the second upper line portions 98A and 98B intersecting the plurality of third recess portions 78.

The second upper line portions 98A and 98B preferably cover the inner portions of the second lower line portions 70A and 70B at intervals from the peripheral edges of the second lower line portions 70A and 70B in plan view. That is, it is preferable that the second upper line portions 98A and 98B face only the second lower line portions 70A and 70B with the interlayer insulating film 74 interposed therebetween and do not face the main surface insulating film 45 with the interlayer insulating film 74 interposed therebetween.

The second upper wiring portion 95 is led out from the first upper wiring portion 94 to the street region 11 and covers the second lower wiring portion 67 of the gate wiring film 65 with the interlayer insulating film 74 interposed therebetween. More specifically, the second upper wiring portion 95 is led out from the inner portion (the central portion in this embodiment) of the first upper line portion 97 and is formed in a band shape extending in the first direction X.

In this embodiment, the second upper wiring portion 95 crosses the center of the chip 2. The second upper wiring portion 95 extends in a band shape such as to be positioned in a region on one side (the third side surface 5C side) and a region on the other side (the fourth side surface 5D side) in the first direction X with respect to a straight line crossing the center of the first main surface 3 in the second direction Y. The second upper wiring portion 95 has one end portion connected to the first upper wiring portion 94 on one side in the first direction X and the other end portion on the other side in the first direction X. In this embodiment, the other end portion of the second upper wiring portion 95 is an open end.

The second upper wiring portion 95 covers the plurality of first gate connection electrodes 84A and is electrically connected to the second lower wiring portion 67 via the plurality of first gate connection electrodes 84A. The second upper wiring portion 95 has a width smaller than the width of the street region 11 in the second direction Y and is formed at intervals inward of the street region 11 from the plurality of active regions 6. That is, the second upper wiring portion 95 is formed at an interval from the plurality of trench separation structures 15 (the plurality of first trench structures 21) in plan view.

The third upper wiring portion 96 is led out from the first upper wiring portion 94 to the outer peripheral region 9 and covers the third lower wiring portion 68 of the gate wiring film 65 with the interlayer insulating film 74 interposed therebetween. Specifically, the third upper wiring portion 96 is led out from the other end portions of the plurality of second upper line portions 98A and 98B to one side (the first side surface 5A side) and the other side (the second side surface 5B side) of the outer peripheral region 9 and is formed in a band shape extending along the outer peripheral region 9.

The third upper wiring portion 96 interposes the plurality of active regions 6 together with the second upper wiring portion 95. Specifically, the third upper wiring portion 96 extends along the peripheral edges (first side surfaces 5A to 5D) of the chip 2 such as to surround the plurality of active regions 6 in plan view. Therefore, the third upper wiring portion 96 surrounds the plurality of active regions 6 together with the second upper wiring portion 95. In this embodiment, the third upper wiring portion 96 is formed at an interval from the second upper wiring portion 95. The third upper wiring portion 96 may be connected to the second upper wiring portion 95.

The third upper wiring portion 96 covers the plurality of second gate connection electrodes 84B and is electrically connected to the third lower wiring portion 68 via the plurality of second gate connection electrodes 84B. The third upper wiring portion 96 preferably has a width smaller than the width of the third lower wiring portion 68 in plan view. The third upper wiring portion 96 preferably covers the inner portion of the third lower wiring portion 68 at an interval from the peripheral edge of the third lower wiring portion 68 in plan view.

With reference to FIGS. 1 and 11 to 22, the semiconductor device 1A includes an emitter terminal electrode 103 arranged on the first main surface 3 at an interval from the gate terminal electrode 90 and the gate wiring electrode 93 in the active region 6. Specifically, the emitter terminal electrode 103 is arranged on the interlayer insulating film 74.

The emitter terminal electrode 103 may be referred to as an “emitter pad” or an “emitter pad electrode.” The emitter terminal electrode 103 is preferably constituted of a conductive material different from the resistive film 60. The emitter terminal electrode 103 is preferably constituted of a conductive material different from the emitter electrode film 47.

The emitter terminal electrode 103 has a lower resistance than that of the trench resistive structure 51 and the resistive film 60. In this embodiment, the emitter terminal electrode 103 is constituted of a metal film. The emitter terminal electrode 103 may be referred to as an “emitter metal terminal.” The emitter terminal electrode 103 may include at least one of a Ti film, a TiN film, a W film, an Al film, a Cu film, an Al alloy film, a Cu alloy film, and a conductive polysilicon film.

The emitter terminal electrode 103 may include at least one of a pure Cu film, a pure Al film, an AlCu alloy film, an AlSi alloy film, and an AlSiCu alloy film. In this embodiment, the emitter terminal electrode 103 has a laminated structure that includes a Ti film and an Al alloy film (in this embodiment, an AlCu alloy film) laminated in that order from the chip 2 side. That is, the emitter terminal electrode 103 has the same electrode configuration as the gate terminal electrode 90.

The emitter terminal electrode 103 preferably has a thickness larger than the thickness of the resistive film 60 (the thickness of the gate electrode film 64). The thickness of the emitter terminal electrode 103 may be 1 μm or more and 10 μm or less. The thickness of the emitter terminal electrode 103 is preferably substantially equal to the thickness of the gate terminal electrode 90.

The emitter terminal electrode 103 has a plane area larger than the plane area of the gate terminal electrode 90. The plane area of the emitter terminal electrode 103 is preferably 50% or more and 90% or less of the plane area of the first main surface 3. The plane area of the emitter terminal electrode 103 is particularly preferably 70% or more of the plane area of the first main surface 3.

In this embodiment, the emitter terminal electrode 103 includes a first emitter terminal electrode 103A and a second emitter terminal electrode 103B. The first emitter terminal electrode 103A is arranged in a region between the second upper wiring portion 95 and the third upper wiring portion 96 on a portion of the interlayer insulating film 74 covering the first active region 6A. The first emitter terminal electrode 103A is led out from the first active region 6A to the outer peripheral region 9 in plan view.

The first emitter terminal electrode 103A covers the plurality of first emitter connection electrodes 85 and the plurality of second emitter connection electrodes 86 in the first active region 6A and covers the plurality of first well connection electrodes 87 in the outer peripheral region 9.

The first emitter terminal electrode 103A is electrically connected to the plurality of second trench structures 25, the plurality of emitter regions 29, and the plurality of contact regions 31 via the plurality of first emitter connection electrodes 85 and the plurality of second emitter connection electrodes 86. The first emitter terminal electrode 103A is electrically connected to the inner edge portion of the outer peripheral well region 41 via the plurality of first well connection electrodes 87.

The second emitter terminal electrode 103B is arranged in a region between the second upper wiring portion 95 and the third upper wiring portion 96 on a portion of the interlayer insulating film 74 covering the second active region 6B. The second emitter terminal electrode 103B is led out from the second active region 6B to the outer peripheral region 9 in plan view.

The second emitter terminal electrode 103B covers the plurality of first emitter connection electrodes 85 and the plurality of second emitter connection electrodes 86 in the second active region 6B and covers the plurality of first well connection electrodes 87 in the outer peripheral region 9.

The second emitter terminal electrode 103B is electrically connected to the plurality of second trench structures 25, the plurality of emitter regions 29, and the plurality of contact regions 31 via the plurality of first emitter connection electrodes 85 and the plurality of second emitter connection electrodes 86. The second emitter terminal electrode 103B is electrically connected to the inner edge portion of the outer peripheral well region 41 via the plurality of first well connection electrodes 87.

The semiconductor device 1A includes an emitter wiring electrode 104 led out from the emitter terminal electrode 103 to a region outside the gate wiring electrode 93 on the interlayer insulating film 74. The emitter wiring electrode 104 may be referred to as an “emitter finger” or an “emitter finger electrode.” The emitter wiring electrode 104 is preferably constituted of a conductive material different from the resistive film 60. The emitter wiring electrode 104 is preferably constituted of a conductive material different from the emitter electrode film 47.

The emitter wiring electrode 104 has a lower resistance than that of the trench resistive structure 51 and the resistive film 60. In this embodiment, the emitter wiring electrode 104 is constituted of a metal film. The emitter wiring electrode 104 may be referred to as an “emitter metal wiring.” The emitter wiring electrode 104 may include at least one of a Ti film, a TiN film, a W film, an Al film, a Cu film, an Al alloy film, a Cu alloy film, and a conductive polysilicon film.

The emitter wiring electrode 104 may include at least one of a pure Cu film, a pure Al film, an AlCu alloy film, an AlSi alloy film, and an AlSiCu alloy film. In this embodiment, the emitter wiring electrode 104 has a laminated structure that includes a Ti film and an Al alloy film (in this embodiment, an AlCu alloy film) laminated in that order from the chip 2 side. That is, the emitter wiring electrode 104 has the same electrode configuration as the emitter terminal electrode 103.

The emitter wiring electrode 104 preferably has a thickness larger than the thickness of the resistive film 60 (the thickness of the gate electrode film 64). The thickness of the emitter wiring electrode 104 may be 1 μm or more and 10 μm or less. The thickness of the emitter wiring electrode 104 is preferably substantially equal to the thickness of the gate terminal electrode 90 (emitter terminal electrode 103).

The emitter wiring electrode 104 is connected to both the first emitter terminal electrode 103A and the second emitter terminal electrode 103B and is led out from the first emitter terminal electrode 103A and the second emitter terminal electrode 103B to a region further outward than the gate wiring electrode 93 (third upper wiring portion 96).

The emitter wiring electrode 104 is formed in a band shape extending along the peripheral edge of the chip 2 such as to surround the gate terminal electrode 90, the gate wiring electrode 93, the first emitter terminal electrode 103A, and the second emitter terminal electrode 103B. In this embodiment, the emitter wiring electrode 104 is formed in an annular shape (specifically, a quadrangular annular shape) extending along the peripheral edge (first to fourth side surfaces 5A to 5D) of the chip 2 and collectively surrounds the gate terminal electrode 90, the gate wiring electrode 93, the first emitter terminal electrode 103A, and the second emitter terminal electrode 103B.

The emitter wiring electrode 104 is routed in a portion of the interlayer insulating film 74 covering the outer edge portion of the outer peripheral well region 41. The emitter wiring electrode 104 covers the plurality of second well connection electrodes 88 and is electrically connected to the outer edge portion of the outer peripheral well region 41 via the plurality of second well connection electrodes 88.

The semiconductor device 1A includes a plurality of field electrodes 105 arranged on the interlayer insulating film 74 in the outer peripheral region 9. The plurality of field electrodes 105 may include at least one of a Ti film, a TiN film, a W film, an Al film, a Cu film, an Al alloy film, a Cu alloy film, and a conductive polysilicon film.

The plurality of field electrodes 105 may include at least one of a pure Cu film, a pure Al film, an AlCu alloy film, an AlSi alloy film, and an AlSiCu alloy film. In this embodiment, the plurality of field electrodes 105 have a laminated structure that includes a Ti film and an Al alloy film (in this embodiment, an AlCu alloy film) laminated in that order from the chip 2 side.

The plurality of field electrodes 105 covers the corresponding field region 42 in a one-to-one correspondence relationship. The field electrodes 105 collectively cover the plurality of corresponding field connection electrodes 89. The field electrodes 105 are electrically connected to the corresponding field region 42 via the plurality of corresponding field connection electrodes 89, respectively. The plurality of field electrodes 105 are formed in an electrically floating state.

The plurality of field electrodes 105 are formed in a band shape extending along the corresponding field region 42. In this embodiment, the plurality of field electrodes 105 are formed in an annular shape (quadrangular annular shape) extending along the corresponding field region 42. The outermost field electrode 105 includes a field lead-out portion 105a led out toward the peripheral edge side of the chip 2 and may be formed to be wider than the other field electrodes 105.

The semiconductor device 1A includes a channel stop electrode 106 arranged on the interlayer insulating film 74 in the outer peripheral region 9. The channel stop electrode 106 may include at least one of a Ti film, a TiN film, a W film, an Al film, a Cu film, an Al alloy film, a Cu alloy film, and a conductive polysilicon film.

The channel stop electrode 106 may include at least one of a pure Cu film, a pure Al film, an AlCu alloy film, an AlSi alloy film, and an AlSiCu alloy film. In this embodiment, the channel stop electrode 106 has a laminated structure that includes a Ti film and an Al alloy film (in this embodiment, an AlCu alloy film) laminated in that order from the chip 2 side.

The channel stop electrode 106 is formed in a band shape extending along the peripheral edge of the first main surface 3. In this embodiment, the channel stop electrode 106 is formed in an annular shape (quadrangular annular shape) extending along the peripheral edge of the first main surface 3.

The channel stop electrode 106 enters the removed portion 46 of the interlayer insulating film 74 from above the interlayer insulating film 74 and is electrically connected to the channel stop region 43. The channel stop electrode 106 is formed in an electrically floating state. The channel stop electrode 106 may be formed at an interval inward from the peripheral edge of the chip 2 such as to expose the peripheral edge portion (channel stop region 43) of the first main surface 3.

The semiconductor device 1A includes a collector electrode 107 that covers the second main surface 4. The collector electrode 107 is electrically connected to the collector region 14 exposed from the second main surface 4. The collector electrode 107 forms an ohmic contact with the collector region 14. The collector electrode 107 may cover a whole region of the second main surface 4 such as to be continuous with the peripheral edge of the chip 2 (first to fourth side surfaces 5A to 5D).

As described above, the semiconductor device 1A includes the chip 2, the trench resistive structure 51, the resistive film 60, the gate terminal electrode 90, and the gate wiring electrode 93. The chip 2 has the first main surface 3. The trench resistive structure 51 is formed in the first main surface 3. The resistive film 60 is electrically connected to the trench resistive structure 51 on the first main surface 3.

The gate terminal electrode 90 has a lower resistance than that of the resistive film 60 and is electrically connected to the trench resistive structure 51 on the first main surface 3 via the resistive film 60. The gate wiring electrode 93 has a lower resistance than that of the resistive film 60 and is electrically connected to the gate terminal electrode 90 on the first main surface 3 via the trench resistive structure 51 and the resistive film 60.

According to this configuration, the gate resistance RG including the trench resistive structure 51 and the resistive film 60 can be interposed between the gate terminal electrode 90 and the gate wiring electrode 93. Particularly, according to this configuration, since the trench resistive structure 51 is incorporated in the chip 2 in the region between the gate terminal electrode 90 and the gate wiring electrode 93, an increase in the occupied area of the gate resistance RG with respect to the first main surface 3 can be suppressed. Therefore, it is possible to provide the semiconductor device 1A having a novel layout that contributes to miniaturization in the configuration including the gate resistance RG.

The semiconductor device 1A preferably includes the gate electrode film 64 and the gate wiring film 65. The gate electrode film 64 is arranged on the first main surface 3 adjacent to the resistive film 60. The gate wiring film 65 is arranged on the first main surface 3 adjacent to the resistive film 60 to face the gate electrode film 64 with the resistive film 60 interposed therebetween.

In such a structure, the gate terminal electrode 90 preferably covers the gate electrode film 64. Also, the gate wiring electrode 93 preferably covers gate wiring film 65. According to this configuration, in the configuration including resistive film 60, the gate electrode film 64, and the gate wiring film 65 on the first main surface 3, it is possible to provide the semiconductor device 1A having a novel layout that contributes to miniaturization.

The resistive film 60 preferably has the first end portion 60A on one side and the second end portion 60B on the other side. In this case, the gate wiring film 65 preferably includes a first connection portion connected to the first end portion 60A of the resistive film 60 and a second connection portion connected to the second end portion 60B of the resistive film 60. In this case, the gate wiring electrode 93 is preferably electrically connected to the resistive film 60 via the gate wiring film 65.

According to this configuration, since the gate wiring electrode 93 can be electrically connected to the resistive film 60 via the gate wiring film 65, it is not necessary to directly connect the gate wiring electrode 93 to the resistive film 60. Consequently, the design rule of the gate wiring electrode 93 can be relaxed, and the degree of freedom of design the gate wiring electrode 93 can be improved.

The semiconductor device 1A preferably includes the first slit 71 demarcated between the resistive film 60 and the gate electrode film 64, and the second slit 72 demarcated between the resistive film 60 and the gate wiring film 65. According to this configuration, the resistive film 60 can be appropriately separated (demarcated) from the gate electrode film 64 and the gate wiring film 65 by the first slit 71 and the second slit 72. As a result, the accuracy of the resistance of the resistive film 60 can be improved.

The gate terminal electrode 90 preferably covers the resistive film 60 and the gate electrode film 64 across the first slit 71 in plan view. The gate wiring film 65 preferably covers the resistive film 60 and the gate electrode film 64 across the second slit 72 in plan view. The first slit 71 is preferably formed to be narrower than the resistive film 60. The second slit 72 is preferably formed to be narrower than the resistive film 60.

The trench resistive structure 51 preferably extends in a band shape in the second direction Y (one direction) in plan view. In this case, the resistive film 60 preferably extends in a band shape in the second direction Y (one direction) in plan view. Also, the first slit 71 preferably extends in a band shape in the second direction Y (one direction) in plan view.

Also, the second slit 72 preferably extends in a band shape in the second direction Y (one direction) in plan view. The first slit 71 may have a first length in the second direction Y (one direction), and the second slit 72 may have a second length smaller than the first length in the second direction Y (one direction).

The semiconductor device 1A preferably includes the third slit 73 demarcated between the gate electrode film 64 and the gate wiring film 65. According to this configuration, the gate wiring film 65 can be appropriately separated (demarcated) from the gate electrode film 64 by the third slit 73. As a result, it is possible to suppress formation, by the gate wiring film 65, of a short circuit not interposing the resistive film 60 together with the gate electrode film 64. The gate terminal electrode 90 preferably covers the gate electrode film 64 and the gate wiring film 65 across the third slit 73 in plan view.

The plurality of trench resistive structures 51 are preferably formed in the first main surface 3 at intervals. In this case, the resistive film 60 preferably covers the plurality of trench resistive structures 51. According to this configuration, the resistance of the gate resistance RG can be adjusted using the plurality of trench resistive structures 51.

The resistive film 60 preferably includes the first covering portion 61 covering the first main surface 3 outside the trench resistive structure 51 and the second covering portion 62 covering the trench resistive structure 51. In this case, the gate terminal electrode 90 is preferably electrically connected to the resistive film 60 at a portion that covers the first covering portion 61.

Also, the gate wiring electrode 93 is preferably electrically connected to the resistive film 60 at a portion that covers the second covering portion 62. According to this configuration, a part of the resistive film 60 and a part of the trench resistive structure 51 can be appropriately interposed in the region between the gate terminal electrode 90 and the gate wiring electrode 93.

The semiconductor device 1A preferably includes the interlayer insulating film 74, the first resistance connection electrode 81, and the second resistance connection electrode 82. The interlayer insulating film 74 covers the resistive film 60. The first resistance connection electrode 81 is embedded in the interlayer insulating film 74 such as to be electrically connected to the resistive film 60. The second resistance connection electrode 82 is embedded in the interlayer insulating film 74 such as to be electrically connected to the resistive film 60 at a different position from the first resistance connection electrode 81.

In such a configuration, the gate terminal electrode 90 is preferably arranged on the interlayer insulating film 74 such as to be electrically connected to the resistive film 60 via the first resistance connection electrode 81. Also, the gate wiring electrode 93 is preferably arranged on the interlayer insulating film 74 such as to be electrically connected to the resistive film 60 via the second resistance connection electrode 82.

According to this configuration, the gate resistance RG can be configured in the region between the first resistance connection electrode 81 and the second resistance connection electrode 82. The resistance of the gate resistance RG can be adjusted by adjusting the distance between the first resistance connection electrode 81 and the second resistance connection electrode 82.

The second resistance connection electrode 82 may extend in a different direction from the first resistance connection electrode 81. For example, the first resistance connection electrode 81 may extend in the first direction X (one direction) in plan view, and the second resistance connection electrode 82 may extend in the second direction Y (intersecting direction) intersecting the first direction X (one direction) in plan view.

The plurality of first resistance connection electrodes 81 are preferably embedded in the interlayer insulating film 74. The plurality of second resistance connection electrodes 82 are preferably embedded in the interlayer insulating film 74. The second connection area S2 of the second resistance connection electrode 82 with respect to the resistive film 60 may be smaller than the first connection area S1 of the first resistance connection electrode 81 with respect to the resistive film 60.

The gate terminal electrode 90 preferably includes the first electrode portion 91 positioned outside the first resistance connection electrode 81 in plan view and the second electrode portion 92 protruding from the first electrode portion 91 toward the first resistance connection electrode 81 to be narrower than the first electrode portion 91. In this case, the first electrode portion 91 is preferably formed as a terminal main body portion of the gate terminal electrode 90. Also, the second electrode portion 92 is preferably formed as a terminal lead-out portion led out from the terminal main body portion.

According to these configurations, the region to which the gate potential is applied can be secured by the first electrode portion 91, and the region electrically connected to the resistive film 60 can be secured by the second electrode portion 92. For example, when a conductive bonding material such as a bonding wire is bonded to the gate terminal electrode 90, the conductive bonding material can be bonded to the first electrode portion 91. As a result, it is possible to suppress generation, in the resistive film 60 or the trench resistive structure 51, of stress caused by the conductive bonding material. Therefore, it is possible to suppress a decrease in electrical characteristics of the gate resistance RG.

The semiconductor device 1A preferably includes the p-type boundary well region 40 formed in a surface layer portion of the first main surface 3. According to this configuration, the breakdown voltage can be improved by the boundary well region 40. In this case, the trench resistive structure 51 is preferably formed at an interval from the bottom portion of the boundary well region 40 toward the first main surface 3 side. According to this configuration, the electric field concentration on the bottom wall of the trench resistive structure 51 can be suppressed by the boundary well region 40. Therefore, the breakdown voltage can be appropriately improved.

The semiconductor device 1A preferably includes the active region 6 provided in the first main surface 3, the non-active region 7 provided outside the active region 6 in the first main surface 3, and the first trench structure 21 (the trench gate structure) formed in the active region 6. In this case, the trench resistive structure 51 is preferably formed in the non-active region 7. Also, the resistive film 60 preferably covers the trench resistive structure 51 in the non-active region 7.

Also, the gate terminal electrode 90 is preferably electrically connected to the resistive film 60 in the non-active region 7. Also, the gate wiring electrode 93 is preferably electrically connected to the first trench structure 21 in the active region 6 and is electrically connected to the resistive film 60 in the non-active region 7. According to these configurations, since the gate resistance RG is formed in the non-active region 7, reduction of the active region 6 can be suppressed.

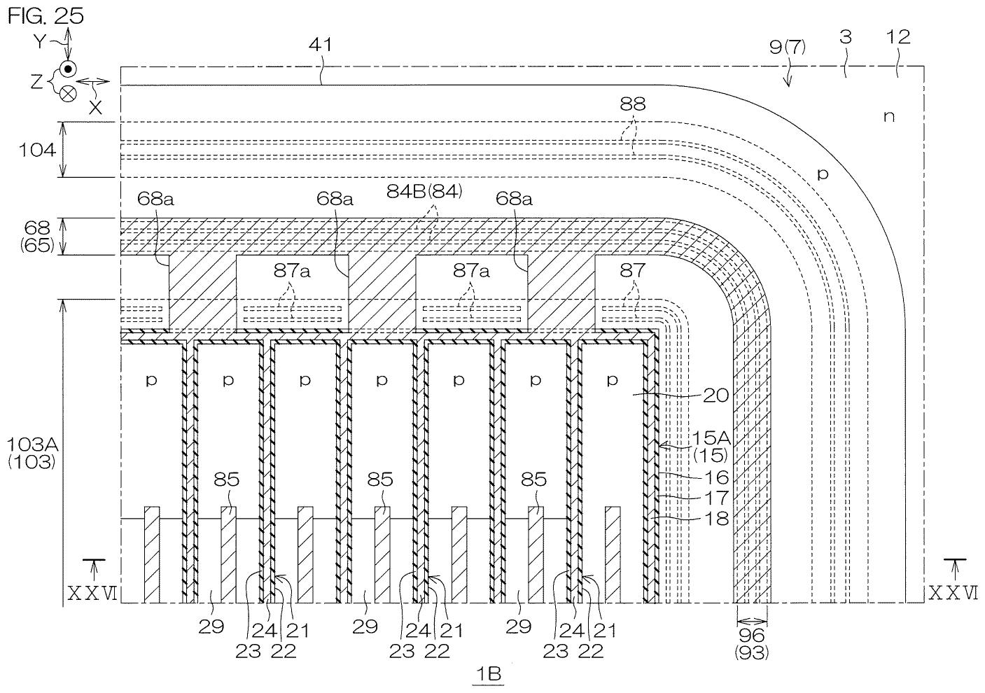

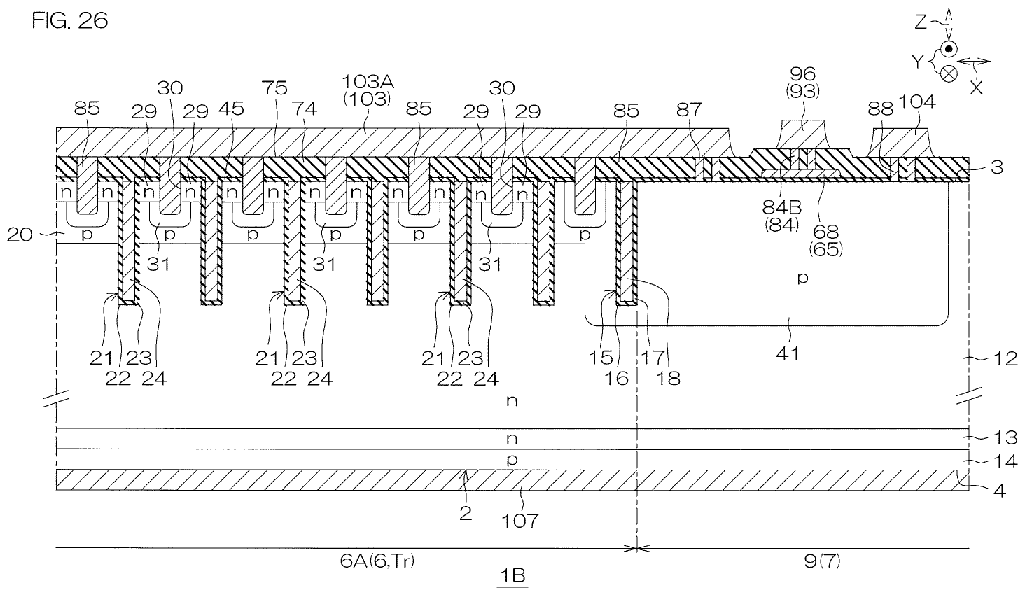

FIG. 25 is a plan view illustrating a layout of the first main surface 3 of a semiconductor device 1B according to a second embodiment. FIG. 26 is a cross-sectional view taken along line XXVI-XXVI illustrated in FIG. 25. The semiconductor device 1B is a device that achieves an effect similar to the effect according to the semiconductor device 1A. The semiconductor device 1A according to the first embodiment has the second trench structure 25 and the floating region 32.

Meanwhile, the semiconductor device 1B does not have the second trench structure 25 and the floating region 32. Specifically, with reference to FIGS. 25 and 26, the semiconductor device 1B includes the plurality of first trench structures 21 that are arranged at intervals in the first direction X such as to be adjacent to each other in the plurality of active regions 6 and are formed in a band shape extending in the second direction Y. The emitter regions 29 described above are respectively formed in each region between the plurality of first trench structures 21 adjacent to each other in the surface layer portion of the first main surface 3. The contact holes 30 described above are respectively formed in regions between the plurality of first trench structures 21 adjacent to each other in plan view.

In the first direction X, the interval between the plurality of trench resistive structures 51 may be substantially equal to the interval between the plurality of first trench structures 21. As a matter of course, the interval between the plurality of trench resistive structures 51 may be larger than the interval between the plurality of first trench structures 21. Also, the interval between the plurality of trench resistive structures 51 may be smaller than the interval between the plurality of first trench structures 21.

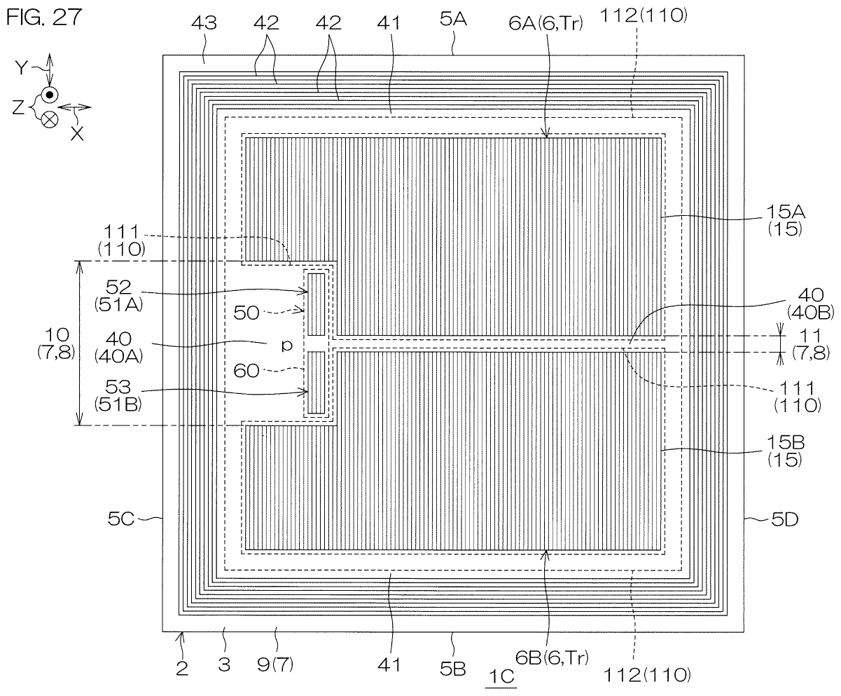

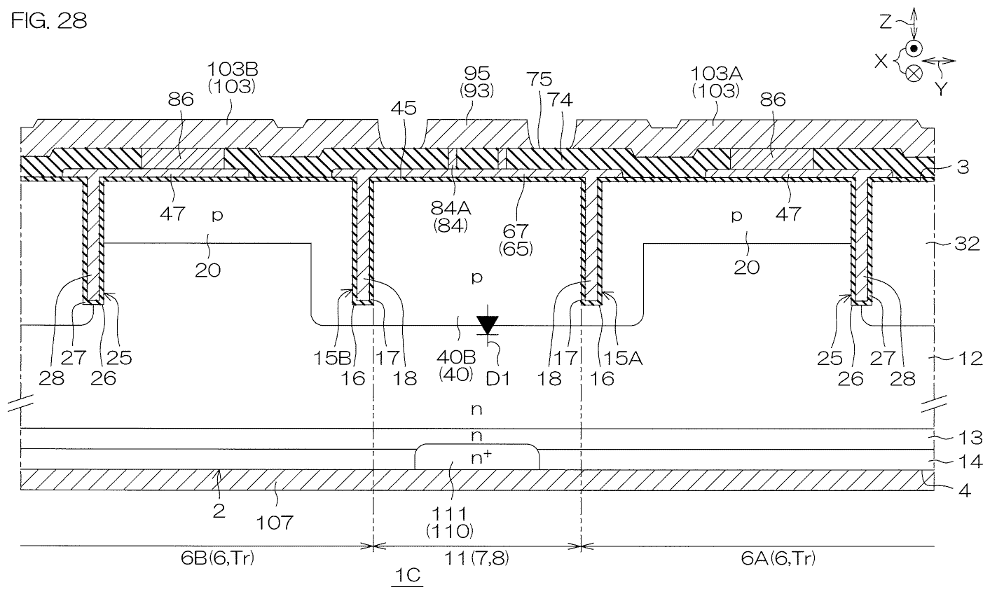

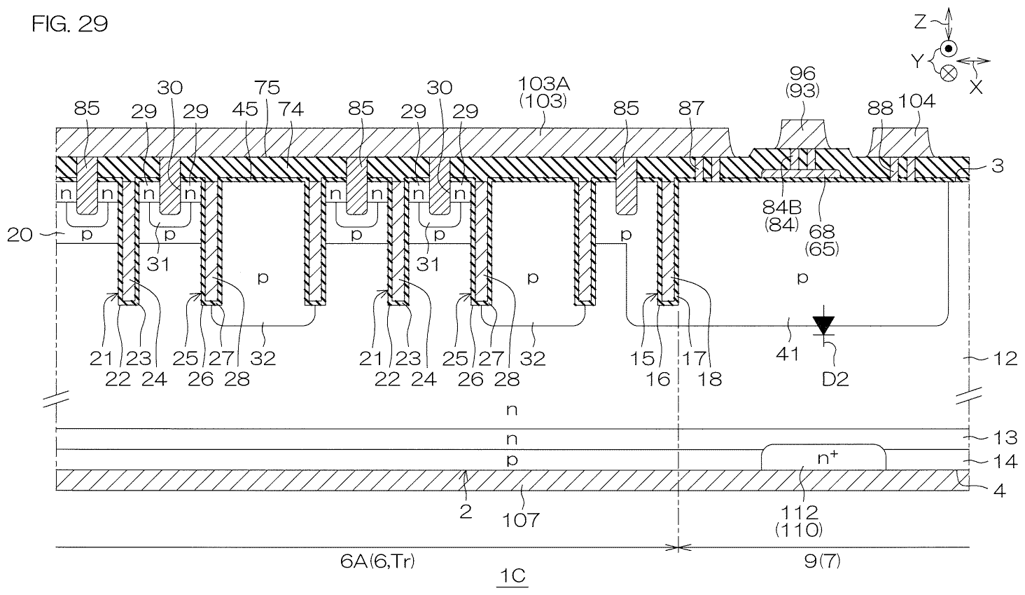

FIG. 27 is a plan view illustrating a layout of the first main surface 3 of a semiconductor device 1C according to a third embodiment. FIG. 28 is a cross-sectional view illustrating a structure on the boundary region 8 side of the semiconductor device 1C illustrated in FIG. 27. FIG. 29 is a cross-sectional view illustrating a structure on the outer peripheral region 9 side of the semiconductor device 1C illustrated in FIG. 27. The semiconductor device 1C is a device that achieves an effect similar to the effect according to the semiconductor device 1A.

With reference to FIGS. 27 to 29, the semiconductor device 1C is an RC-IGBT semiconductor device having an RC-IGBT (reverse conducting-IGBT) which includes an IGBT (insulated gate bipolar transistor) and a diode in an integral manner. The diode is a freewheeling diode for the IGBT.

Specifically, the semiconductor device 1C includes an n-type cathode region 110 formed in a surface layer portion of the second main surface 4 in addition to the configuration of the semiconductor device 1A described above. The cathode region 110 has an n-type impurity concentration the than p-type impurity concentration higher that of the collector region 14 and includes a region in which the conductivity type of a part of the collector region 14 is replaced from a p-type to an n-type.

The cathode region 110 penetrates through the collector region 14 and is connected to the buffer region 13. When the buffer region 13 is not formed, the cathode region 110 is connected to the drift region 12. The cathode region 110 preferably has a higher n-type impurity concentration than that of the drift region 12 and the buffer region 13.

In this embodiment, the cathode region 110 includes a boundary cathode region 111 formed in the surface layer portion of the second main surface 4 in the boundary region 8 and an outer peripheral cathode region 112 formed in the surface layer portion of the second main surface 4 in the outer peripheral region 9.

The cathode region 110 suffices to include at least one of the boundary cathode region 111 and the outer peripheral cathode region 112 and does not necessarily include both the boundary cathode region 111 and the outer peripheral cathode region 112 at the same time. The cathode region 110 may include only the boundary cathode region 111, or the cathode region 110 may include only the outer peripheral cathode region 112.

The boundary cathode region 111 is formed in the surface layer portion of the second main surface 4 to face the boundary well region 40 in the thickness direction of the chip 2 in the boundary region 8. The boundary cathode region 111 is formed in a region interposed between the first trench separation structure 15A and the second trench separation structure 15B in plan view.

That is, the boundary cathode region 111 is formed in a region interposed between the plurality of first trench structures 21 on the first active region 6A side and the plurality of first trench structures 21 on the second active region 6B side in plan view. The boundary cathode region 111 is preferably formed at an interval from the base region 20 in the direction along the second main surface 4 such as not to face the base region 20 of each active region 6 in the thickness direction.

The boundary cathode region 111 is particularly preferably formed at an interval from the plurality of first trench structures 21 in the direction along the second main surface 4 such as not to face the plurality of first trench structures 21 in the thickness direction of the chip 2. In this embodiment, the boundary cathode region 111 is formed at an interval from the plurality of trench separation structures 15 in the direction along the second main surface 4.

That is, the boundary cathode region 111 has a width smaller than the width of the boundary region 8 in the second direction Y. Also, the boundary cathode region 111 is formed in the surface layer portion of the second main surface 4 such as to remain a part of the collector region 14 in the boundary region 8. That is, the semiconductor device 1C includes the collector region 14 formed in the street region 11.

The boundary cathode region 111 is formed in either or both of the pad region 10 and the street region 11. That is, the boundary cathode region 111 may be formed in the street region 11 and may not be formed in the pad region 10. Also, the boundary cathode region 111 may be formed in the pad region 10 and may not be formed in the street region 11. In this embodiment, the boundary cathode region 111 is formed in both the pad region 10 and the street region 11.

When the boundary cathode region 111 is formed in the pad region 10, the boundary cathode region 111 is formed in a polygonal shape (quadrangular shape) along the peripheral edge of the pad region 10 in the pad region 10. The boundary cathode region 111 faces the first boundary well region 40A of the boundary well region 40 in the thickness direction of the chip 2 in the pad region 10.

In this case, the boundary cathode region 111 may face any one or both of the first trench group 52 (a plurality of first trench resistive structures 51A) and the second trench group 53 (the plurality of second trench resistive structures 51B) with the first boundary well region 40A interposed therebetween. The boundary cathode region 111 may face some or all of the plurality of first trench resistive structures 51A. The boundary cathode region 111 may face some or all of the plurality of second trench resistive structures 51B.

When the boundary cathode region 111 is formed in the street region 11, the boundary cathode region 111 is formed in a band shape extending in the second direction Y in the street region 11. The boundary cathode region 111 faces the second boundary well region 40B of the boundary well region 40 in the thickness direction of the chip 2 in the street region 11.

The outer peripheral cathode region 112 is formed in the surface layer portion of the second main surface 4 to face the outer peripheral well region 41 in the thickness direction of the chip 2 in the outer peripheral region 9. In this embodiment, the outer peripheral cathode region 112 is formed in an annular shape (quadrangular annular shape in this embodiment) surrounding the plurality of active regions 6 in plan view.

The outer peripheral cathode region 112 is preferably formed at an interval from the base region 20 of each active region 6 toward the peripheral edge side of the chip 2 such as not to face the base region 20 of each active region 6 at least in the thickness direction. The outer peripheral cathode region 112 is preferably formed at an interval from the plurality of first trench structures 21 toward the peripheral edge side of the chip 2 such as not to face the plurality of first trench structures 21 in the thickness direction.

The outer peripheral cathode region 112 is preferably formed at an interval from the plurality of trench separation structures 15 toward the peripheral edge side of the chip 2 such as not to face the plurality of trench separation structures 15 in the thickness direction. That is, the outer peripheral cathode region 112 is preferably formed only in the outer peripheral region 9 and is not formed in the plurality of active regions 6. The outer peripheral cathode region 112 may be connected to the boundary cathode region 111 in the connection portion of the boundary region 8 and the outer peripheral region 9.

The collector electrode 107 described above is electrically connected to the collector region 14 and the cathode region 110. As described above, the semiconductor device 1C includes the IGBT structure Tr formed in each active region 6, a boundary diode D1 formed in the boundary region 8, and an outer diode D2 formed in the outer peripheral region 9. Each IGBT structure Tr includes the first trench structure 21 as a gate, the emitter region 29 as the emitter, and the collector region 14 as a collector.

The boundary diode D1 includes the boundary well region 40 as an anode and the boundary cathode region 111 as a cathode. An anode of the boundary diode D1 is electrically connected to an emitter of each IGBT structure Tr, and a cathode of the boundary diode D1 is electrically connected to a collector of each IGBT structure Tr. As a result, the boundary diode D1 functions as a first freewheeling diode according to each IGBT structure Tr.

The outer diode D2 includes the outer peripheral well region 41 as an anode and the outer peripheral cathode region 112 as a cathode. An anode of the outer diode D2 is electrically connected to an emitter of each IGBT structure Tr, and a cathode of the outer diode D2 is electrically connected to a collector of each IGBT structure Tr. Thus, the outer diode D2 is connected in parallel to the boundary diode D1 in the forward direction. Also, the outer diode D2 functions as a second freewheeling diode according to each IGBT structure Tr.

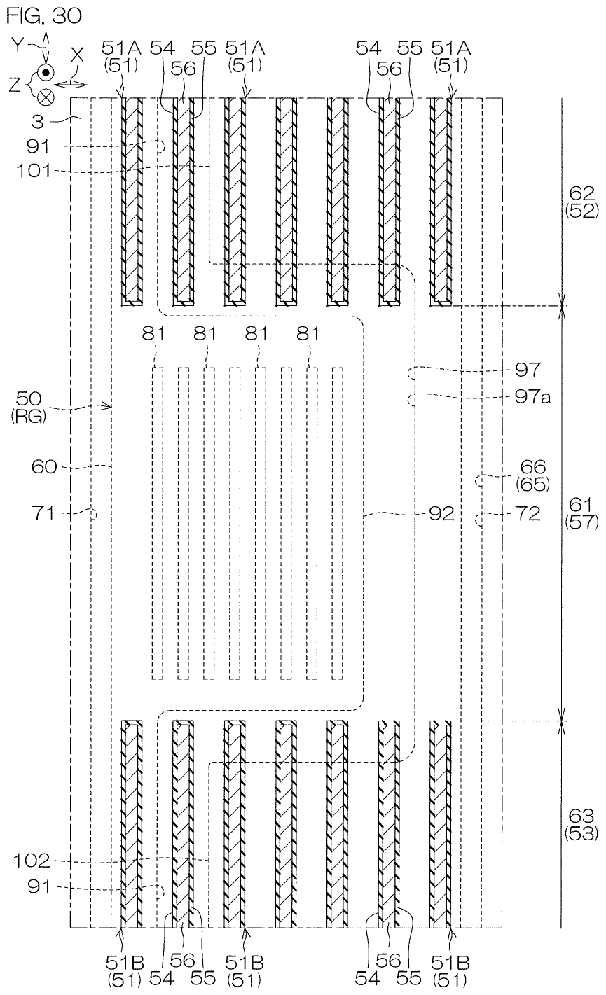

Hereinafter, modifications applicable to each of the above-described embodiments are described. The following modifications may be applied to each embodiment alone. Also, the following modifications may be applied to each embodiment after being appropriately combined. FIG. 30 is an enlarged plan view illustrating the first resistance connection electrode 81 according to a modification. Although FIG. 30 illustrates the plurality of first resistance connection electrodes 81, it suffices that at least one first resistance connection electrode 81 is formed.

With reference to FIG. 30, the plurality of first resistance connection electrodes 81 may be arranged at intervals in the first direction X in plan view and may be each formed in a band shape extending in the second direction Y. That is, the plurality of first resistance connection electrodes 81 may be arranged in a stripe shape extending in the second direction Y in plan view. The plurality of first resistance connection electrodes 81 may face the plurality of first trench resistive structures 51A in a one-to-one correspondence relationship in the second direction Y or may each face a region between the plurality of first trench resistive structures 51A in a one-to-one correspondence relationship in the second direction Y.

The second electrode portion 92 is led out from the first electrode portion 91 in the first direction X similarly to the above-described embodiment. In this embodiment, the projecting direction of the second electrode portion 92 is a direction intersecting the extending direction of the plurality of first resistance connection electrodes 81. In this embodiment, the second electrode portion 92 intersects (specifically, is orthogonal to) the plurality of first resistance connection electrodes 81 and is led out from the first electrode portion 91 in the first direction X such as to cover the plurality of first resistance connection electrodes 81.

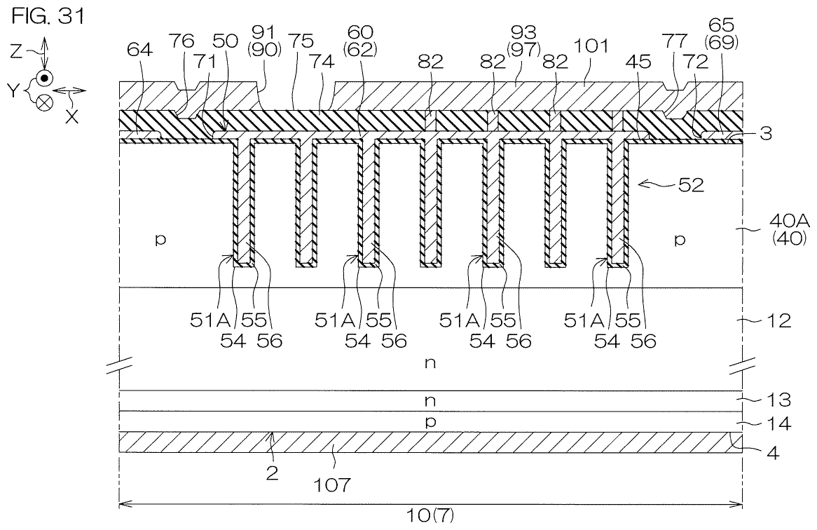

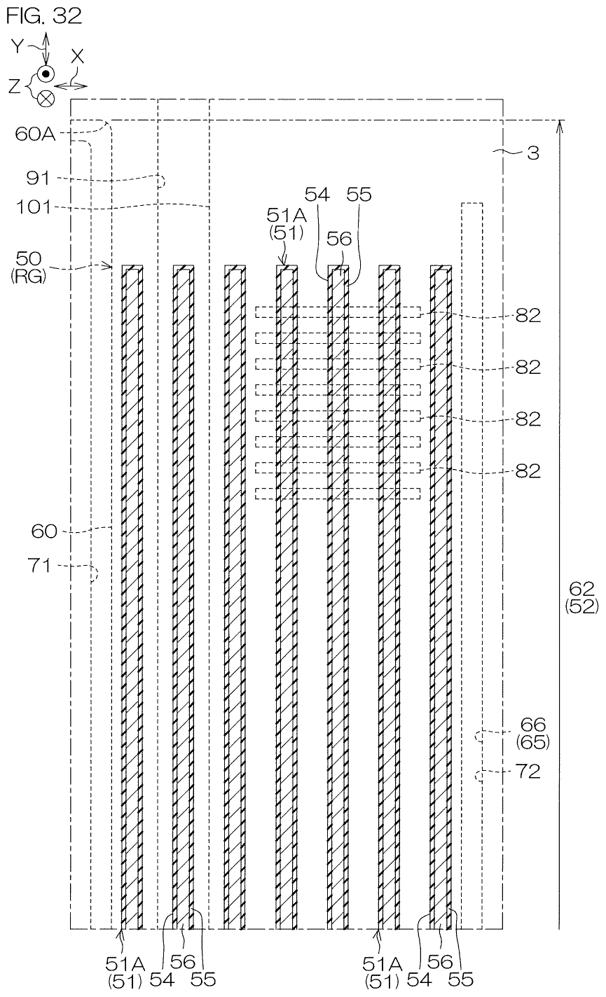

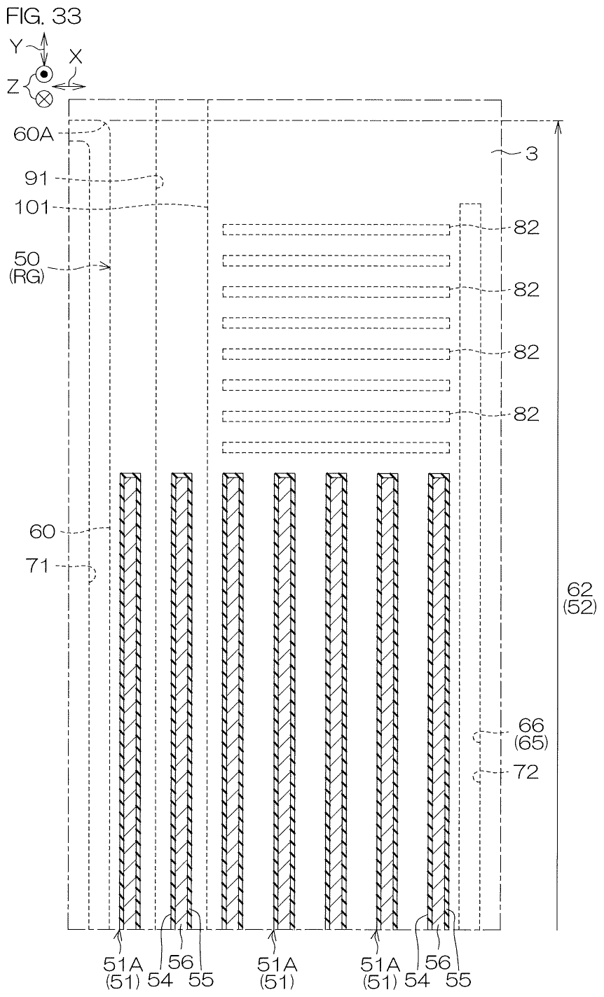

FIG. 31 is a cross-sectional view illustrating the second resistance connection electrode 82 according to a first modification. FIG. 32 is an enlarged plan view illustrating the second resistance connection electrode 82 according to a second modification. FIG. 33 is an enlarged plan view illustrating the second resistance connection electrode 82 according to a third modification. Although FIGS. 31 to 33 illustrate the plurality of second resistance connection electrodes 82, it suffices that at least one second resistance connection electrode 82 is formed.

With reference to FIG. 31, the plurality of second resistance connection electrodes 82 may be embedded in the interlayer insulating film 74 to face the plurality of first trench resistive structures 51A with the resistive film 60 interposed therebetween. With reference to FIG. 32, the plurality of second resistance connection electrodes 82 may be each formed in a band shape extending in the first direction X such as to intersect the plurality of first trench resistive structures 51A in plan view and may be arranged at intervals in the second direction Y. That is, the plurality of second resistance connection electrodes 82 may be arranged in a stripe shape extending in the first direction X in plan view.

The plurality of second resistance connection electrodes 82 suffice to intersect at least one of the plurality of first trench resistive structures 51A and do not have to intersect all of the first trench resistive structures 51A. In this embodiment, the plurality of second resistance connection electrodes 82 intersect some of the plurality of first trench resistive structures 51A. As a matter of course, the plurality of second resistance connection electrodes 82 may face all of the first trench resistive structures 51A in the second direction Y.

With reference to FIG. 33, the plurality of second resistance connection electrodes 82 may be connected to a region of the resistive film 60 between the first trench group 52 and the first end portion 60A of the resistive film 60 in plan view. In this embodiment, the plurality of second resistance connection electrodes 82 are arranged in a stripe shape extending in the first direction X in plan view.

The plurality of second resistance connection electrodes 82 may face at least one of the plurality of first trench resistive structures 51A in the second direction Y. The plurality of second resistance connection electrodes 82 preferably face at least two of the plurality of first trench resistive structures 51A in the second direction Y. As a matter of course, the plurality of second resistance connection electrodes 82 may face all of the first trench resistive structures 51A in the second direction Y.

As a matter of course, the plurality of second resistance connection electrodes 82 may be arranged in a stripe shape extending in the second direction Y in plan view. In this case, the plurality of second resistance connection electrodes 82 may face the plurality of first trench resistive structures 51A in a one-to-one correspondence relationship in the second direction Y or may each face a region between the plurality of first trench resistive structures 51A in a one-to-one correspondence relationship in the second direction Y.

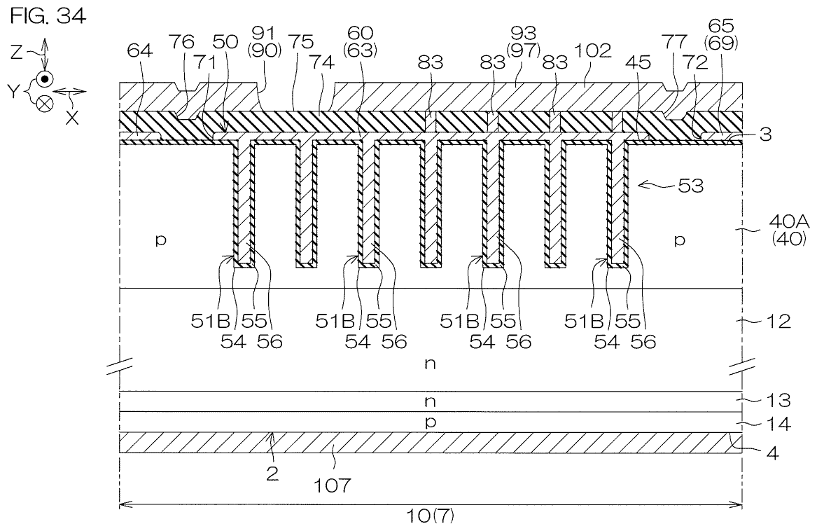

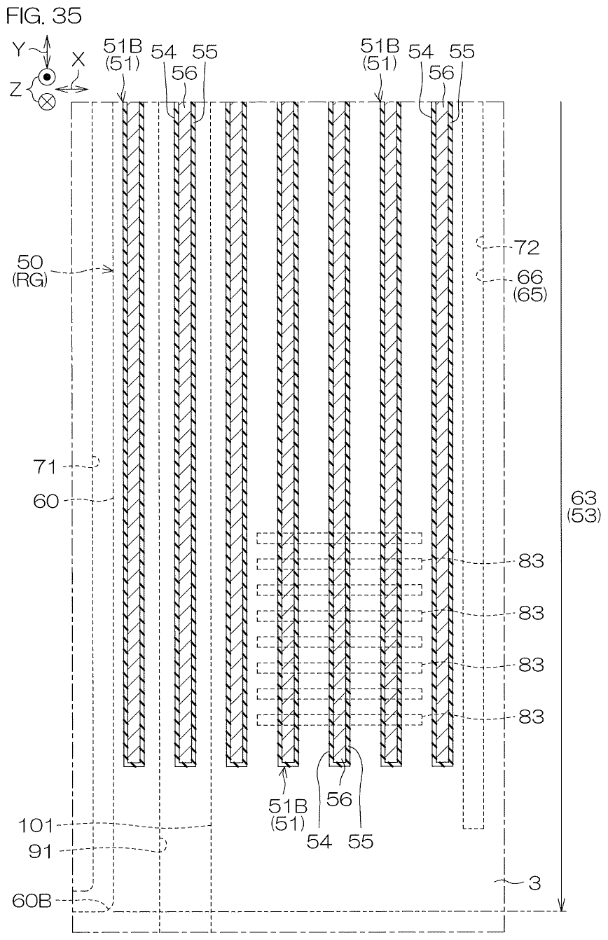

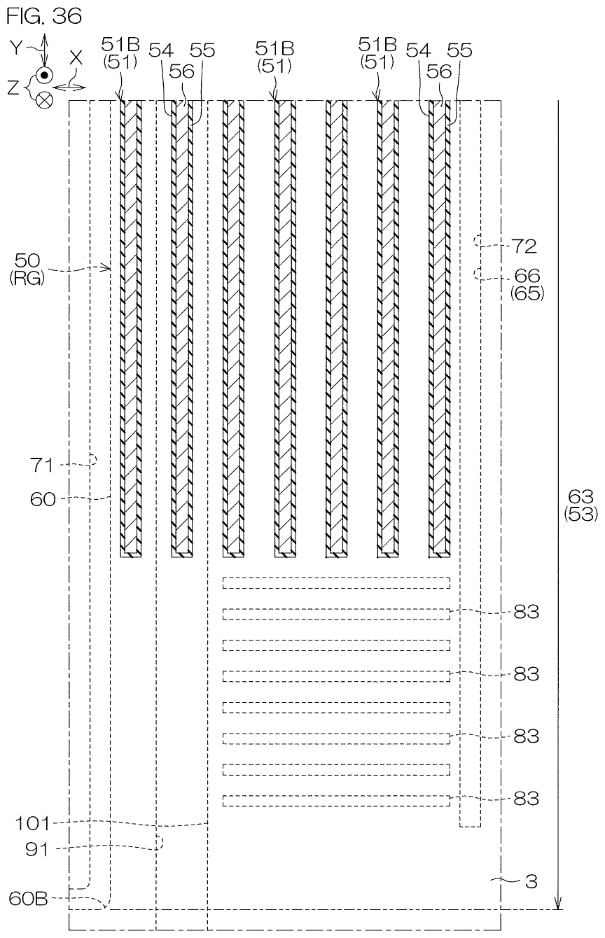

FIG. 34 is a cross-sectional view illustrating the third resistance connection electrode 83 according to the first modification. FIG. 35 is an enlarged plan view illustrating the third resistance connection electrode 83 according to the second modification. FIG. 36 is an enlarged plan view illustrating the third resistance connection electrode 83 according to the third modification. Although FIGS. 34 to 36 illustrate the plurality of third resistance connection electrodes 83, it suffices that at least one third resistance connection electrode 83 may be formed.

With reference to FIG. 34, the plurality of third resistance connection electrodes 83 may be embedded in the interlayer insulating film 74 to face the plurality of second trench resistive structures 51B with the resistive film 60 interposed therebetween. With reference to FIG. 35, the plurality of third resistance connection electrodes 83 may be each formed in a band shape extending in the first direction X such as to intersect the plurality of second trench resistive structures 51B in plan view and may be arranged at intervals in the second direction Y. That is, the plurality of third resistance connection electrodes 83 may be arranged in a stripe shape extending in the first direction X in plan view.

The plurality of third resistance connection electrodes 83 suffice to intersect at least one of the plurality of second trench resistive structures 51B and do not have to intersect all of the second trench resistive structure 51B. In this embodiment, the plurality of third resistance connection electrodes 83 intersect some of the plurality of second trench resistive structures 51B. As a matter of course, the plurality of third resistance connection electrodes 83 may face all of the second trench resistive structures 51B in the second direction Y.

With reference to FIG. 36, the plurality of third resistance connection electrodes 83 may be connected to a region of the resistive film 60 between the second trench group 53 and the second end portion 60B of the resistive film 60 in plan view. In this embodiment, the plurality of third resistance connection electrodes 83 are arranged in a stripe shape extending in the first direction X in plan view.

The plurality of third resistance connection electrodes 83 may face at least one of the plurality of second trench resistive structures 51B in the second direction Y. The plurality of third resistance connection electrodes 83 preferably face at least two of the plurality of second trench resistive structures 51B in the second direction Y. As a matter of course, the plurality of third resistance connection electrodes 83 may face all of the second trench resistive structures 51B in the second direction Y.

As a matter of course, the plurality of third resistance connection electrodes 83 may be arranged in a stripe shape extending in the second direction Y in plan view. In this case, the plurality of third resistance connection electrodes 83 may face the plurality of second trench resistive structures 51B in a one-to-one correspondence relationship in the second direction Y or may each face a region between the plurality of second trench resistive structures 51B in a one-to-one correspondence relationship in the second direction Y.

Any one of the third resistance connection electrodes 83 according to the first to third modifications may be applied to each of the embodiments described above simultaneously with any one of the second resistance connection electrodes 82 according to the first to third modifications.

From the viewpoint of layout symmetry, the third resistance connection electrode 83 according to the first modification is preferably applied simultaneously with the second resistance connection electrode 82 according to the first modification. Also, the third resistance connection electrode 83 according to the second modification is preferably applied simultaneously with the second resistance connection electrode 82 according to the second modification. Also, the third resistance connection electrode 83 according to the third modification is preferably applied simultaneously with the second resistance connection electrode 82 according to the third modification.

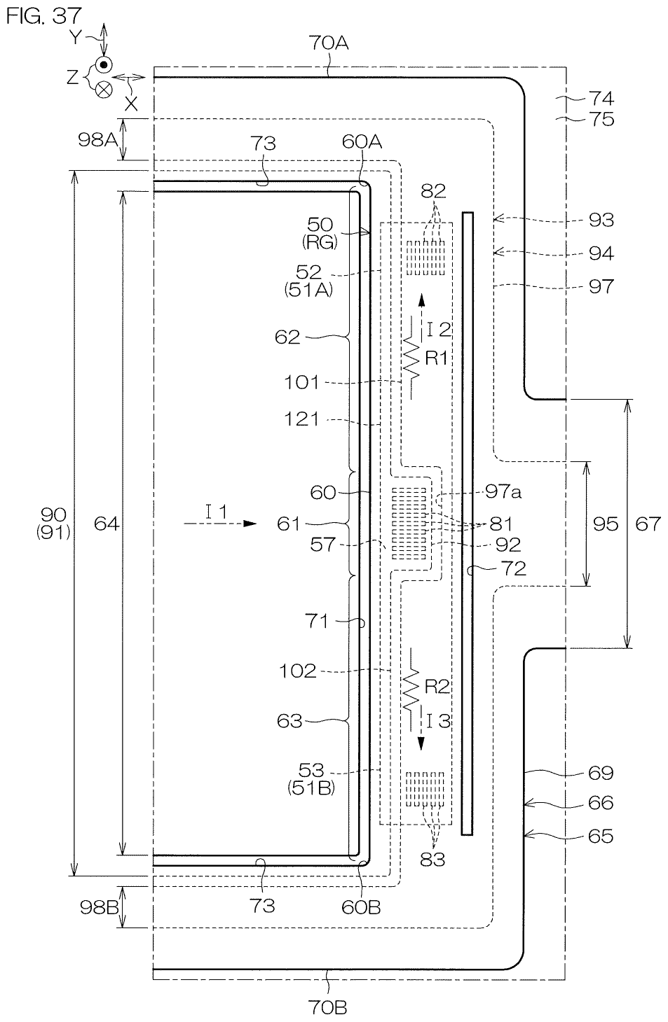

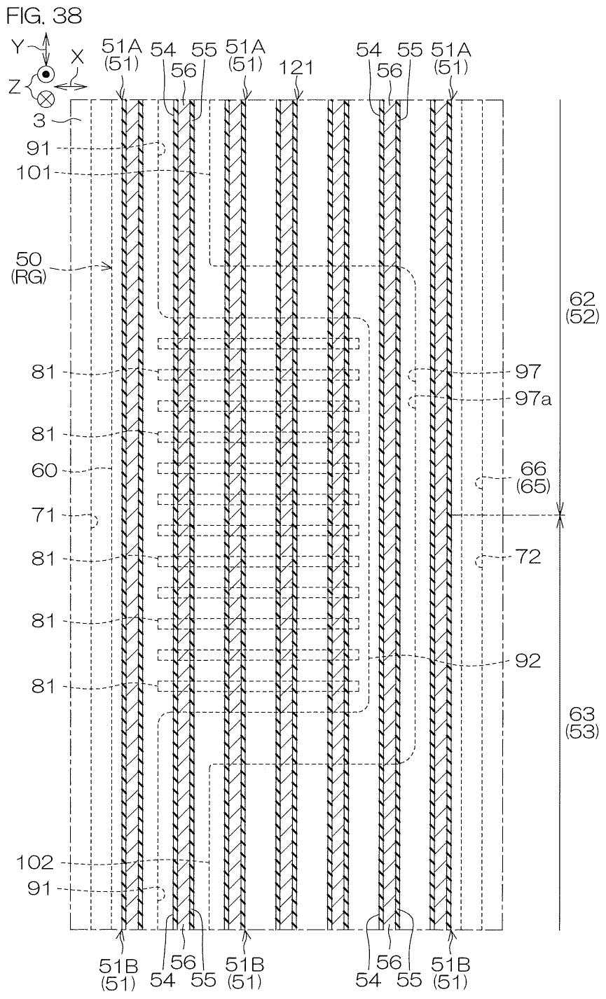

FIG. 37 is an enlarged plan view illustrating the gate resistive structure 50 according to the first modification. FIG. 38 is an enlarged plan view illustrating an inner portion of the gate resistive structure 50 illustrated in FIG. 37. In each of the embodiments described above, the gate resistive structure 50 includes the first trench group 52 (the plurality of first trench resistive structures 51A) and the second trench group 53 (the plurality of second trench resistive structures 51B). Meanwhile, the gate resistive structure 50 according to the modification includes a single trench group 121 in which the first trench group 52 and the second trench group 53 are integrated, and does not have the space region 57.

The single trench group 121 includes the plurality of trench resistive structures 51. The plurality of trench resistive structures 51 are arranged at intervals in the first direction X and each formed in a band shape extending in the second direction Y. That is, the plurality of trench resistive structures 51 are arranged in a stripe shape extending in the second direction Y. The plurality of trench resistive structures 51 have one end portion on one side (the first side surface 5A side) in the second direction Y and the other end portion on the other side (the second side surface 5B side) in the second direction Y.

One end portions of the plurality of trench resistive structures 51 face the first active region 6A, and the other end portions of the plurality of trench resistive structures 51 face the second active region 6B. A region on one side (the first side surface 5A side) in the second direction Y with respect to the intermediate portion of the single trench group 121 may be regarded as the first trench group 52, and a region on the other side (the second side surface 5B side) in the second direction Y with respect to the intermediate portion of the single trench group 121 may be regarded as the second trench group 53.

In this embodiment, the resistive film 60 collectively covers the single trench group 121 (the plurality of trench resistive structures 51). The resistive film 60 has the first end portion 60A on one end portion side of the plurality of trench resistive structures 51 and the second end portion 60B on the other end portion side of the plurality of trench resistive structures 51.

In this embodiment, the plurality of first resistance connection electrodes 81 are connected to the inner portion (the intermediate portion) of the resistive film 60 in plan view. In this embodiment, the plurality of first resistance connection electrodes 81 are each formed in a band shape extending in the first direction X and are arranged at intervals in the second direction Y. That is, the plurality of first resistance connection electrodes 81 are arranged in a stripe shape extending in the first direction X.

The plurality of first resistance connection electrodes 81 intersect the plurality of trench resistive structures 51. The plurality of first resistance connection electrodes 81 suffice to intersect at least one of the plurality of trench resistive structures 51 and do not have to intersect all of the trench resistive structures 51. In this embodiment, the plurality of first resistance connection electrodes 81 intersect some of the plurality of trench resistive structures 51. As a matter of course, the plurality of first resistance connection electrodes 81 may face all of the trench resistive structures 51 in the second direction Y.

The plurality of second resistance connection electrodes 82 are connected to the resistive film 60 in a region of the resistive film 60 on the first end portion 60A side (a region on one end portion side of the plurality of trench resistive structures 51) with respect to the plurality of first resistance connection electrodes 81 in plan view. The plurality of second resistance connection electrodes 82 are formed in a layout similar to that in the first embodiment. As a matter of course, any one of the second resistance connection electrodes 82 according to the first to third modifications may be applied.

The plurality of third resistance connection electrodes 83 are connected to the resistive film 60 in a region of the resistive film 60 on the second end portion 60B side (a region of the plurality of trench resistive structures 51 on the other end portion side) with respect to the plurality of first resistance connection electrodes 81 in plan view. The plurality of third resistance connection electrodes 83 are formed in a layout similar to that in the first embodiment. As a matter of course, any one of the third resistance connection electrodes 83 according to the first to third modifications may be applied.

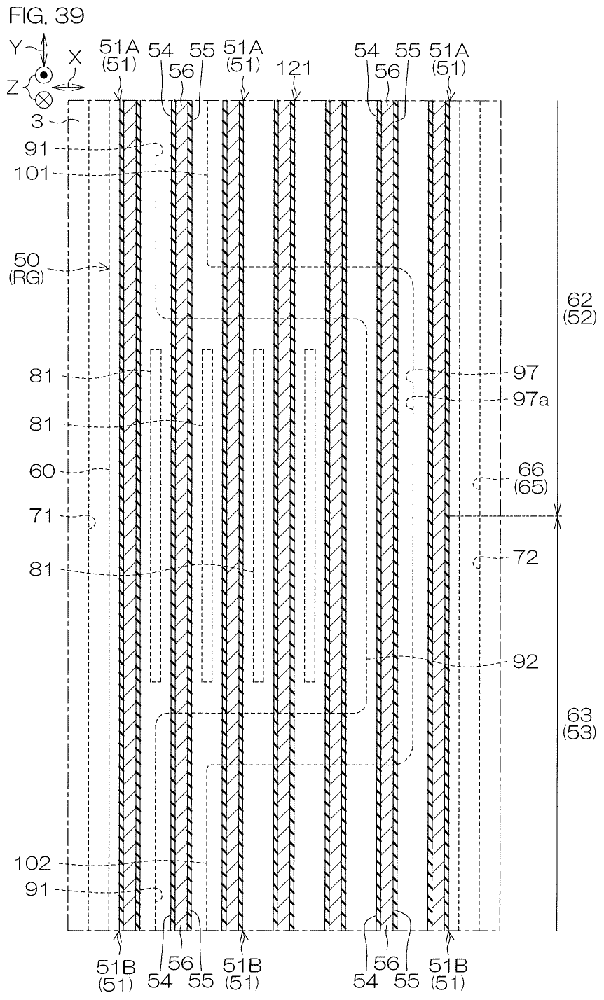

FIG. 39 is an enlarged plan view illustrating an inner portion of the gate resistive structure 50 according to the second modification. In the gate resistive structure 50 according to the first modification, the plurality of first resistance connection electrodes 81 intersect the plurality of trench resistive structures 51. Meanwhile, the gate resistive structure 50 according to the second modification includes the plurality of first resistance connection electrodes 81 that do not intersect with the plurality of trench resistive structures 51. With reference to FIG. 39, the plurality of first resistance connection electrodes 81 are formed in a region facing the plurality of trench resistive structures 51 in the first direction X in plan view. In this embodiment, the plurality of first resistance connection electrodes 81 are each formed in a band shape extending in the second direction Y in plan view, and are arranged at intervals in the first direction X. That is, the plurality of first resistance connection electrodes 81 are arranged in a stripe shape extending in the second direction Y in plan view.

The plurality of first resistance connection electrodes 81 are arranged in regions between the plurality of trench resistive structures 51 adjacent to each other at intervals from the plurality of trench resistive structures 51 in plan view. That is, the plurality of first resistance connection electrodes 81 are alternately arranged with the plurality of trench resistive structures 51 in the first direction X.

Also, in this embodiment, the plurality of first resistance connection electrodes 81 face only the flat portion of the first main surface 3 with the resistive film 60 interposed therebetween, and do not face the trench resistive structure 51 with the resistive film 60 interposed therebetween. The plurality of first resistance connection electrodes 81 face the boundary well region 40 with the resistive film 60 and the main surface insulating film 45 interposed therebetween.

The plurality of first resistance connection electrodes 81 suffice to be arranged in some of the regions between the plurality of trench resistive structures 51 and is not necessarily arranged in all of the regions between the plurality of trench resistive structures 51. For example, the plurality of first resistance connection electrodes 81 suffice to be arranged in at least one region positioned on the gate electrode film 64 side among the regions between the plurality of first trench resistive structures 51A and do not have to be arranged in at least one region positioned on the active region 6 side among the regions between the plurality of first trench resistive structures 51A.

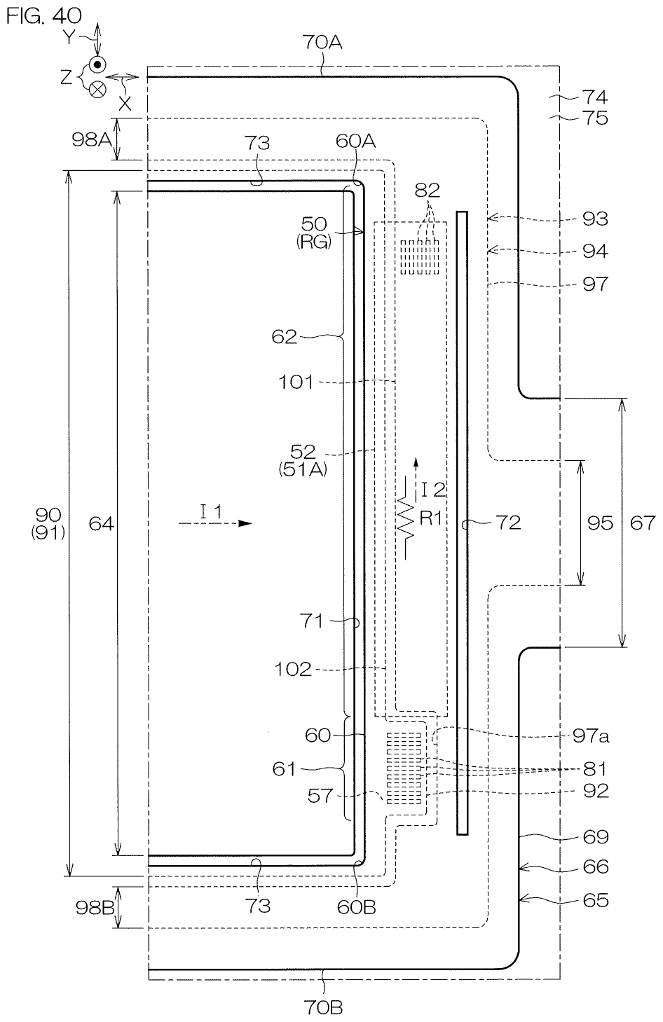

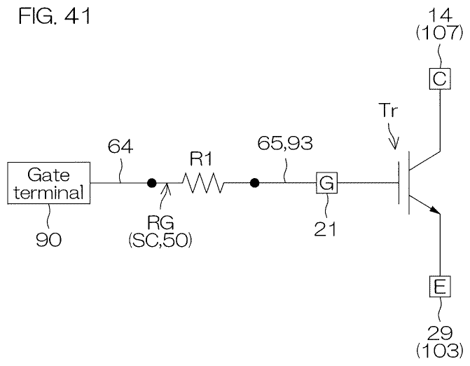

FIG. 40 is an enlarged plan view illustrating the gate resistive structure 50 according to the third modification. FIG. 41 is an electric circuit diagram illustrating the gate terminal electrode 90, the gate wiring electrode 93, and the gate resistive structure 50. With reference to FIGS. 40 and 41, the gate resistive structure 50 includes the first trench group 52 and does not include the second trench group 53 in this embodiment.

In this embodiment, the space region 57 is provided on the other side (the second side surface 5B side) in the second direction Y with respect to the first trench group 52. That is, in this embodiment, the first covering portion 61 of the resistive film 60 is provided in the region of the resistive film 60 on the second end portion 60B side, and the second covering portion 62 of the resistive film 60 is provided in the region of the resistive film 60 on the first end portion 60A side.

The plurality of first resistance connection electrodes 81 are formed in a layout similar to that in the first embodiment. As a matter of course, the first resistance connection electrode 81 according to the modification may be applied. The plurality of second resistance connection electrodes 82 are formed in a layout similar to that in the first embodiment. As a matter of course, any one of the second resistance connection electrodes 82 according to the first to third modifications may be applied. In this embodiment, the plurality of third resistance connection electrodes 83 are not formed.

The second current 12 flowing through the second resistance connection electrode 82 is substantially equal to the first current I1 flowing through the first resistance connection electrode 81. That is, the current ratio I2/I1 (shunt ratio) is substantially 1. In this case, the area ratio S2/S1 of the second connection area S2 of the plurality of second resistance connection electrodes 82 with respect to the first connection area S1 of the plurality of first resistance connection electrodes 81 may be one or more. The area ratio S2/S1 is preferably 2 or less.

In this embodiment, the gate wiring electrode 93 includes the first connection region 101 in the first upper line portion 97 and does not include the second connection region 102. The first connection region 101 is electrically connected to the plurality of first resistance connection electrodes 81 as in each of the embodiments described above. As a result, the first connection region 101 is electrically connected to the second covering portion 62 of the resistive film 60 and the first trench group 52 (the plurality of first trench resistive structures 51A) via the plurality of first resistance connection electrodes 81.

As described above, the first upper line portion 97 (gate wiring electrode 93) configures a series resistance circuit SC including the first gate resistor R1 between the first upper line portion 97 (gate wiring electrode 93) and the second electrode portion 92 (gate terminal electrode 90) (see also FIG. 41).

In this embodiment, the gate resistive structure 50 that includes the first trench group 52 and does not include the second trench group 53 is described. However, the gate resistive structure 50 that includes the second trench group 53 and does not include the first trench group 52 may be adopted. A specific configuration in this case is obtained by replacing the configuration on the first trench group 52 side with the configuration on the second trench group 53 side in the above description and the accompanying drawings.

In this embodiment, the gate resistive structure 50 including the space region 57 is described. However, as in the gate resistive structure 50 according to the first and second modifications, the gate resistive structure 50 without the space region 57 may be adopted (see FIGS. 37 to 39).

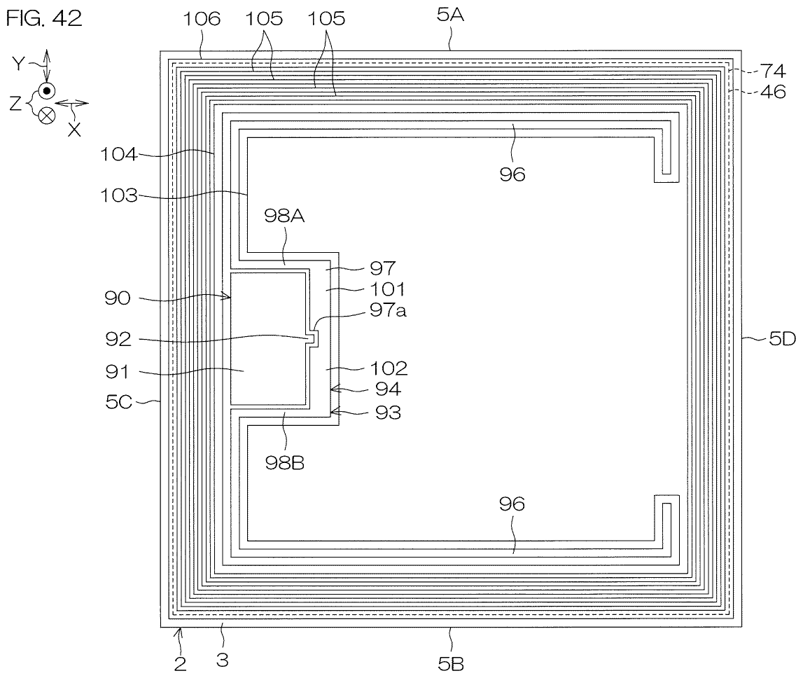

FIG. 42 is a plan view illustrating the gate wiring electrode 93 according to the modification and the emitter terminal electrode 103 according to the modification. With reference to FIG. 42, the gate wiring electrode 93 without the second upper wiring portion 95 may be adopted. In this case, the single emitter terminal electrode 103 may be arranged on the interlayer insulating film 74. In this case, the plurality of active regions 6 may be provided in the first main surface 3, or the single active region 6 may be provided in the first main surface 3.

When the plurality of active regions 6 are provided in the first main surface 3, the single emitter terminal electrode 103 covers the plurality of active regions 6 across the boundary region 8 in plan view. When the single active region 6 is provided in the first main surface 3, the single emitter terminal electrode 103 covers the single active region 6 in plan view.

When a single active region 6 is provided, the street region 11 is omitted. The single active region 6 is demarcated by a single trench separation structure 15. The planar shape of the single active region 6 is different from the planar shape of the first active region 6A (second active region 6B), however, the internal configuration of the single active region 6 is similar to the internal configuration of the first active region 6A (second active region 6B). The description of the internal configuration of the first active region 6A (second active region 6B) may be applied to the description of the internal configuration of the single active region 6.

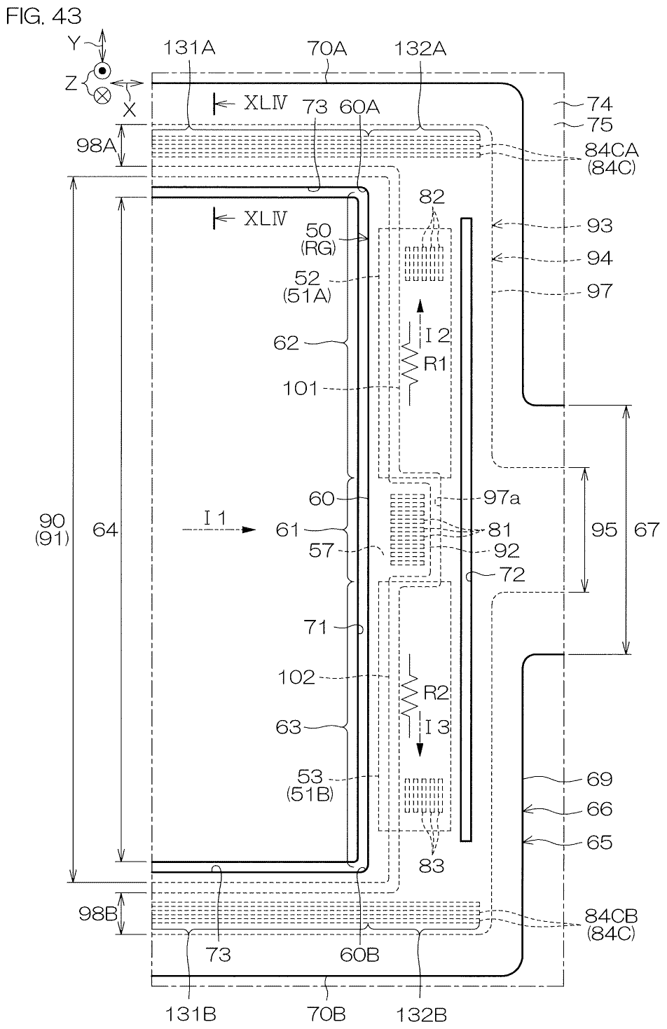

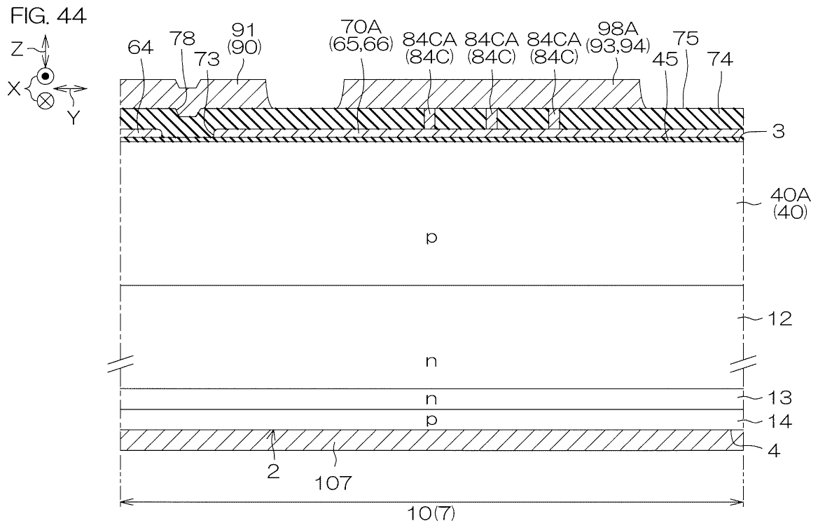

FIG. 43 is an enlarged plan view illustrating the gate connection electrode 84 according to the modification. FIG. 44 is a cross-sectional view taken along line XLIV-XLIV illustrated in FIG. 43. In this embodiment, with reference to FIGS. 43 and 44, the plurality of gate connection electrodes 84 include at least one third gate connection electrode 84C (in this embodiment, a plurality of third gate connection electrodes 84C) in addition to the first gate connection electrode 84A and the second gate connection electrode 84B.

The plurality of third gate connection electrodes 84C include at least one third gate connection electrode 84CA (in this embodiment, a plurality of third gate connection electrodes 84CA) on the second lower line portion 70A side and at least one third gate connection electrode 84CB (in this embodiment, a plurality of third gate connection electrodes 84CB) on the second lower line portion 70B side.

The plurality of third gate connection electrodes 84CA on one side are embedded in a portion of the interlayer insulating film 74 covering the second lower line portion 70A in the pad region 10 and are electrically connected to the second lower line portion 70A. In this embodiment, the plurality of third gate connection electrodes 84CA are formed at intervals in the second direction Y and formed in a band shape extending in the first direction X.

Each of the plurality of third gate connection electrodes 84CA has a gate facing portion 131A facing the gate electrode film 64 in the second direction Y with the third slit 73 interposed therebetween. In this embodiment, each of the plurality of third gate connection electrodes 84CA has a resistance facing portion 132A led out from the gate facing portion 131A to the first lower line portion 69 side (the resistive film 60 side) to face the resistive film 60 in the second direction Y.

That is, the resistance facing portion 132A faces the first slit 71 in the second direction Y. In this embodiment, the resistance facing portion 132A is formed to be wider than the width of the resistive film 60 in the first direction X and has a portion positioned on the first lower line portion 69. That is, the resistance facing portion 132A faces the second slit 72 in the second direction Y. As a result, the resistance facing portion 132A faces the entire region of the resistive film 60 in the width direction of the first direction X with respect to the second direction Y.

As a matter of course, the resistance facing portion 132A may be formed to be deviated from the first lower line portion 69 to the second lower line portion 70A side such as not to cover the first lower line portion 69 and may face a part or an entirety of the resistive film 60 in the second direction Y. In this case, the resistance facing portion 132A may face the second slit 72 in the second direction Y and may not face the second slit 72 in the second direction Y.

As a matter of course, the plurality of third gate connection electrodes 84CA may include only the gate facing portion 131A without including the resistance facing portion 132A. In this case, the gate facing portion 131A may face the first slit 71 in the second direction Y and may not face the first slit 71 in the second direction Y.

The plurality of third gate connection electrodes 84CB on the other side are embedded in a portion of the interlayer insulating film 74 covering the second lower line portion 70B in the pad region 10 and are electrically connected to the second lower line portion 70B. In this embodiment, the plurality of third gate connection electrodes 84CB are formed at intervals in the second direction Y and formed in a band shape extending in the first direction X.

Each of the plurality of third gate connection electrodes 84CB has a gate facing portion 131B facing the gate electrode film 64 in the second direction Y with the third slit 73 interposed therebetween. That is, the gate facing portion 131B faces the gate facing portion 131A in the second direction Y with the gate electrode film 64 interposed therebetween.

In this embodiment, each of the plurality of third gate connection electrodes 84CB has a resistance facing portion 132B led out from the gate facing portion 131B to the first lower line portion 69 side (resistive film 60 side) to face the resistive film 60 in the second direction Y. That is, the resistance facing portion 132B faces the first slit 71 in the second direction Y. Also, the resistance facing portion 132B faces the resistance facing portion 132A in the second direction Y with the resistive film 60 and the first slit 71 interposed therebetween.

In this embodiment, the resistance facing portion 132B is formed to be wider than the width of the resistive film 60 in the first direction X and has a portion positioned on the first lower line portion 69. That is, the resistance facing portion 132B faces the second slit 72 in the second direction Y. As a result, the resistance facing portion 132B faces the entire region of the resistive film 60 in the width direction of the first direction X with respect to the second direction Y.

As a matter of course, the resistance facing portion 132B may be formed to be deviated from the first lower line portion 69 to the second lower line portion 70B side such as not to cover the first lower line portion 69 and may face a part or an entirety of the resistive film 60 in the second direction Y. In this case, the resistance facing portion 132B may face the second slit 72 in the second direction Y and may not face the second slit 72 in the second direction Y.

As a matter of course, the plurality of third gate connection electrodes 84CB may include only the gate facing portion 131B without including the resistance facing portion 132B. In this case, the gate facing portion 131B may face the first slit 71 in the second direction Y and may not face the first slit 71 in the second direction Y.

The second upper line portion 98A covers the plurality of third gate connection electrodes 84CA and is electrically connected to the second lower line portion 70A via the plurality of third gate connection electrodes 84CA. The second upper line portion 98B covers the plurality of third gate connection electrodes 84CB and is electrically connected to the second lower line portion 70B via the plurality of third gate connection electrodes 84CB.

Each of the embodiments and modifications described above can be implemented in still other embodiments. For example, in each of the embodiments described above, an example in which the chip 2 is constituted of a silicon single crystal substrate is described. However, the chip 2 may be constituted of a silicon carbide (SiC) single crystal substrate.

In each of the embodiments described above, the n-type semiconductor region may be replaced with a p-type semiconductor region, and the p-type semiconductor region may be replaced with an n-type semiconductor region. A specific configuration in this case can be obtained by replacing the “n-type” with the “p-type” at the same time as replacing the “p-type” with the “n-type” in the above descriptions and accompanying drawings.

In the above embodiments, the p-type collector region 14 is described. However, an n-type drain region may be adopted instead of the p-type collector region 14. In this case, the buffer region 13 is omitted. The n-type drain region may be formed by an n-type semiconductor substrate, and the n-type drift region 12 may be formed by an n-type epitaxial layer. The n-type impurity concentration of the drift region 12 is preferably less than the n-type impurity concentration of the drain region.

In this case, a MISFET (metal insulator semiconductor field effect transistor) structure is formed instead of the IGBT. The specific configuration in this case can be obtained by replacing “emitter” with “source” and “collector” with “drain” in the above description.

In each of the embodiments described above, the first direction X and the second direction Y are defined by the extending directions of the first to fourth side surfaces 5A to 5D. However, the first direction X and the second direction Y may be arbitrary directions as long as the directions maintain an intersecting (specifically, orthogonal) relationship with each other. For example, the first direction X may be an extending direction of the third side surface 5C (fourth side surface 5D), and the second direction Y may be an extending direction of the first side surface 5A (second side surface 5B). Also, the first direction X may be a direction intersecting the first to fourth side surfaces 5A to 5D, and the second direction Y may be a direction intersecting the first to fourth side surfaces 5A to 5D.

Hereinafter, examples of features extracted from the present Description and the attached drawings shall be indicated below. Hereinafter, the alphanumeric characters, etc., in parentheses represent the corresponding components, etc., in the embodiments described above, but are not intended to limit the scope of each clause to the embodiments. The “semiconductor device” according to the following clauses may be replaced with a “semiconductor switching device,” an “IGBT semiconductor device,” an “RC-IGBT semiconductor device,” or a “MISFET semiconductor device.”
[A1] A semiconductor device (1A, 1B, 1C) comprising: a chip (2) that has a main surface (3); a trench resistive structure (51, 51A, 51B) that is formed in the main surface (3); a resistive film (60) that is electrically connected to the trench resistive structure (51, 51A, 51B) on the main surface (3); a gate terminal electrode (90) that has a lower resistance than that of the resistive film (60) and that is electrically connected to the trench resistive structure (51, 51A, 51B) via the resistive film (60) on the main surface (3); and a gate wiring electrode (93) that has a lower resistance than that of the resistive film (60) and that is electrically connected to the gate terminal electrode (90) via the resistive film (60) and the trench resistive structure (51, 51A, 51B) on the main surface (3).
[A2] The semiconductor device (1A, 1B, 1C) according to A1, further comprising: a gate electrode film (64) that is arranged on the main surface (3) adjacent to the resistive film (60); and a gate wiring film (65) that is arranged on the main surface (3) adjacent to the resistive film (60) such as to face the gate electrode film (64) with the resistive film (60) interposed between the gate electrode film and the gate wiring film; wherein the gate terminal electrode (90) covers the gate electrode film (64), and the gate wiring electrode (93) covers the gate wiring film (65).
[A3] The semiconductor device (1A, 1B, 1C) according to A2, wherein the resistive film (60) has a first end portion (60A) on one side and a second end portion (60B) on the other side, and the gate wiring film (65) has a first connection portion (70A) that is connected to the first end portion (60A) of the resistive film (60) and a second connection portion (70B) that is connected to the second end portion (60B) of the resistive film (60).
[A4] The semiconductor device (1A, 1B, 1C) according to A2 or A3, further comprising: a first slit (71) that is demarcated between the resistive film (60) and the gate electrode film (64); and a second slit (72) that is demarcated between the resistive film (60) and the gate wiring film (65).
[A5] The semiconductor device (1A, 1B, 1C) according to A4, wherein the gate terminal electrode (90) covers the resistive film (60) and the gate electrode film (64) across the first slit (71) in plan view.
[A6] The semiconductor device (1A, 1B, 1C) according to A4 or A5, wherein the gate wiring film (65) covers the resistive film (60) and the gate electrode film (64) across the second slit (72) in plan view.
[A7] The semiconductor device (1A, 1B, 1C) according to any one of A4 to A6, wherein the first slit (71) is formed to be narrower than the resistive film (60), and the second slit (72) is formed to be narrower than the resistive film (60).
[A8] The semiconductor device (1A, 1B, 1C) according to any one of A4 to A7, wherein the trench resistive structure (51, 51A, 51B) extends in a band shape in one direction (Y) in plan view, the resistive film (60) extends in a band shape in the one direction (Y) in plan view, the first slit (71) extends in a band shape in the one direction (Y) in plan view, and the second slit (72) extends in a band shape in the one direction (Y) in plan view.
[A9] The semiconductor device (1A, 1B, 1C) according to A8, wherein the first slit (71) has a first length in the one direction (Y), and the second slit (72) has a second length smaller than the first length in the one direction (Y).
[A10] The semiconductor device (1A, 1B, 1C) according to any one of A3 to A9, further comprising: a third slit (73) that is demarcated between the gate electrode film (64) and the gate wiring film (65).
[A11] The semiconductor device (1A, 1B, 1C) according to A10, wherein the gate terminal electrode (90) covers the gate electrode film (64) and the gate wiring film (65) across the third slit (73) in plan view.
[A12] The semiconductor device (1A, 1B, 1C) according to any one of A1 to A11, wherein the trench resistive structures (51, 51A, 51B) are formed in the main surface (3) at intervals, and the resistive film (60) covers the trench resistive structures (51, 51A, 51B).
[A13] The semiconductor device (1A, 1B, 1C) according to any one of A1 to A12, wherein the resistive film (60) includes a first covering portion (61) that covers the main surface (3) outside the trench resistive structure (51, 51A, 51B) and a second covering portion (62, 63) that covers the trench resistive structure (51, 51A, 51B), the gate terminal electrode (90) is electrically connected to the resistive film (60) at a portion that covers the first covering portion (61), and the gate wiring electrode (93) is electrically connected to the resistive film (60) at a portion that covers the second covering portion (62, 63).
[A14] The semiconductor device (1A, 1B, 1C) according to any one of A1 to A13, further comprising: an interlayer insulating film (74) that covers the resistive film (60); a first connection electrode (81) that is embedded in the interlayer insulating film (74) such as to be electrically connected to the resistive film (60); and a second connection electrode (82, 83) that is embedded in the interlayer insulating film (74) such as to be electrically connected to the resistive film (60) at a different position from the first connection electrode (81); wherein the gate terminal electrode (90) is arranged on the interlayer insulating film (74) such as to be electrically connected to the resistive film (60) via the first connection electrode (81), and the gate wiring electrode (93) is arranged on the interlayer insulating film (74) such as to be electrically connected to the resistive film (60) via the second connection electrode (82, 83).
[A15] The semiconductor device (1A, 1B, 1C) according to A14, wherein the second connection electrode (82, 83) extends in a different direction from the first connection electrode (81).
[A16] The semiconductor device (1A, 1B, 1C) according to A14 or A15, wherein the first connection electrodes (81) are embedded in the interlayer insulating film (74), and the second connection electrodes (82, 83) are embedded in the interlayer insulating film (74).
[A17] The semiconductor device (1A, 1B, 1C) according to any one of A14 to A16, wherein a connection area of the second connection electrode (82, 83) with respect to the resistive film (60) is different from a connection area of the first connection electrode (81) with respect to the resistive film (60).
[A18] The semiconductor device (1A, 1B, 1C) according to any one of A14 to A17, wherein the gate terminal electrode (90) includes a first electrode portion (91) that is positioned outside the first connection electrode (81) in plan view, and a second electrode portion (92) that protrudes from the first electrode portion (91) to the first connection electrode (81) to be narrower than the first electrode portion (91).
[A19] The semiconductor device (1A, 1B, 1C) according to any one of A1 to A18, further comprising: a p-type well region (40) that is formed in a surface layer portion of the main surface (3); wherein the trench resistive structure (51, 51A, 51B) is formed at an interval from a bottom portion of the well region (40) toward the main surface (3) side such as to be positioned in the well region (40).
[A20] The semiconductor device (1A, 1B, 1C) according to any one of A1 to A19, further comprising: an active region (6, 6A, 6B) that is provided in the main surface (3); a non-active region (7) that is provided outside an active region (6, 6A, 6B) in the main surface (3); and a trench structure (15, 21) that is formed in the active region (6, 6A, 6B); wherein the trench resistive structure (51, 51A, 51B) is formed in the non-active region (7), the resistive film (60) covers the trench resistive structure (51, 51A, 51B) in the non-active region (7), the gate terminal electrode (90) is electrically connected to the resistive film (60) in the non-active region (7), and the gate wiring electrode (93) is electrically connected to the trench structure (15, 21) in the active region (6, 6A, 6B) and is electrically connected to the resistive film (60) in the non-active region (7).
[B1] A semiconductor device (1A, 1B, 1C) comprising: a chip (2) that has a main surface (3); a trench resistive structure (51, 51A, 51B) that is formed in the main surface (3); a gate terminal electrode (90) that has a lower resistance than that of the trench resistive structure (51, 51A, 51B) and is electrically connected to the trench resistive structure (51, 51A, 51B) on the main surface (3); and a gate wiring electrode (93) that has a lower resistance than that of the trench resistive structure (51, 51A, 51B) and is electrically connected to the gate terminal electrode (90) via the trench resistive structure (51, 51A, 51B) on the main surface (3).
[C1] A semiconductor device (1A, 1B, 1C) comprising: a chip (2) that has a main surface (3); a resistive film (60) that is formed on the main surface (3); a gate terminal electrode (90) that has a lower resistance than that of the resistive film (60) and is electrically connected to the resistive film (60) on the main surface (3); and a gate wiring electrode (93) that has a lower resistance than that of the resistive film (60) and is electrically connected to the gate terminal electrode (90) via the resistive film (60) on the main surface (3).

While embodiments of the present invention have been described in detail above, there are merely specific examples used to clarify the technical contents. The various technical ideas extracted from this Description are not limited by the order of description, the order of embodiments, and the like in the Description and can be combined as appropriate with each other.

What is claimed is:

1. A semiconductor device comprising:
a chip that has a main surface;
a trench resistive structure that is formed in the main surface;
a resistive film that is electrically connected to the trench resistive structure on the main surface;
a gate terminal electrode that has a lower resistance than that of the resistive film and that is electrically connected to the trench resistive structure via the resistive film on the main surface; and
a gate wiring electrode that has a lower resistance than that of the resistive film and that is electrically connected to the gate terminal electrode via the resistive film and the trench resistive structure on the main surface.

2. The semiconductor device according to claim 1, further comprising:
a gate electrode film that is arranged on the main surface adjacent to the resistive film; and
a gate wiring film that is arranged on the main surface adjacent to the resistive film such as to face the gate electrode film with the resistive film interposed between the gate electrode film and the gate wiring film;
wherein the gate terminal electrode covers the gate electrode film, and
the gate wiring electrode covers the gate wiring film.

3. The semiconductor device according to claim 2,
wherein the resistive film has a first end portion on one side and a second end portion on the other side, and
the gate wiring film has a first connection portion that is connected to the first end portion of the resistive film and a second connection portion that is connected to the second end portion of the resistive film.

4. The semiconductor device according to claim 2, further comprising:
a first slit that is demarcated between the resistive film and the gate electrode film; and
a second slit that is demarcated between the resistive film and the gate wiring film.

5. The semiconductor device according to claim 4,
wherein the gate terminal electrode covers the resistive film and the gate electrode film across the first slit in plan view.

6. The semiconductor device according to claim 4,
wherein the gate wiring film covers the resistive film and the gate electrode film across the second slit in plan view.

7. The semiconductor device according to claim 4,
wherein the first slit is formed to be narrower than the resistive film, and
the second slit is formed to be narrower than the resistive film.

8. The semiconductor device according to claim 4,
wherein the trench resistive structure extends in a band shape in one direction in plan view,
the resistive film extends in a band shape in the one direction in plan view,
the first slit extends in a band shape in the one direction in plan view, and
the second slit extends in a band shape in the one direction in plan view.

9. The semiconductor device according to claim 8,
wherein the first slit has a first length in the one direction, and
the second slit has a second length smaller than the first length in the one direction.

10. The semiconductor device according to claim 3, further comprising:
a third slit that is demarcated between the gate electrode film and the gate wiring film.

11. The semiconductor device according to claim 10,
wherein the gate terminal electrode covers the gate electrode film and the gate wiring film across the third slit in plan view.

12. The semiconductor device according to claim 1,
wherein the trench resistive structures are formed in the main surface at intervals, and
the resistive film covers the trench resistive structures.

13. The semiconductor device according to claim 1,
wherein the resistive film includes a first covering portion that covers the main surface outside the trench resistive structure and a second covering portion that covers the trench resistive structure,
the gate terminal electrode is electrically connected to the resistive film at a portion that covers the first covering portion, and
the gate wiring electrode is electrically connected to the resistive film at a portion that covers the second covering portion.

14. The semiconductor device according to claim 1, further comprising:
an interlayer insulating film that covers the resistive film;
a first connection electrode that is embedded in the interlayer insulating film such as to be electrically connected to the resistive film; and
a second connection electrode that is embedded in the interlayer insulating film such as to be electrically connected to the resistive film at a different position from the first connection electrode;
wherein the gate terminal electrode is arranged on the interlayer insulating film such as to be electrically connected to the resistive film via the first connection electrode, and
the gate wiring electrode is arranged on the interlayer insulating film such as to be electrically connected to the resistive film via the second connection electrode.

15. The semiconductor device according to claim 14,
wherein the second connection electrode extends in a different direction from the first connection electrode.

16. The semiconductor device according to claim 14,
wherein the first connection electrodes are embedded in the interlayer insulating film, and
the second connection electrodes are embedded in the interlayer insulating film.

17. The semiconductor device according to claim 14,
wherein a connection area of the second connection electrode with respect to the resistive film is different from a connection area of the first connection electrode with respect to the resistive film.

18. The semiconductor device according to claim 14,
wherein the gate terminal electrode includes:
a first electrode portion that is positioned outside the first connection electrode in plan view, and
a second electrode portion that protrudes from the first electrode portion to the first connection electrode to be narrower than the first electrode portion.

19. The semiconductor device according to claim 1, further comprising:
a p-type well region that is formed in a surface layer portion of the main surface;
wherein the trench resistive structure is formed at an interval from a bottom portion of the well region toward the main surface side such as to be positioned in the well region.

20. The semiconductor device according to claim 1, further comprising:
an active region that is provided in the main surface;
a non-active region that is provided outside an active region in the main surface; and
a trench structure that is formed in the active region;
wherein the trench resistive structure is formed in the non-active region,
the resistive film covers the trench resistive structure in the non-active region,
the gate terminal electrode is electrically connected to the resistive film in the non-active region, and
the gate wiring electrode is electrically connected to the trench structure in the active region and is electrically connected to the resistive film in the non-active region.
